(19) United States
(12) Patent Application Publication
(10) Pub. No.: US 2010/0295027 A1
(43) Pub. Date: Nov. 25, 2010

(54) ORGANIC ELECTROLUMINESCENCE DEVICE

(75) Inventors: Yuichiro Kawamura, Sodegaura-shi (JP); Kazuki Nishimura, Sodegaura-shi (JP); Yukitoshi Jinde, Sodegaura-shi (JP); Hitoshi Kuma, Sodegaura-shi (JP); Toshinari Ogiwara, Sodegaura-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Idemitsu Kosan Co., Ltd., Chiyoda-ku (JP)

(21) Appl. No.: 12/545,425

(22) Filed: Aug. 21, 2009

(30) Foreign Application Priority Data
May 22, 2009 (JP) 2009-124740

(51) Int. Cl. H01L 51/10

(52) U.S. Cl. 257/40; 257/E51.022

(57) ABSTRACT

An organic electroluminescence device includes: an anode; a cathode; and an organic thin-film layer provided between the anode and the cathode and including at least three emitting layers. The organic thin-film layer includes: a first emitting layer adjacent to the anode; a second emitting layer adjacent to the cathode; and a third emitting layer interposed between the first emitting layer and the second emitting layer. The first emitting layer, the second emitting layer and the third emitting layer contain phosphorescent dopants. The first emitting layer and the second emitting layer use fused polycyclic aromatic derivatives as host materials.

### BACKGROUND OF THE INVENTION

1. Field of the Invention

The present invention relates to an organic electroluminescence device.

2. Description of Related Art

Organic electroluminescence devices (hereinafter abbreviated as “organic EL device”), which include organic thin-film layers (in which emitting layers are included) between anodes and cathodes, have been known to emit light using exciton energy generated by recombination a of holes and electrons that have been injected into the emitting layers.

Such an organic EL device, which has the advantages as a self-emitting device, is expected to serve as an emitting device excellent in luminous efficiency, image quality, power consumption and thin design.

However, a variety of challenges have been noted in practical realization, among which, for instance, organic EL devices are indispensably required to reduce its power consumption when used as illuminators.

One method of reducing the power consumption is to use such phosphorescent devices that have higher theoretical efficiency than typical fluorescent devices. However, there have been few examples that achieved a practical lifetime and efficiency.

As a reason for the above, as degradation of materials is progressed in accordance with driving of the device, luminance is decreased and the materials become unequally degraded, whereby color shift and the like come to a big issue.

Further, when organic EL devices are applied to illuminators or displays, white-emitting devices are required. For realization of a practical white-emitting device, emitting layer(s) containing a plurality of components of which luminescence peaks are respectively different is required to be used. When such different-color emitting layers are laminated together, color shift resultant from changes in current density may occur. In other words, the chromaticity at low luminance and the chromaticity at high luminance may be different. This is attributed to changes in recombination positions in the emitting layers as a result of changes in carrier balance in the emitting layers at respective current densities.

In recent years, technique for suppressing color shift in organic EL devices has been suggested (see, for instance, document 1: WO/2006/008977, document 2: JP-A-2001-319779 (Example 4)).

Document 1 discloses an organic EL device including a multilayered emitting layer in which heterocycle-containing compounds (particularly, carbazole or azacarbazole) are used as hosts. The multilayered emitting layer of the organic EL device is structured such that a plurality of phosphorescent layers are laminated periodically or at random. Thus, color shift when the current density is changed can be suppressed.

Document 2 discloses an emitting device that includes: a first emitting layer containing a hole transporting material; and a third emitting layer containing an electron transporting material.

Presumably, by adopting the emitting layer containing the hole transporting material and the emitting layer containing the electron transporting material, the technique disclosed in Document 2 copes with color shift. However, Document 1 or 2 has no disclosure on color shift resultant from continuous driving, which is another big issue in white-emitting devices in practice.

On the other hand, emitting layers of phosphorescent devices are required to have high excited triplet energy (Eg(T)) in order to achieve highly efficient emission. As materials capable of realizing such high Eg(T), skeletons having heterocycles such as carbazole derivatives and furan derivatives are effective.

However, although having high Eg(T), such heterocycle-containing skeletons are less stable against oxidation and reduction and vulnerable to degradation due to accumulated carrier.

In other words, when degradation of materials due to accumulated carrier occurs at an interface between the emitting layer and peripheral materials of layers adjoining to the emitting layer, carrier balance may be changed due to driving and balance of emitting colors may be deteriorated, which may lead to color shift.

### SUMMARY OF THE INVENTION

An object of the invention is to provide an organic EL device excellent in color stability at the time of changes in current density and also at the time of continuous driving.

An organic electroluminescence device according to an aspect of the invention includes:

an anode;

a cathode; and

an organic thin-film layer provided between the anode and the cathode and including at least three emitting layers, in which

the organic thin-film layer includes: a first emitting layer adjacent to the anode; a second emitting layer adjacent to the cathode; and a third emitting layer interposed between the first emitting layer and the second emitting layer,

the first emitting layer, the second emitting layer and the third emitting layer contain phosphorescent dopants, and

the first emitting layer and the second emitting layer use fused polycyclic aromatic derivatives as host materials.

According to the aspect of the invention, the fused polycyclic aromatic derivatives contained in the first emitting layer and the second emitting layer have high resistance against carriers from the anode or the cathode. Thus, the third emitting layer interposed therebetween is not degraded by carriers.

Accordingly, the degradation of the compound(s) contained in the third emitting layer can be suppressed, and such a level of Eg(T) as required for higher-efficiency phosphorescent emission can be stably obtained. Thus, not only at the time when current density is changed but also at the time when the device is continuously driven, the organic electroluminescence device can exhibit excellent color stability and high luminous efficiency.

It should be noted that the fused polycyclic aromatic derivative in the first emitting layer and the fused polycyclic aromatic derivative in the second emitting layer may be the same or different.

The aspect of the invention is capable of providing an organic EL device excellent in color stability at the time of changes in current density and also at the time of continuous driving.

### BRIEF DESCRIPTION OF THE DRAWINGS

FIG. 1 schematically shows an exemplary arrangement of an organic electroluminescence device according to an exemplary embodiment of the invention.

FIG. 2 shows an exemplary energy relationship between components of the organic electroluminescence device according to the exemplary embodiment.

FIG. 3 schematically shows an exemplary arrangement of another organic electroluminescence device.

FIG. 4 schematically shows an exemplary arrangement of still another organic electroluminescence device.

### DETAILED DESCRIPTION OF PREFERRED EMBODIMENT(S)

Exemplary embodiment(s) of the invention will be described below.

### (Arrangement of Organic EL Device)

Arrangement(s) of an organic EL device according to the aspect of the invention will be described below.

The followings are representative arrangement examples of an organic EL device:

(1) anode/emitting layer/cathode;
(2) anode/hole injecting layer/emitting layer/cathode;
(3) anode/emitting layer/electron injecting·transporting layer/cathode;
(4) anode/hole injecting layer/emitting layer/electron injecting·transporting layer/cathode;
(5) anode/organic semiconductor layer/emitting layer/cathode;
(6) anode organic semiconductor layer/electron blocking layer/emitting layer/cathode;
(7) anode/organic semiconductor layer/emitting layer/adhesion improving layer/cathode;
(8) anode/hole injecting·transporting layer/emitting layer/electron injecting·transporting layer/cathode;
(9) anode/insulating layer/emitting layer/insulating layer/cathode;
(10) anode/inorganic semiconductor layer/insulating layer/emitting layer/insulating layer/cathode;
(11) anode/organic semiconductor layer/insulating layer/emitting layer/insulating layer/cathode;
(12) anode/insulating layer/hole injecting·transporting layer/emitting layer/insulating layer/cathode;
(13) anode/insulating layer/hole injecting·transporting layer/emitting layer/electron injecting·transporting layer/cathode; and
(14) anode emitting layer/intermediate layer/emitting layer/cathode.

While the arrangement (8) is preferably used among the above, the arrangement of the invention is not limited to the above arrangements.

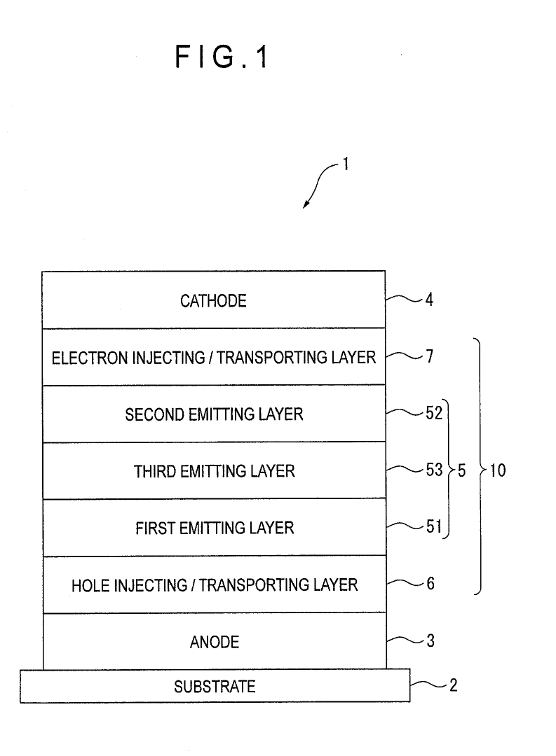

FIG. 1 schematically shows an exemplary arrangement of an organic EL device according to an exemplary embodiment of the invention.

An organic EL device 1 includes a transparent substrate 2, an anode 3, a cathode 4 and an organic thin-film layer 10 provided between the anode 3 and the cathode 4.

The organic thin-film layer 10 includes: a phosphorescent-emitting layer 5 containing a phosphorescent host and a phosphorescent dopant; a hole injecting/transporting layer 6 provided between the phosphorescent-emitting layer 5 and the anode 3; and an electron injecting/transporting layer 7 provided between the phosphorescent-emitting layer 5 and the cathode 4.

The phosphorescent-emitting layer 5 includes a red-emitting first emitting layer 51, a green-emitting second emitting layer 52 and red-emitting third emitting layer 53.

In addition, an electron blocking layer may be provided to the phosphorescent-emitting layer 5 adjacently to the anode 3 while a hole blocking layer may be provided to the phosphorescent-emitting layer 5 adjacently to the cathode 4.

With this arrangement, electrons and holes can be trapped in the phosphorescent-emitting layer 5, thereby enhancing probability of exciton generation in the phosphorescent-emitting layer 5.

It should be noted that a “fluorescent host” and a “phosphorescent host” herein respectively mean a host combined with a fluorescent dopant and a host combined with a phosphorescent dopant, and that a distinction between the fluorescent host and phosphorescent host is not unambiguously derived only from a molecular structure of the host in a limited manner.

In other words, the fluorescent host herein means a material for forming a fluorescent-emitting layer containing a fluorescent dopant, and does not mean a host that is only usable as a host of a fluorescent material.

Likewise, the phosphorescent host herein means a material for forming a phosphorescent-emitting layer containing a phosphorescent dopant, and does not mean a host that is only usable as a host of a phosphorescent material.

It should also be noted that the “hole injecting/transporting layer (or hole injecting-transporting layer)” herein means “at least one of hole injecting layer and hole transporting layer” while “electron injecting/transporting layer (or electron injecting·transporting layer)” herein means “at least one of electron injecting layer and electron transporting layer”.

(Light-Transmissive Substrate 2)

The organic EL device 1 is formed on the light-transmissive substrate 2. The light-transmissive substrate, which supports the organic EL device 1, is preferably a smoothly-shaped substrate that transmits 50% or more of light in a visible region of 400 nm to 700 nm.

The light-transmissive substrate is exemplarily a glass plate, a polymer plate or the like.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate resins, acryl resins, polyethylene terephthalate resins, polyether sulfide resins and polysulfone resins can be used.

(Anode 3 and Cathode 4)

The anode 3 of the organic EL device 1 is used for injecting holes into the hole injecting layer, the hole transporting layer or the emitting layer. It is effective that the anode has a work function of 4.5 eV or more.

Exemplary materials for the anode are alloys of indium-tin oxide (ITO), tin oxide (NESA), indium zinc oxide, gold, silver, platinum and copper.

The anode may be made by forming a thin film from these electrode materials through a method such as vapor deposition or sputtering.

When tight from the phosphorescent-emitting layer 5 is to be emitted through the anode as in this embodiment, the anode preferably transmits more than 10% of the light in the visible region. Sheet resistance of the anode is preferably several hundreds Ω/square or lower. Although depending on the material of the anode, thickness of the anode is typically in a range of 10 nm to 1 μm, and preferably in a range of 10 to 200 nm.

The cathode 4 is preferably formed of a material with smaller work function in order to inject electrons into the electron injecting layer, the electron transporting layer or the emitting layer.

Although a material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, alloy of magnesium and silver and the like.

Like the anode 3, the cathode 4 may be made by forming a thin film from the above materials through a method such as vapor deposition or sputtering. In addition, the light may be emitted through the cathode 4.

### (Phosphorescent-Emitting Layer 5)

The phosphorescent-emitting layer 5 of the organic EL device 1 has functions as follows,

namely:

(1) injecting function: a function for accepting, when an electrical field is applied, the holes injected by the anode or the hole injecting layer, or the electrons injected by the cathode or the electron injecting layer;
(2) transporting function: a function for transporting injected electric charges (the electrons and the holes) by the force of the electrical field; and
(3) emitting function: a function for providing a condition for recombination of the electrons and the holes to emit light.

Injectability of the holes may differ from that of the electrons and transporting capabilities of the hole and the electrons (represented by mobilities of the holes and the electrons) may differ from each other.

As a method of forming the phosphorescent-emitting layer 5, known methods such as vapor deposition, spin coating and an LB method may be employed.

The phosphorescent-emitting layer 5 is preferably a molecular deposit film.

The molecular deposit film means a thin film formed by depositing a material compound in gas phase or a film formed by solidifying a material compound in a solution state or in liquid phase. The molecular deposit film is typically distinguished from a thin film formed by the LB method (molecular accumulation film) by differences in aggregation structures, higher order structures and functional differences arising therefrom.

As disclosed in JP-A-57-51781, the emitting layer can be formed from a thin film formed by spin coating or the like, the thin film being formed from a solution prepared by dissolving a binder (e.g. a resin) and a material compound in a solvent.

The thickness of the emitting layer is preferably in a range of 5 to 50 nm, more preferably in a range of 7 to 50 nm and most preferably in a range of 10 to 50 nm. The thickness below 5 nm may cause difficulty in forming the emitting layer and in controlling chromaticity, while the thickness above 50 nm may increase driving voltage.

### (Organic-EL-Device Material)

The phosphorescent-emitting layer 5 of the above-described organic EL device 1, which includes at least three emitting layers, includes the first emitting layer 51, the second emitting layer 52 and the third emitting layer 53.

The first emitting layer 51 is located adjacent to the anode 3, the second emitting layer 52 is located adjacent to the cathode 4 and the third emitting layer 53 is interposed between the first emitting layer 51 and the second emitting layer 52 in contact with them.

Host materials for the first emitting layer 51 and the second emitting layer 52 are fused polycyclic aromatic derivative(s).

In this exemplary embodiment, the third emitting layer 53 preferably uses a heterocycle-containing compound as the host material. Such a heterocycle-containing compound, which has high excited triplet energy (Eg(T)), is preferably usable in the third emitting layer 53 as a material for achieving high-efficient emission.

The fused polycyclic aromatic derivative(s) in the first emitting layer 51 and the second emitting layer 52 preferably has triplet energy of 2.0 eV or more.

Since the triplet energy is 2.0 eV or more, energy can be transferred to a phosphorescent dopant that emits light in a range of 520 nm to 720 nm.

The triplet energy is preferably in a range of 2.0 eV to 2.6 eV, more preferably 2.0 eV to 2.5 eV, the most preferably 2.0 eV to 2.4 eV.

Triplet energy Eg(T) of a material for forming an organic EL device may be exemplarily defined based on the phosphorescence spectrum. For instance, in the invention, the triplet energy Eg(T) may be defined as follows.

Specifically, each material is dissolved in an EPA solvent (diethylether:isopentane:ethanol=5:5:2 in volume ratio) with a concentration of 10 μmol/L, thereby forming a sample for phosphorescence measurement.

Then, the sample for phosphorescence measurement is put into a quartz cell, cooled to 77K and irradiated with exciting light, so that a wavelength of phosphorescence radiated therefrom is measured.

A tangent line is drawn to be tangent to a rising section adjacent to the short-wavelength side of the obtained phosphorescence spectrum, and a wavelength value at an intersection of the tangent line and a base line is converted into energy value. Then, the converted energy value is defined as the triplet energy gap Eg(T).

For the measurement, for instance, a commercially-available FLUOROLOG II (manufactured by SPEX Corporation) may be used.

However, the triplet energy does not need to be defined by the above method, but may be defined by any other suitable method as long as compatible with the invention.

In this exemplary embodiment, emission wavelengths of the phosphorescent dopants contained in the first emitting layer and the second emitting layer are preferably longer than an emission wavelength of the phosphorescent dopant contained in third emitting layer.

Emitting-color combinations of the above-described first emitting layer 51, second emitting layer 52 and third emitting layer 53 can be exemplified as follows:

red-emitting first emitting layer 51/green-emitting third emitting layer 53/red-emitting second emitting layer 52;

red-emitting first emitting layer 51/blue-emitting third emitting layer 53/green-emitting second emitting layer 52;

green-emitting first emitting layer 51/blue-emitting third emitting layer 53/red-emitting second emitting layer 52;

red-emitting first emitting layer 51/blue-emitting third emitting layer 53/red-emitting second emitting layer 52; and

green-emitting first emitting layer 51/blue-emitting third emitting layer 53/green-emitting second emitting layer 52.

In this exemplary embodiment, the phosphorescent dopants contained in the first emitting layer 51 and the second emitting layer 52 each preferably emit light of red color while the phosphorescent dopant contained in third emitting layer 53 preferably emits light of green color.

Host materials for the first emitting layer 51 and the second emitting layer 52 are preferably fused polycyclic aromatic derivative(s) that does not have a heterocycle skeleton because such a fused polycyclic aromatic derivative containing no hetero atom such as nitrogen atom can further enhance molecular stability. The heterocycle skeleton means a skeleton having hetero atom(s) on a ring of the fused ring or a skeleton structured such that the fused ring is bonded with hetero atom(s).

Further, in this exemplary embodiment, the fused polycyclic aromatic derivative is preferably fused polycyclic aromatic hydrocarbon.

Furthermore, in this exemplary embodiment, the fused polycyclic aromatic hydrocarbon is preferably naphthalene derivatives. Naphthalene derivatives, of which length of the conjugate is moderate, can provide relatively large triplet energy.

Examples of the naphthalene derivative are as follows.

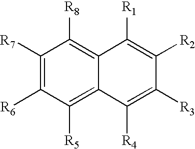

In the formula, R₁ to R₈ each represent a substituted or unsubstituted benzene ring or a substituted or unsubstituted fused aromatic hydrocarbon group selected from naphthalene ring, fluorene ring, chrysene ring, fluoranthene ring, triphenylene ring, phenanthrene ring, benzophenanthrene ring, dibenzophenanthrene ring, benzotriphenylene ring, benzochrysene ring, picene ring and benzo[b]fluoranthene ring.

Further, the host material may be a material represented by the following general formula.

Ra—Ar¹—Ar²—Rb (1)

In the formula, Ar¹, Ar², Ra and Rb each represent a substituted or unsubstituted benzene ring or a substituted or unsubstituted fused aromatic hydrocarbon group selected from naphthalene ring, fluorene ring, chrysene ring, fluoranthene ring, triphenylene ring, phenanthrene ring, benzophenanthrene ring, dibenzophenanthrene ring, benzotriphenylene ring, benzochrysene ring, picene ring and benzo[b]fluoranthene ring.

When Ar¹ represents a substituted or unsubstituted benzene ring, Ra and Ar² represent different substituted or unsubstituted fused aromatic hydrocarbon groups.

When Ar² represents a substituted or unsubstituted benzene ring, Rb and Ar¹ represent different substituted or unsubstituted fused aromatic hydrocarbon groups.

In addition, substituents for Ra and Rb are not aryl groups.

When Ra, Ra, Ar² or Ar³ in the formula (1) has a single or plural substituent(s), the single or plural substituent(s) is an alkyl group having 1 to 20 carbon atoms, haloalkyl group having 1 to 20 carbon atoms, cycloalkyl group having 5 to 18 carbon atoms, silyl group having 3 to 20 carbon atoms, cyano group or halogen atom, while a substituent for Ar² or Ar² is further allowed to be an aryl group having 6 to 22 carbon atoms.

In the formula (1), Ra and Ar² each preferably represent a naphthalene ring while Rb preferably represents a group selected from fluorene ring, phenanthrene ring, triphenylene ring, benzophenanthrene ring, dibenzophenanthrene ring, benzotriphenylene ring, fluoranthene ring, benzochrysene ring, benzo[b]fluoranthene ring and picene ring.

The host material represented by the formula (1) may be represented by the following formula (2).

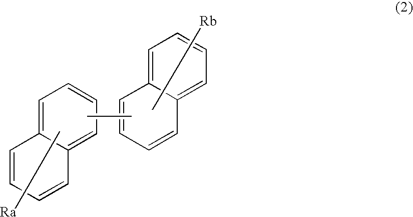

When Ra, Rb or naphthalene rings in the formula (2) has a single substituent or plural substituents, the single or plural substituent(s) is an alkyl group having 1 to 20 carbon atoms, haloalkyl group having 1 to 20 carbon atoms, cycloalkyl group having 5 to 18 carbon atoms, silyl group having 3 to 20 carbon atoms, cyano group or halogen atom, while substituents for the naphthalene rings other than Ra and Rb are further allowed to be an aryl group having 6 to 22 carbon atoms.

In the formula (2), Ra and Rb each preferably represent a group selected from fluorene ring, phenanthrene ring, triphenylene ring, benzophenanthrene ring, dibenzophenanthrene ring, benzotriphenylene ring, fluoranthene ring, benzochrysene ring, benzo[b]fluoranthene ring and picene ring.

Examples of the naphthalene derivative are as follows.

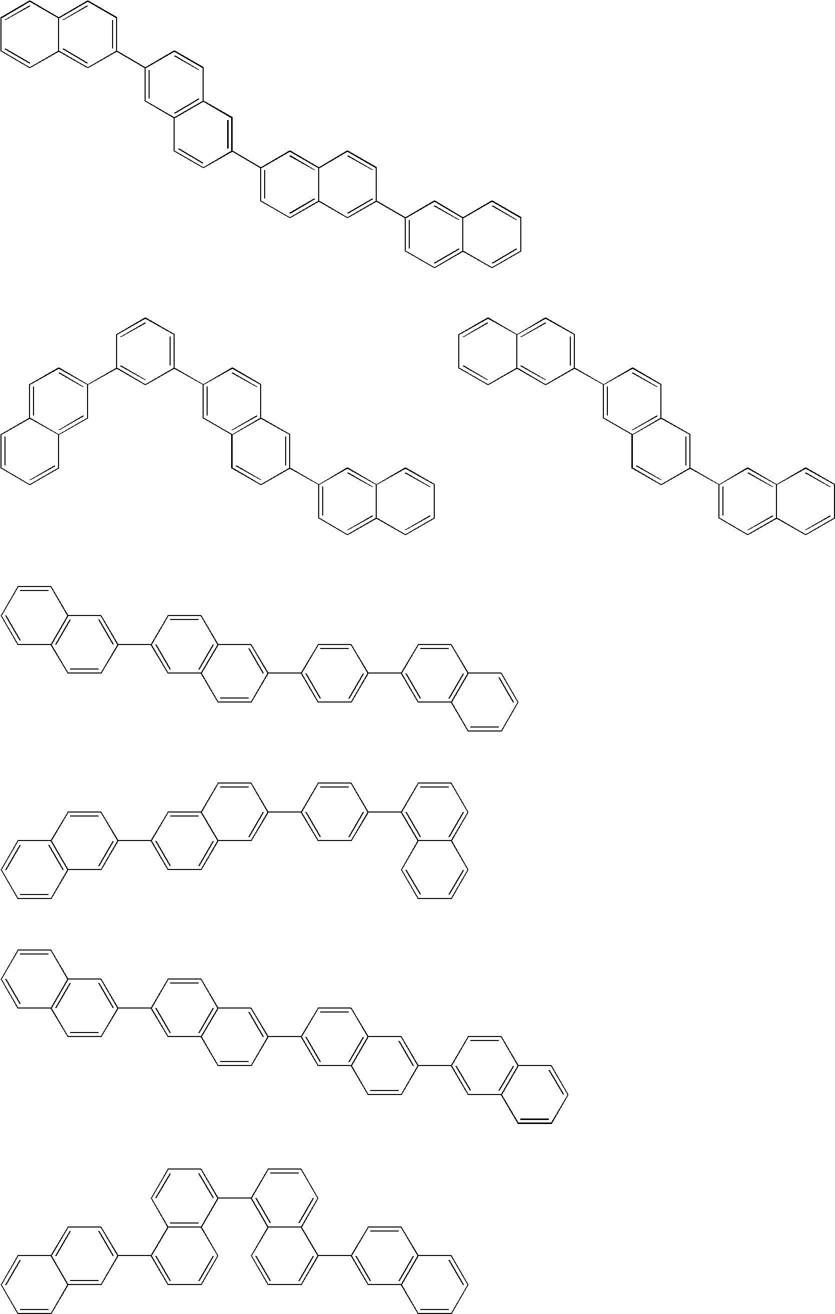

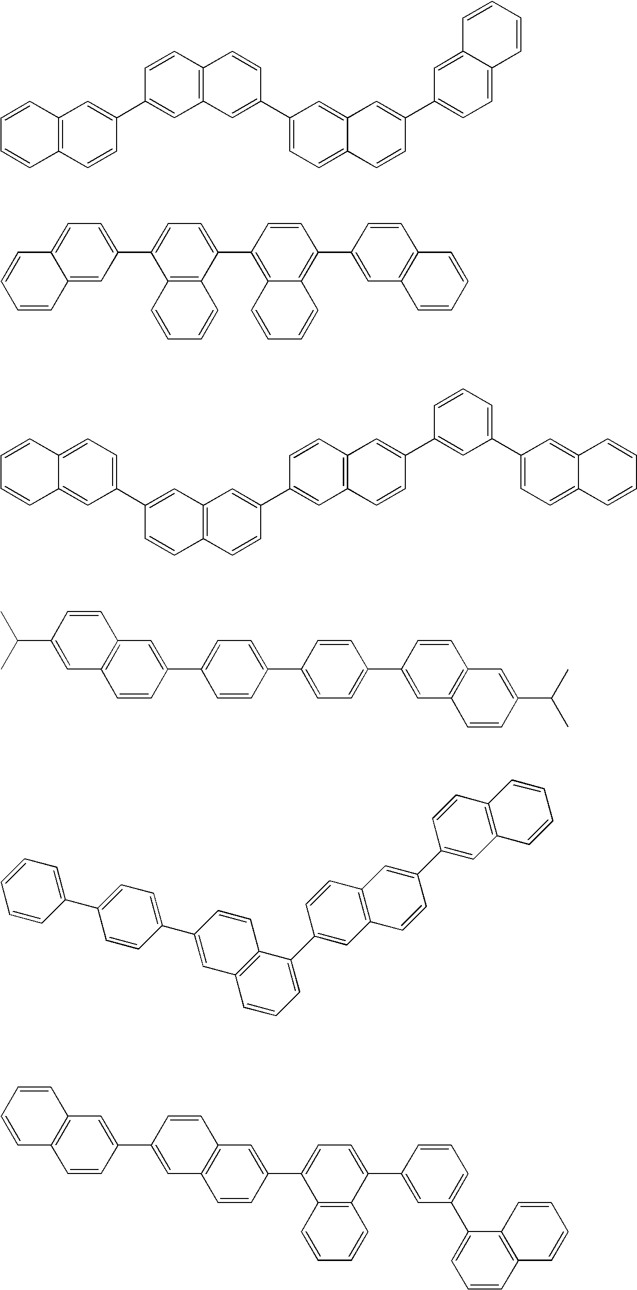

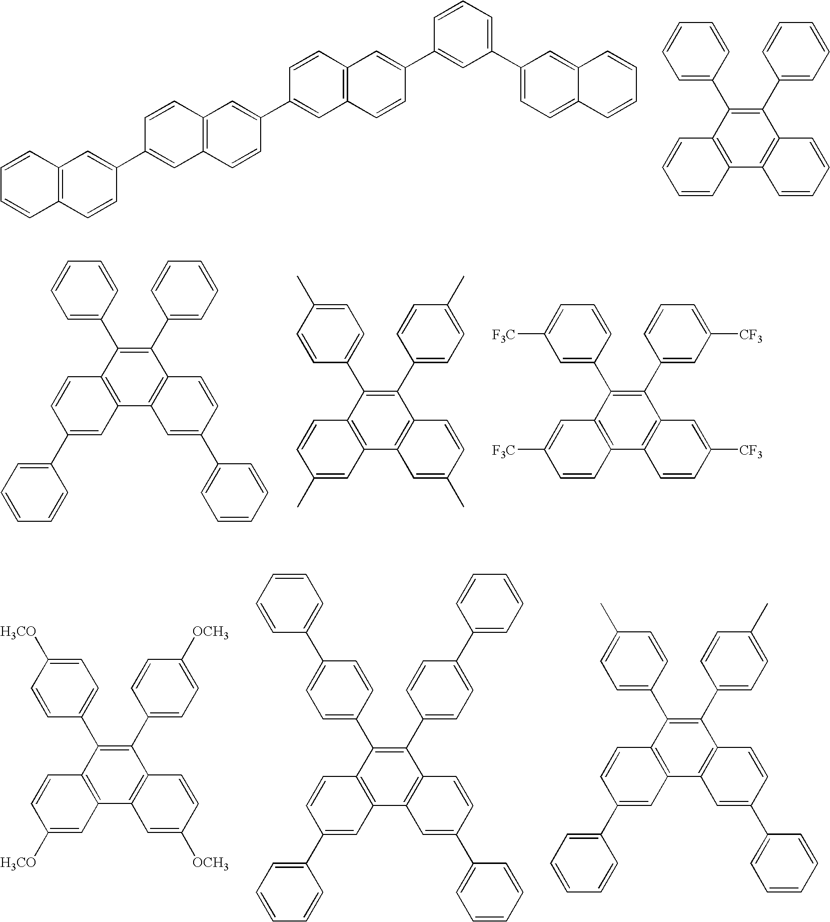

In this exemplary embodiment, the fused polycyclic aromatic hydrocarbon is preferably the elementary substance of phenanthrene represented by the following formula (5) or its derivative.

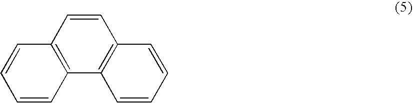

Examples of the substituent for the phenanthrene derivative are an alkyl group, cycloalkyl group, aralkyl group, alkenyl group, cycloalkenyl group, alkynyl group, hydroxyl group, mercapto group, alkoxy group, alkylthio group, arylether group, arylthioether group, aryl group, heterocyclic group, halogen, haloalkane, haloalkene, haloalkyne, cyano group, aldehyde group, carbonyl group, carboxyl group, ester group, amino group, nitro group, silyl group and siloxanyl group.

The phenanthrene derivative is exemplarily represented by the following formula (5A).

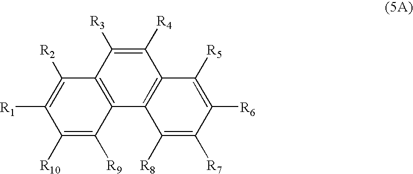

In the Formula (5A), R₁ to R₁₀ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the phenanthrene derivative represented by the formula (5A) are as follows.

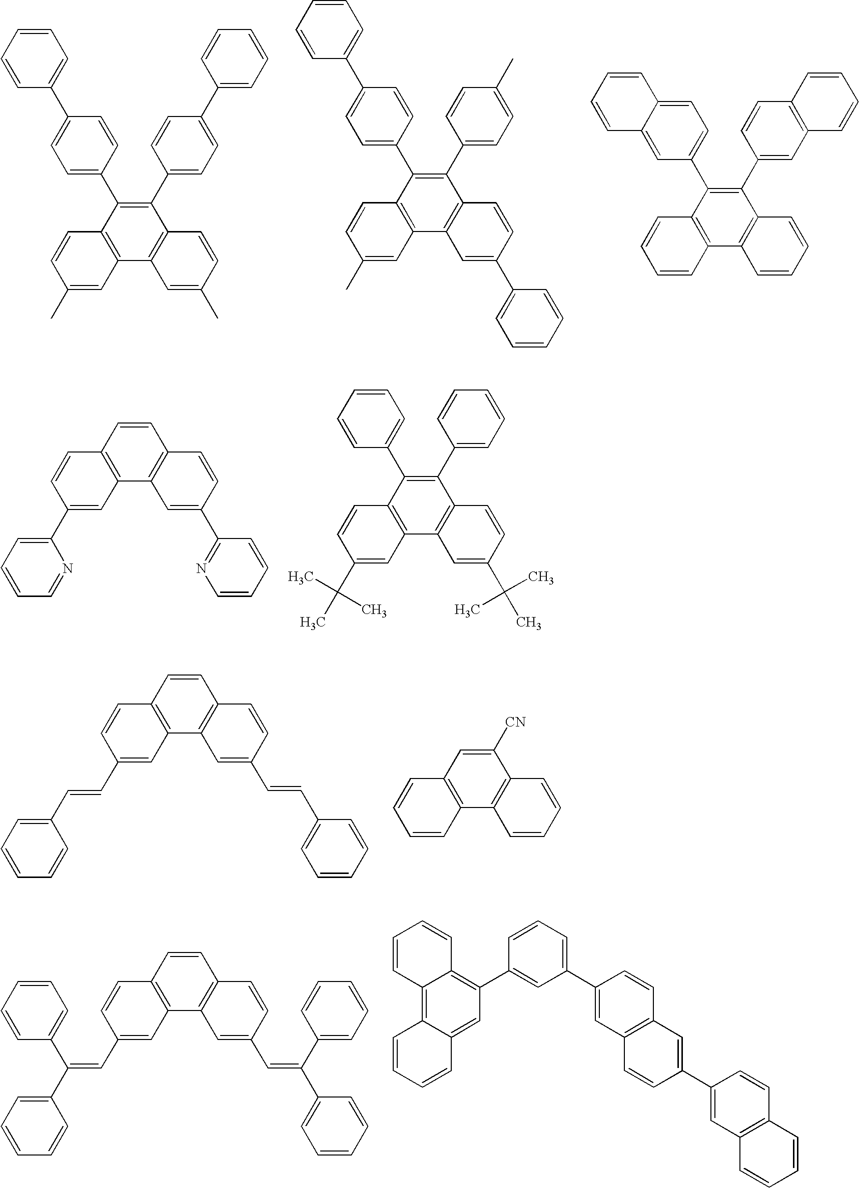

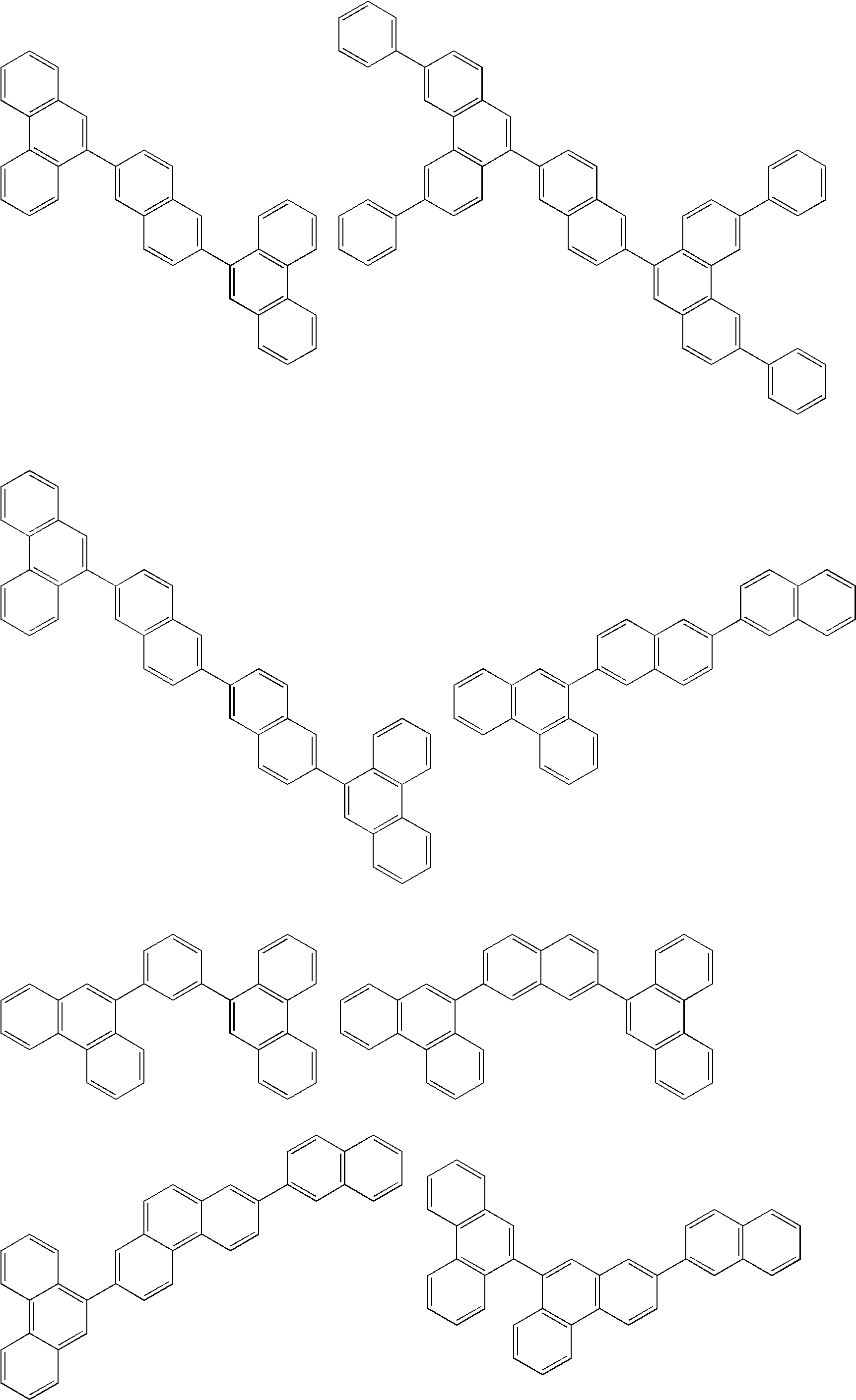

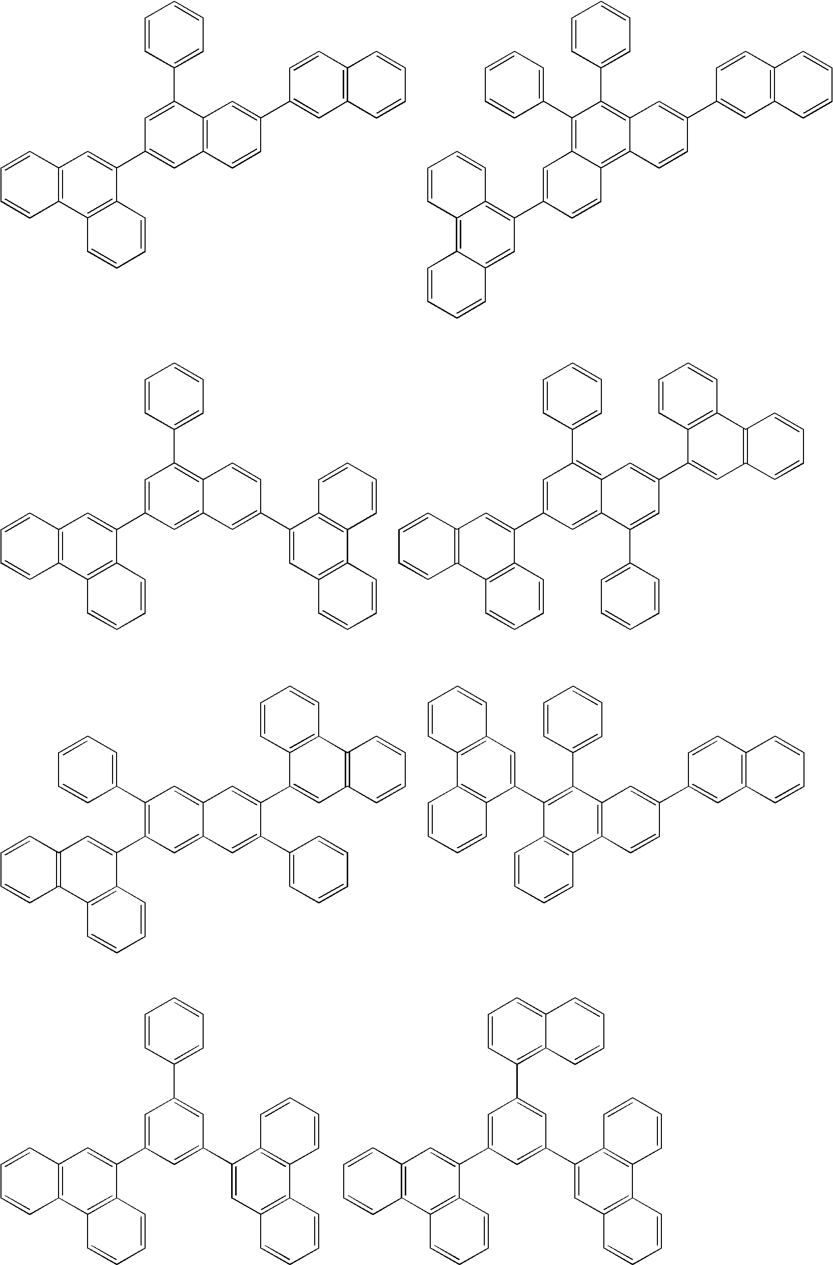

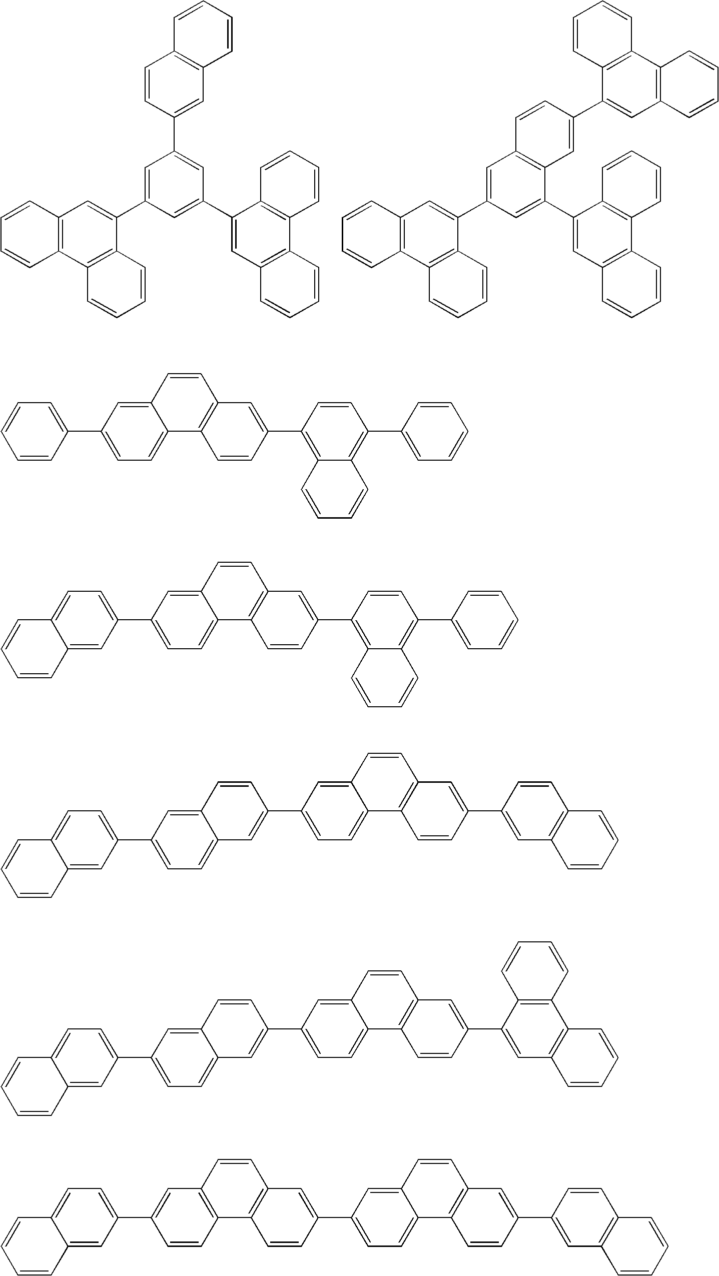

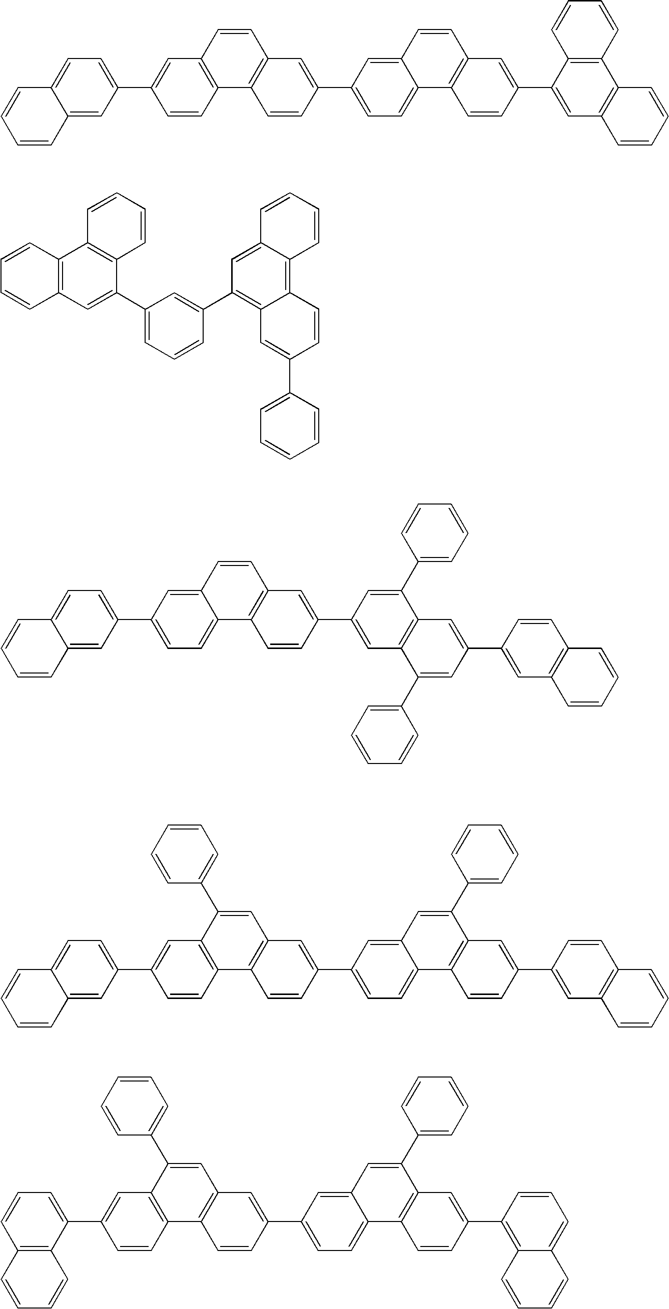

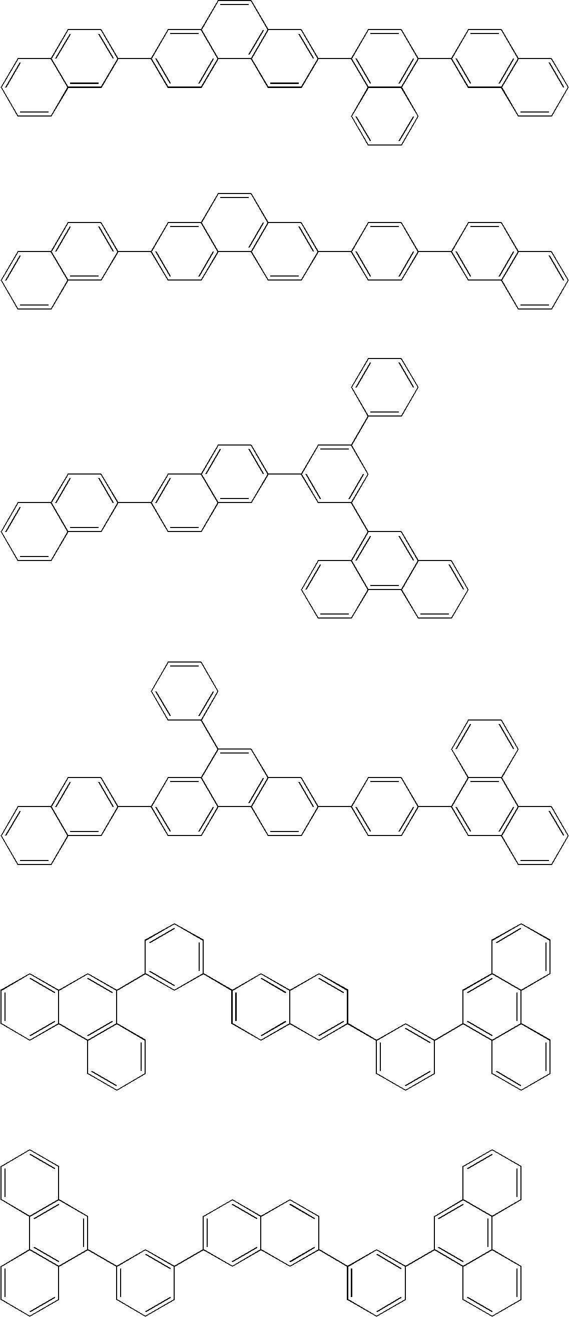

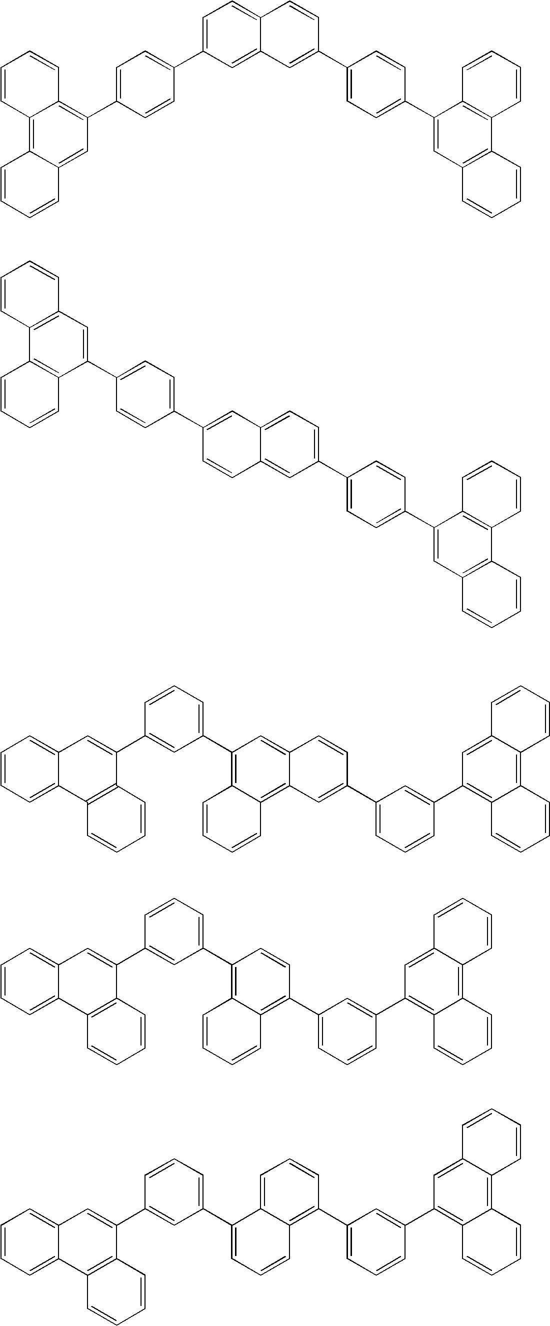

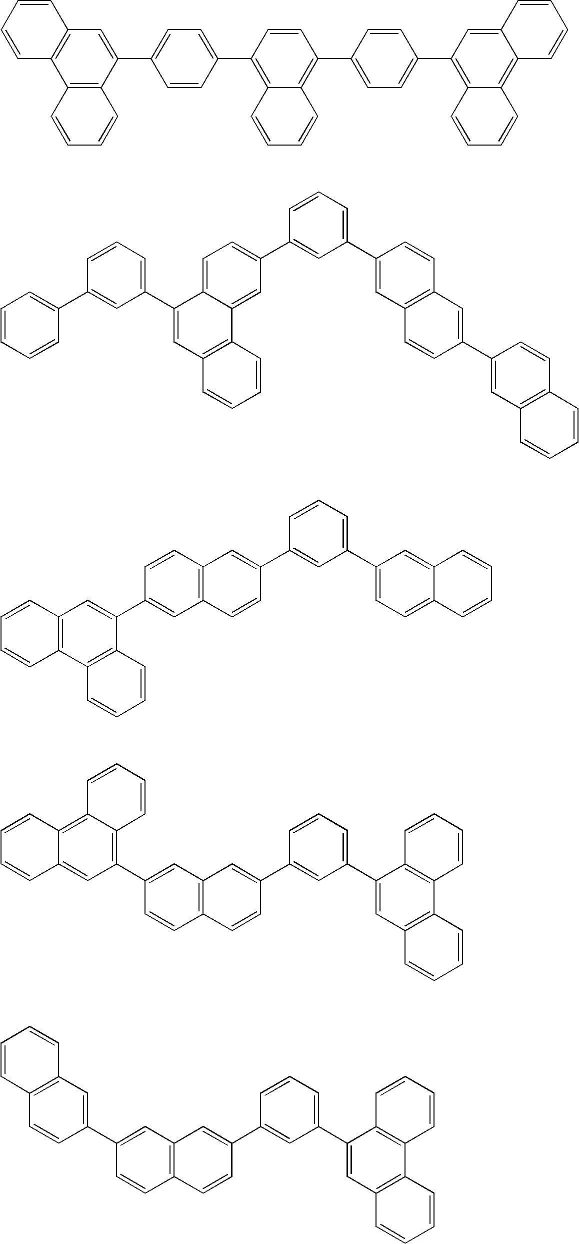

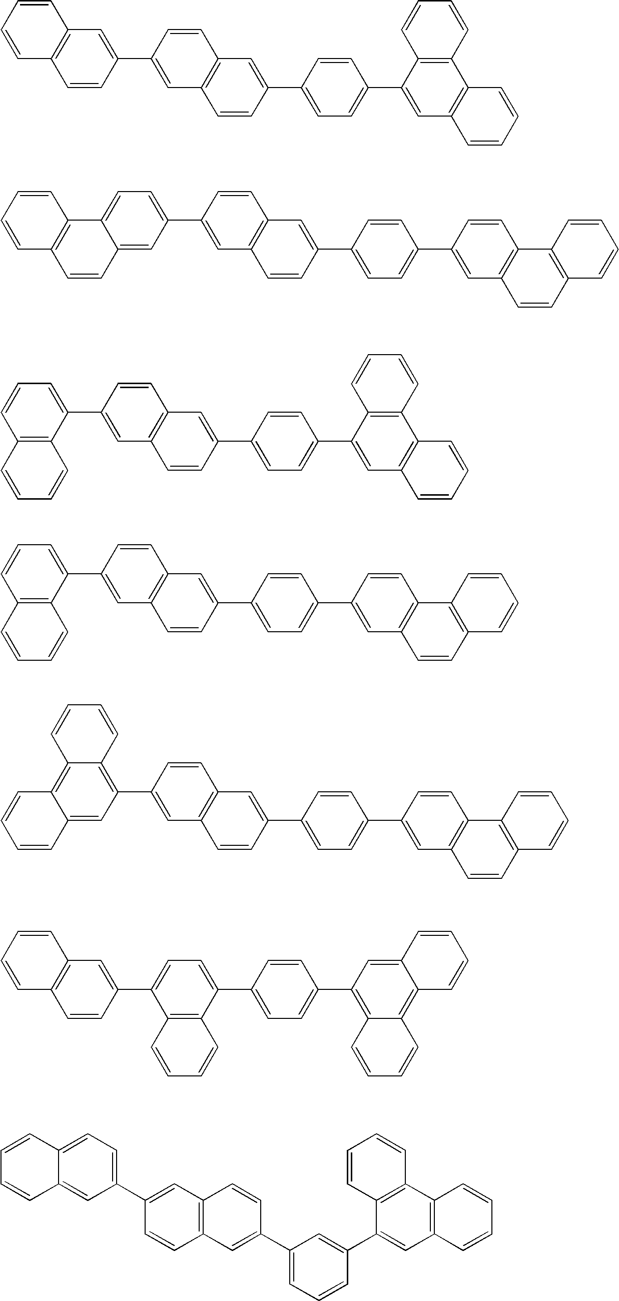

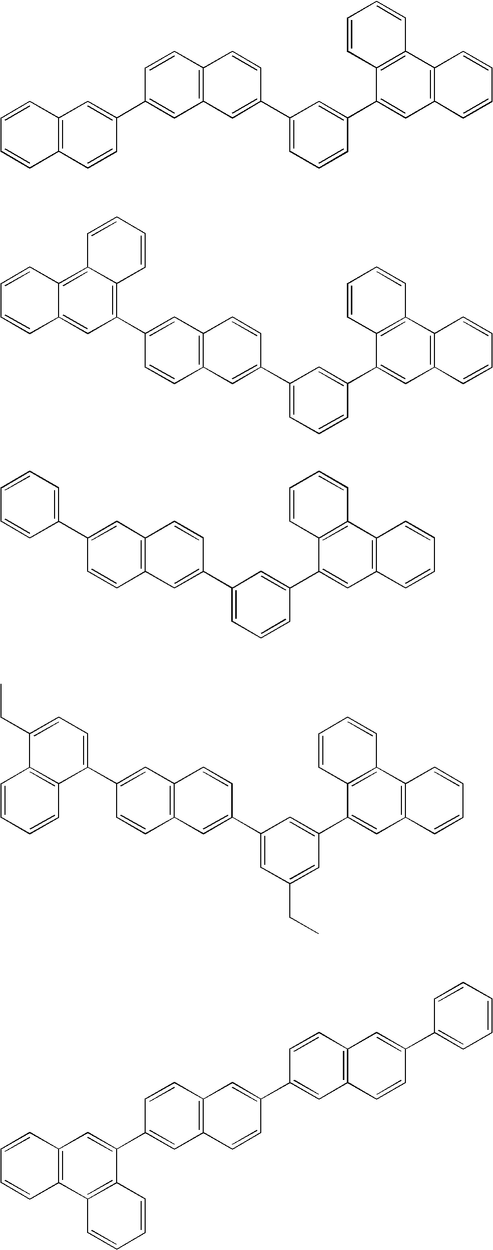

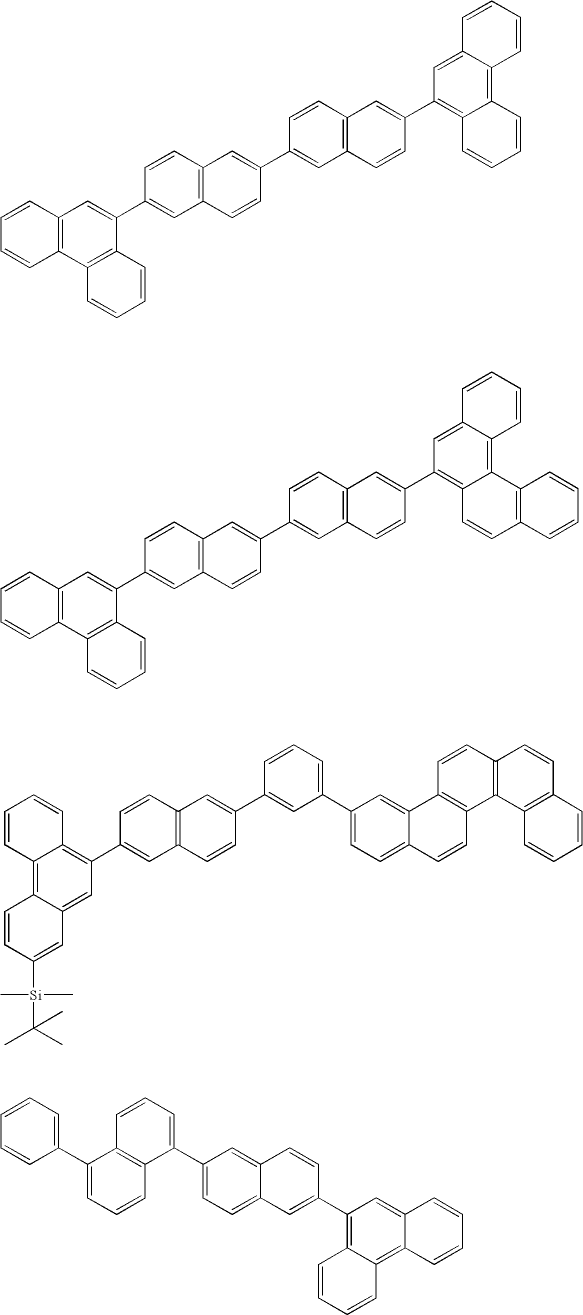

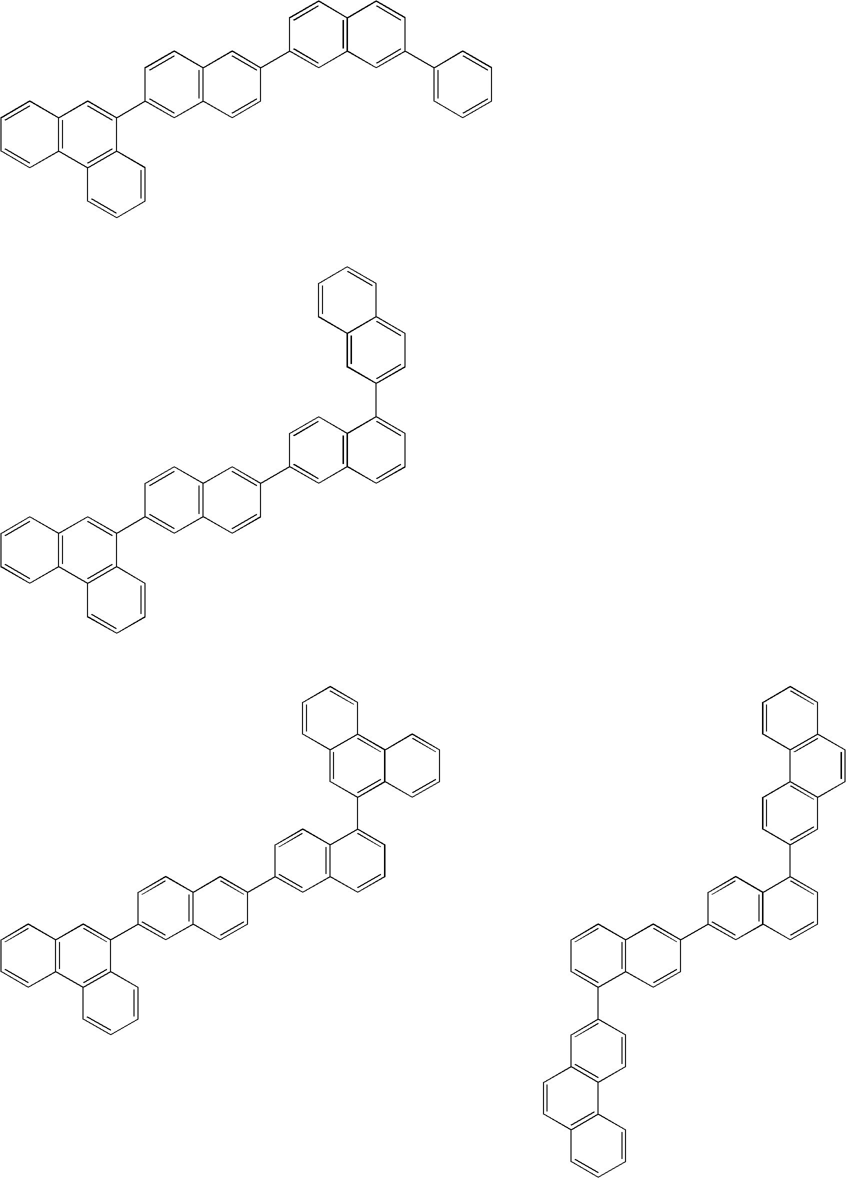

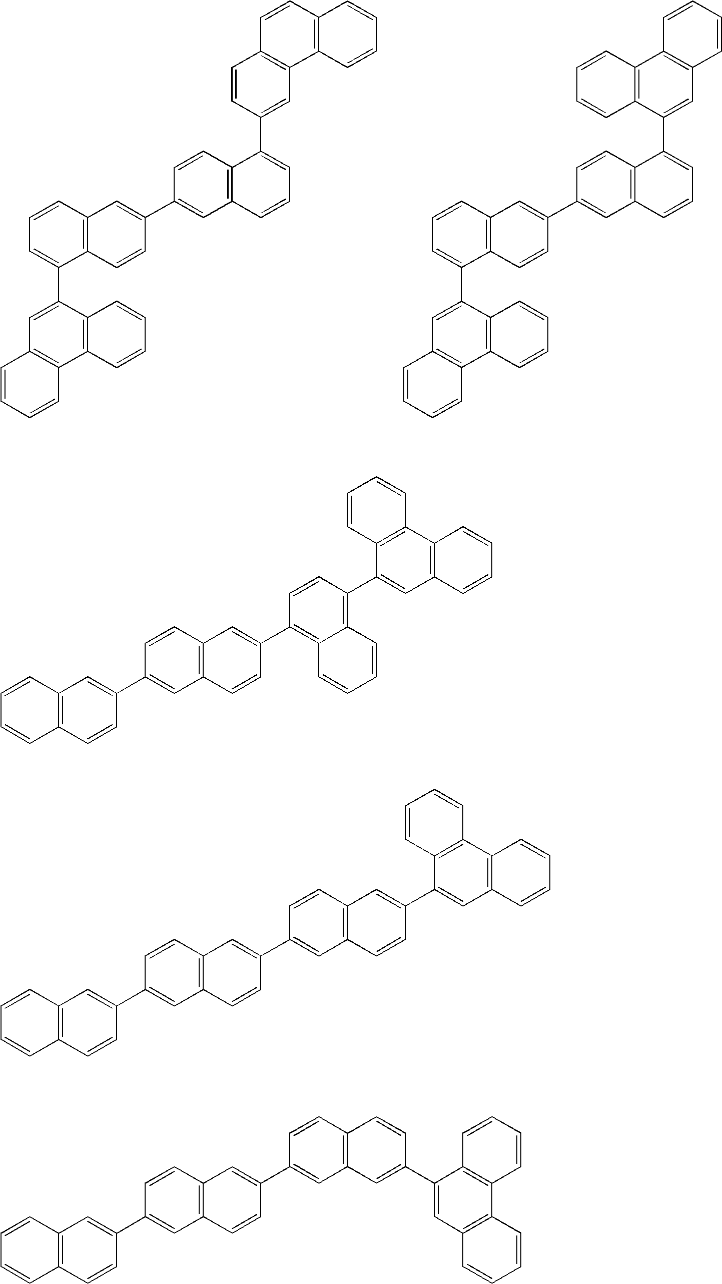

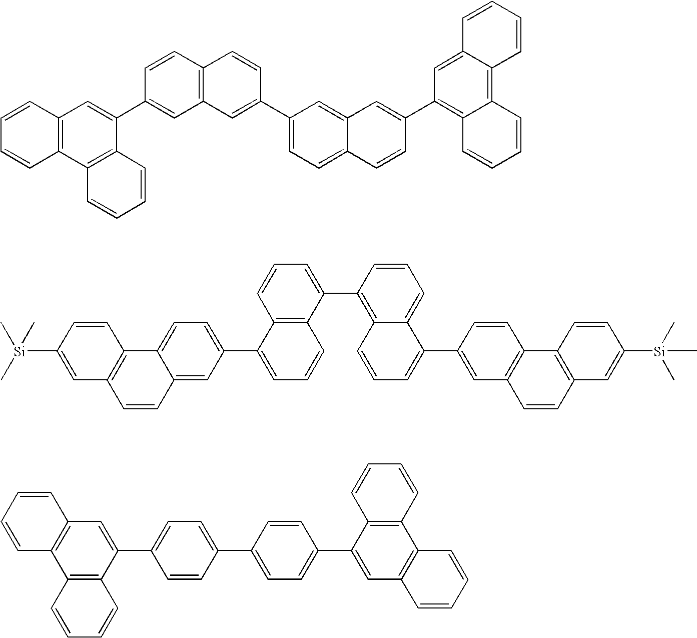

In this exemplary embodiment, the fused polycyclic aromatic hydrocarbon is preferably the elementary substance of chrysene represented by the following formula (6) or its derivative.

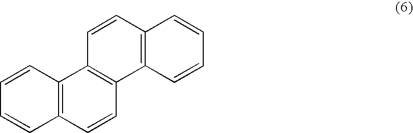

The chrysene derivative is exemplarily represented by the following formula (6A).

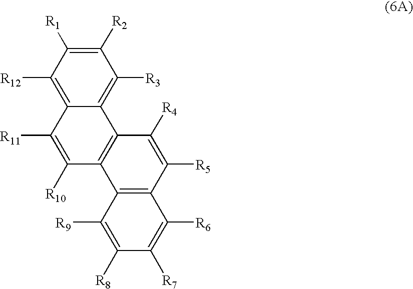

In the formula (6A), R₁ to R₁₂ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

In this exemplary embodiment, the fused polycyclic aromatic hydrocarbon is preferably the elementary substance of a compound represented by the following formula (7) (benzo[c]phenanthrene) or its derivative.

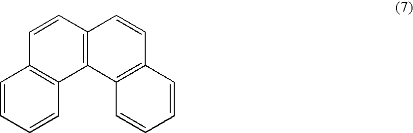

The benzo[c]phenanthrene derivative is exemplarily represented by the following formula (7A).

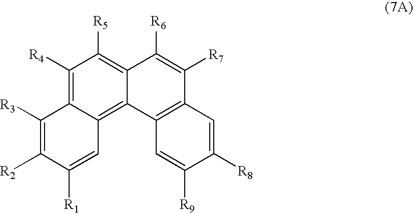

In the formula (7A), R₁ to R₉ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Examples of the benzo[c]phenanthrene derivative represented by the formula (7A) are as follows.

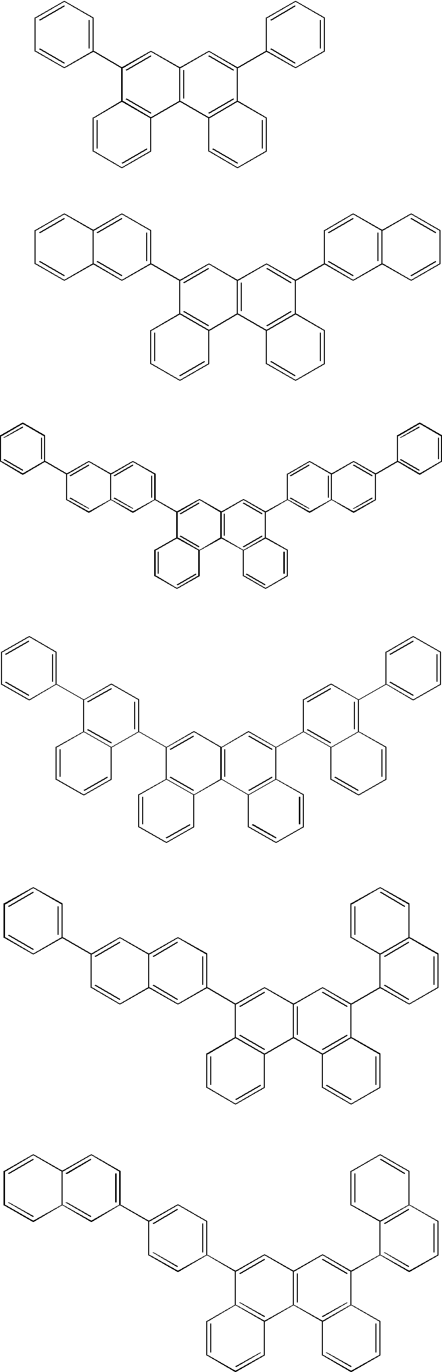

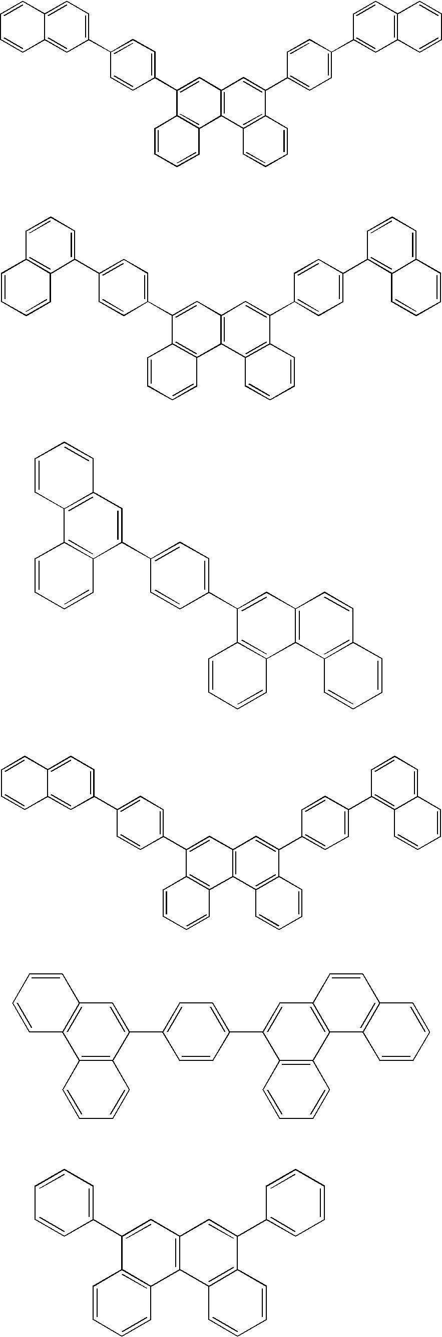

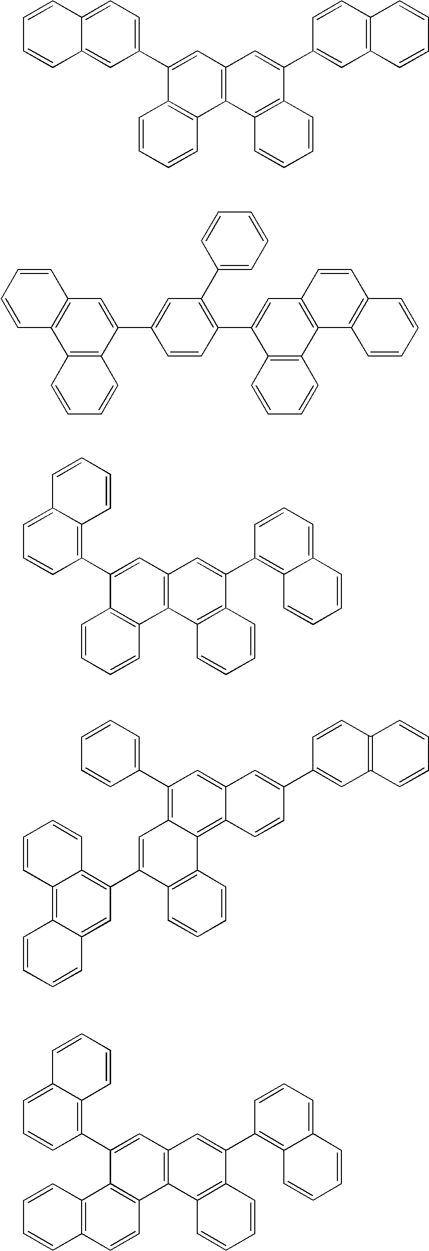

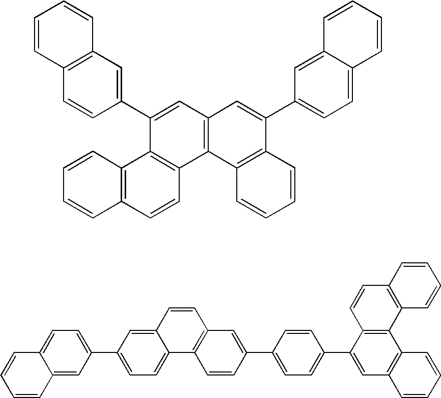

In this exemplary embodiment, the fused polycyclic aromatic hydrocarbon is preferably the elementary substance of fluoranthene represented by the following formula (10) or its derivative.

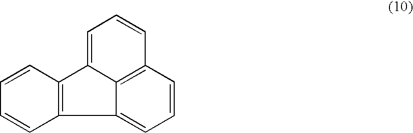

The fluoranthene derivative is exemplarily represented by the following formula (10A).

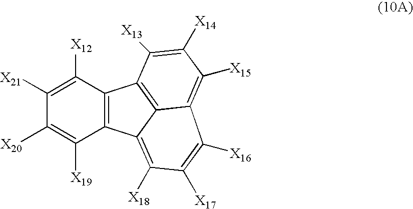

In the formula (10A), X₁₂ to X₂₁ each represent a hydrogen atom, a halogen atom, a linear, branched or cyclic alkyl group, a linear, branched or cyclic alkoxy group, or a substituted or unsubstituted aryl group.

The aryl group represents a carbocyclic aromatic group such as a phenyl group and a naphthyl group.

X₁₂ to X₂₁ each preferably represent a hydrogen atom, halogen atom (such as fluorine atom, chlorine atom or bromine atom), linear, branched or cyclic alkyl group having 1 to 16 carbon atoms (such as methyl group, ethyl group, n-propyl group, isopropyl group, n-butyl group, isobutyl group, sec-butyl group, tert-butyl group, n-pentyl group, isopentyl group, neopentyl group, tert-pentyl group, cyclopentyl group, n-hexyl group, 3,3-dimethylbutyl group, cyclohexyl group, n-heptyl group, cyclohexylmethyl group, n-octyl group, tert-octyl group, 2-ethylhexyl group, n-nonyl group, n-decyl group, n-dodecyl group, n-tetradecyl group or n-hexadecyl group), linear, branched or cyclic alkoxy group having 1 to 16 carbon atoms (such as methoxy group, ethoxy group, n-propoxy group, isopropoxy group, n-butoxy group, isobutoxy group, sec-butoxy group, n-pentyloxy group, neopentyloxy group, cyclopentyloxy group, n-hexyloxy group, 3,3-dimethylbutyloxy group, cyclohexyloxy group, n-heptyloxy group, n-octyloxy group, 2-ethylhexyloxy group, n-nonyloxy group, n-decyloxy group, n-dodecyloxy group, n-tetradecyloxy group or n-hexadecyloxy group), or substituted or unsubstituted aryl group having 4 to 16 carbon atoms (such as phenyl group, 2-methylphenyl group, 3-methylphenyl group, 4-methylphenyl group, 4-ethylphenyl group, 4-n-propylphenyl group, 4-isopropylphenyl group, 4-n-butylphenyl group, 4-tert-butylphenyl group, 4-isopentylphenyl group, 4-tert-pentylphenyl group, 4-n-hexylphenyl group, 4-cyclohexylphenyl group, 4-n-octylphenyl group, 4-n-decylphenyl group, 2,3-dimethylphenyl group, 2,4-dimethylphenyl group, 2,5-dimethylphenyl group, 3,4-dimethylphenyl group, 5-indanyl group, 1,2,3,4-tetrahydro-5-naphthyl group, 1,2,3,4-tetrahydro-6-naphthyl group, 2-methoxyphenyl group, 3-methoxyphenyl group, 4-methoxyphenyl group, 3-ethoxyphenyl group, 4-ethoxyphenyl group, 4-n-propoxyphenyl group, 4-isopropoxyphenyl group, 4-n-butoxyphenyl group, 4-n-pentyloxyphenyl group, 4-n-hexyloxyphenyl group, 4-cyclohexyloxyphenyl group, 4-n-heptyloxyphenyl group, 4-n-octyloxyphenyl group, 4-n-decyloxyphenyl group, 2,3-dimethoxyphenyl group, 2,5-dimethoxyphenyl group, 3,4-dimethoxyphenyl group, 2-methoxy-5-methylphenyl group, 3-methyl-4-methoxyphenyl group, 2-fluorophenyl group, 3-fluorophenyl group, 4-fluorophenyl group, 2-chlorophenyl group, 3-chlorophenyl group, 4-chlorophenyl group, 4-bromophenyl group, 4-trifluoromethylphenyl group, 3,4-dichlorophenyl group, 2-methyl-4-chlorophenyl group, 2-chloro-4-methylphenyl group, 3-chloro-4-methylphenyl group, 2-chloro-4-methoxyphenyl group, 4-phenylphenyl group, 3-phenylphenyl group, 4-(4′-methylphenyl)phenyl group, 4-(4′-methoxyphenyl)phenyl group, 1-naphthyl group, 2-naphthyl group, 4-ethoxy-1-naphthyl group, 6-methoxy-2-naphthyl group or 7-ethoxy-2-naphthyl group), more preferably hydrogen atom, fluorine atom, chlorine atom, alkyl group having 1 to 10 carbon atoms, alkoxy group having 1 to 10 carbon atoms or aryl group having 6 to 12 carbon atoms, further more preferably hydrogen atom, fluorine atom, chlorine atom, alkyl group having 1 to 6 carbon atoms, alkoxy group having 1 to 6 carbon atoms or carbocyclic aromatic group having 6 to 10 carbon atoms.

Examples of the fluoranthene derivative represented by the formula (10) are as follows.

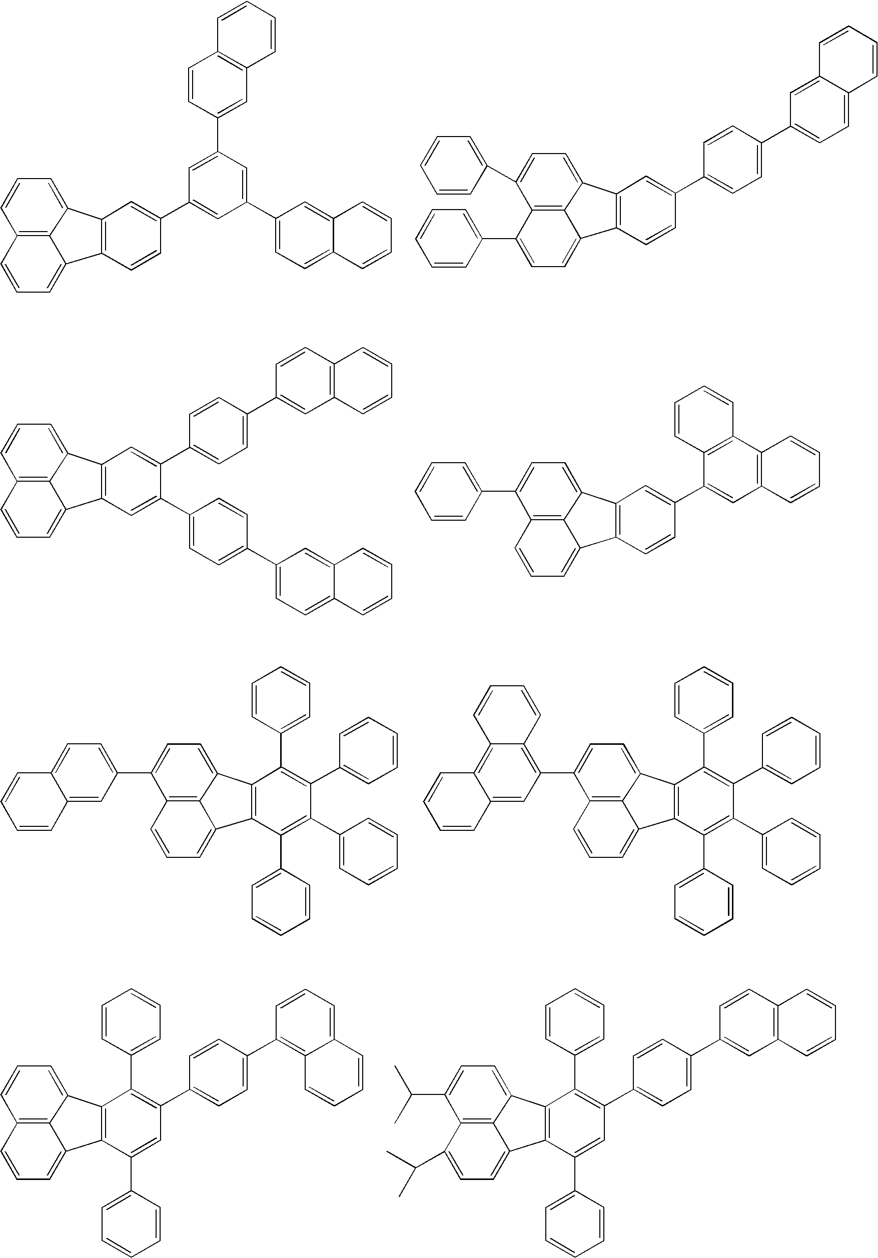

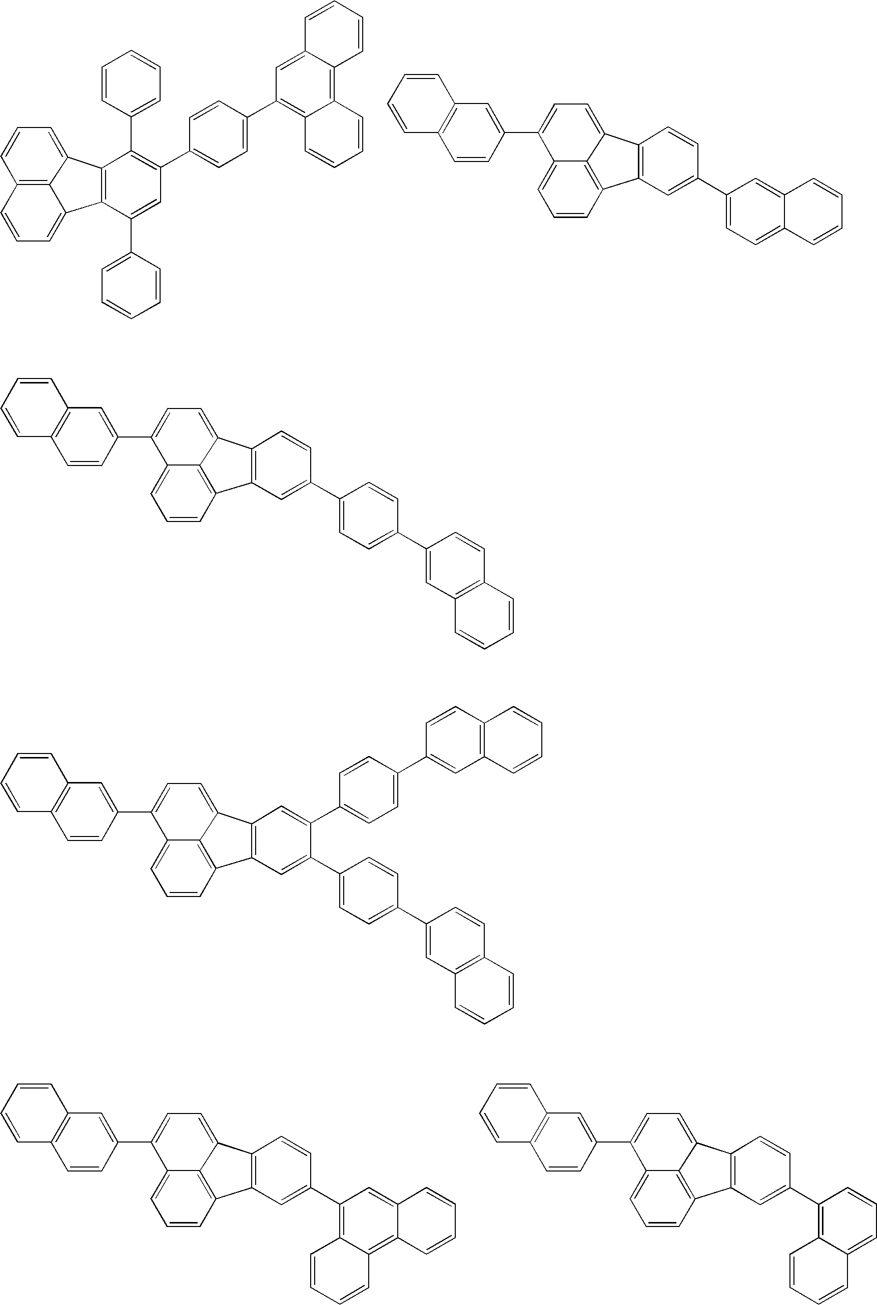

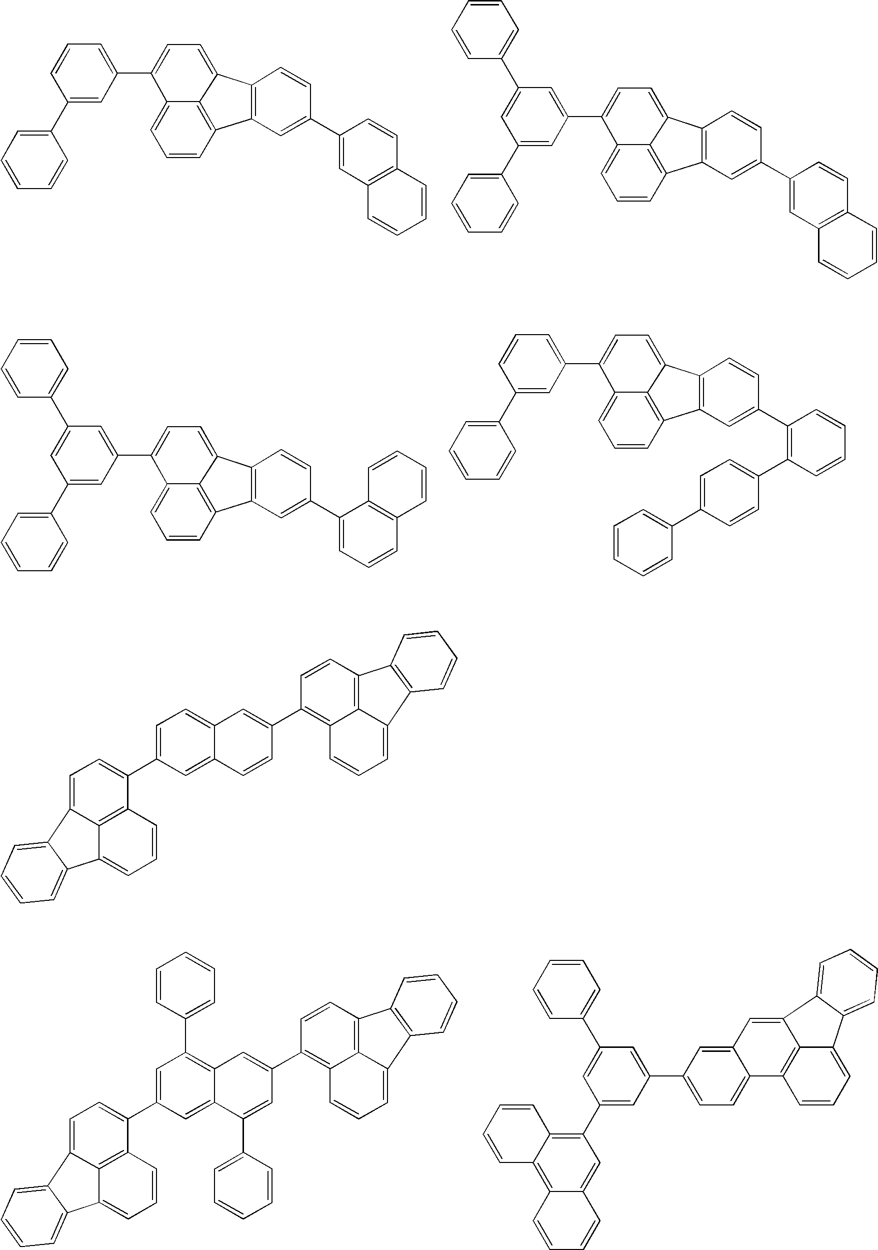

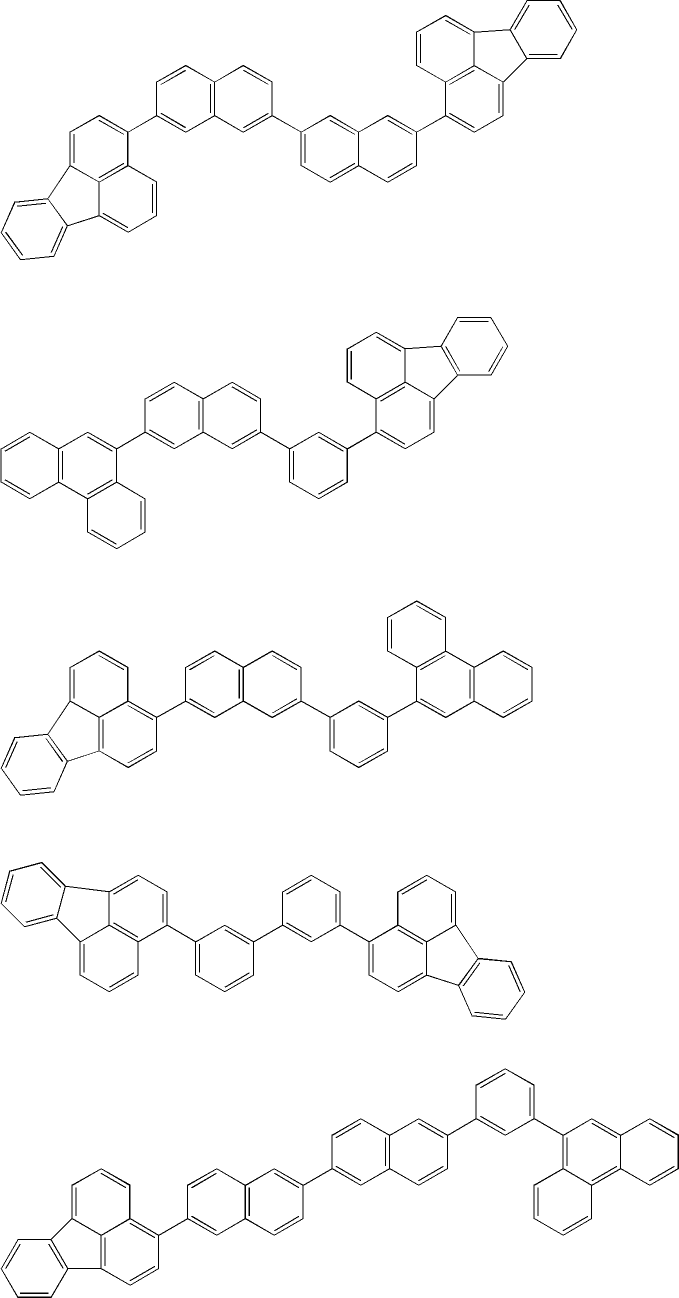

In this exemplary embodiment, examples of the fused polycyclic aromatic hydrocarbon are the elementary substance of benzo[b]fluoranthene represented by the following formula (10B) or its derivative and the elementary substance of benzo[k]fluoranthene represented by a formula (10C) or its derivative.

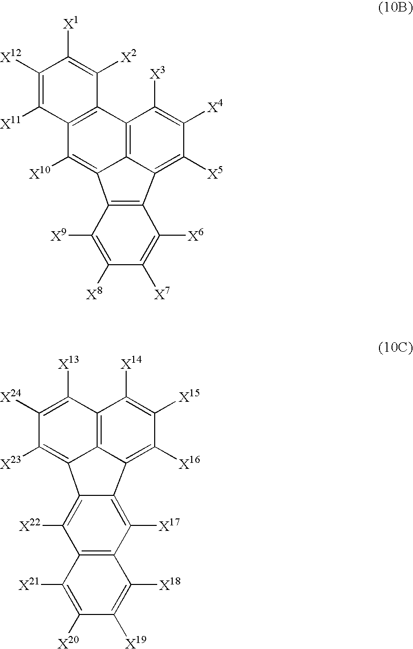

In the formulae (10B) and (10C), X¹ to X²⁴ each represent a hydrogen atom, halogen atom, linear, branched or cyclic alkyl group, linear, branched or cyclic alkoxy group, or substituted or unsubstituted aryl group.

The aryl group represents a carbocyclic aromatic group such as a phenyl group and naphthyl group.

X¹ to X²⁴ each preferably represent a hydrogen atom, halogen atom (such as fluorine atom, chlorine atom or bromine atom), linear, branched or cyclic alkyl group having 1 to 16 carbon atoms (such as methyl group, ethyl group, n-propyl group, isopropyl group, n-butyl group, isobutyl group, sec-butyl group, tert-butyl group, n-pentyl group, isopentyl group, neopentyl group, tert-pentyl group, cyclopentyl group, n-hexyl group, 3,3-dimethylbutyl group, cyclohexyl group, n-heptyl group, cyclohexylmethyl group, n-octyl group, tert-octyl group, 2-ethylhexyl group, n-nonyl group, n-decyl group, n-dodecyl group, n-tetradecyl group or n-hexadecyl group), linear, branched or cyclic alkoxy group having 1 to 16 carbon atoms (such as methoxy group, ethoxy group, n-propoxy group, isopropoxy group, n-butoxy group, isobutoxy group, sec-butoxy group, n-pentyloxy group, neopentyloxy group, cyclopentyloxy group, n-hexyloxy group, 3,3-dimethylbutyloxy group, cyclohexyloxy group, n-heptyloxy group, n-octyloxy group, 2-ethylhexyloxy group, n-nonyloxy group, n-decyloxy group, n-dodecyloxy group, n-tetradecyloxy group or n-hexadecyloxy group), or substituted or unsubstituted aryl group having 4 to 16 carbon atoms (such as phenyl group, 2-methylphenyl group, 3-methylphenyl group, 4-methylphenyl group, 4-ethylphenyl group, 4-n-propylphenyl group, 4-isopropylphenyl group, 4-n-butylphenyl group, 4-tert-butylphenyl group, 4-isopentylphenyl group, 4-tert-pentylphenyl group, 4-n-hexylphenyl group, 4-cyclohexylphenyl group, 4-n-octylphenyl group, 4-n-decylphenyl group, 2,3-dimethylphenyl group, 2,4-dimethylphenyl group, 2,5-dimethylphenyl group, 3,4-dimethylphenyl group, 5-indanyl group, 1,2,3,4-tetrahydro-5-naphthyl group, 1,2,3,4-tetrahydro-6-naphthyl group, 2-methoxyphenyl group, 3-methoxyphenyl group, 4-methoxyphenyl group, 3-ethoxyphenyl group, 4-ethoxyphenyl group, 4-n-propoxyphenyl group, 4-isopropoxyphenyl group, 4-n-butoxyphenyl group, 4-n-pentyloxyphenyl group, 4-n-hexyloxyphenyl group, 4-cyclohexyloxyphenyl group, 4-n-heptyloxyphenyl group, 4-n-octyloxyphenyl group, 4-n-decyloxyphenyl group, 2,3-dimethoxyphenyl group, 2,5-dimethoxyphenyl group, 3,4-dimethoxyphenyl group, 2-methoxy-5-methylphenyl group, 3-methyl-4-methoxyphenyl group, 2-fluorophenyl group, 3-fluorophenyl group, 4-fluorophenyl group, 2-chlorophenyl group, 3-chlorophenyl group, 4-chlorophenyl group, 4-bromophenyl group, 4-trifluoromethylphenyl group, 3,4-dichlorophenyl group, 2-methyl-4-chlorophenyl group, 2-chloro-4-methylphenyl group, 3-chloro-4-methylphenyl group, 2-chloro-4-methoxyphenyl group, 4-phenylphenyl group, 3-phenylphenyl group, 4-(4′-methylphenyl)phenyl group, 4-(4′-methoxyphenyl)phenyl group, 1-naphthyl group, 2-naphthyl group, 4-ethoxy-1-naphthyl group, 6-methoxy-2-naphthyl group or 7-ethoxy-2-naphthyl group), more preferably hydrogen atom, fluorine atom, chlorine atom, alkyl group having 1 to 10 carbon atoms, alkoxy group having 1 to 10 carbon atoms or aryl group having 6 to 12 carbon atoms, further more preferably hydrogen atom, fluorine atom, chlorine atom, alkyl group having 1 to 6 carbon atoms, alkoxy group having 1 to 6 carbon atoms or carbocyclic aromatic group having 6 to 10 carbon atoms.

Examples of the benzo[b]fluoranthene derivative represented by the formula (10B) are as follows.

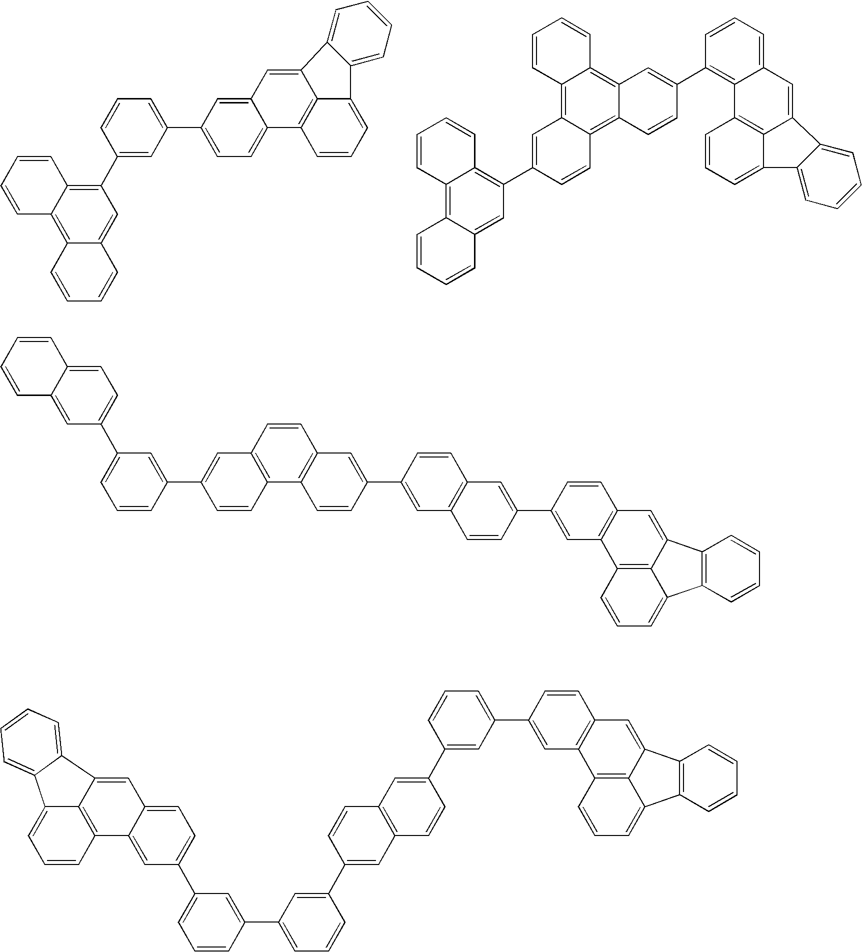

In this exemplary embodiment, the fused polycyclic aromatic hydrocarbon is preferably the elementary substance of triphenylene represented by the following formula (11) or its derivative.

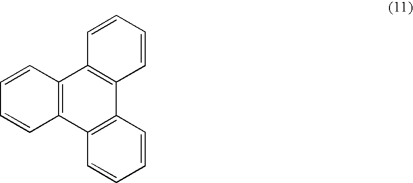

The triphenylene derivative is exemplarily represented by the following formula (11A).

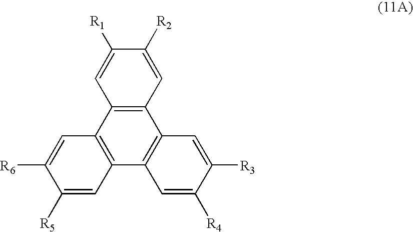

In the formula (11A), R₁ to R₆ each independently represent a hydrogen atom or a substituent formed by one group or a combination of two or more groups selected from a substituted or unsubstituted aryl group having 5 to 30 ring-forming carbon atoms (excluding the number of carbon atoms in the substituent), a branched or linear alkyl group having 1 to 30 carbon atoms and a substituted or unsubstituted cycloalkyl group having 3 to 20 carbon atoms.

Additional examples of the above-described fused aromatic hydrocarbon are the following compounds.

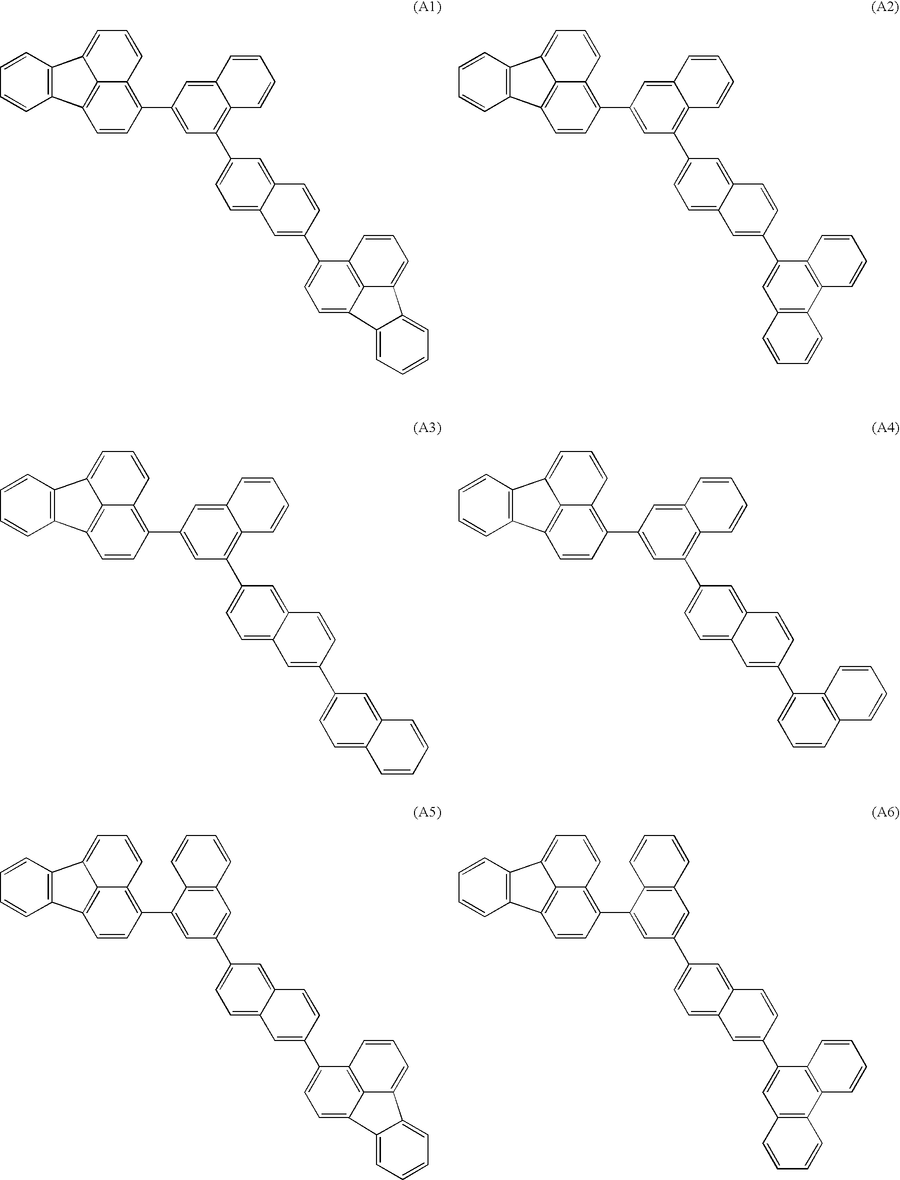

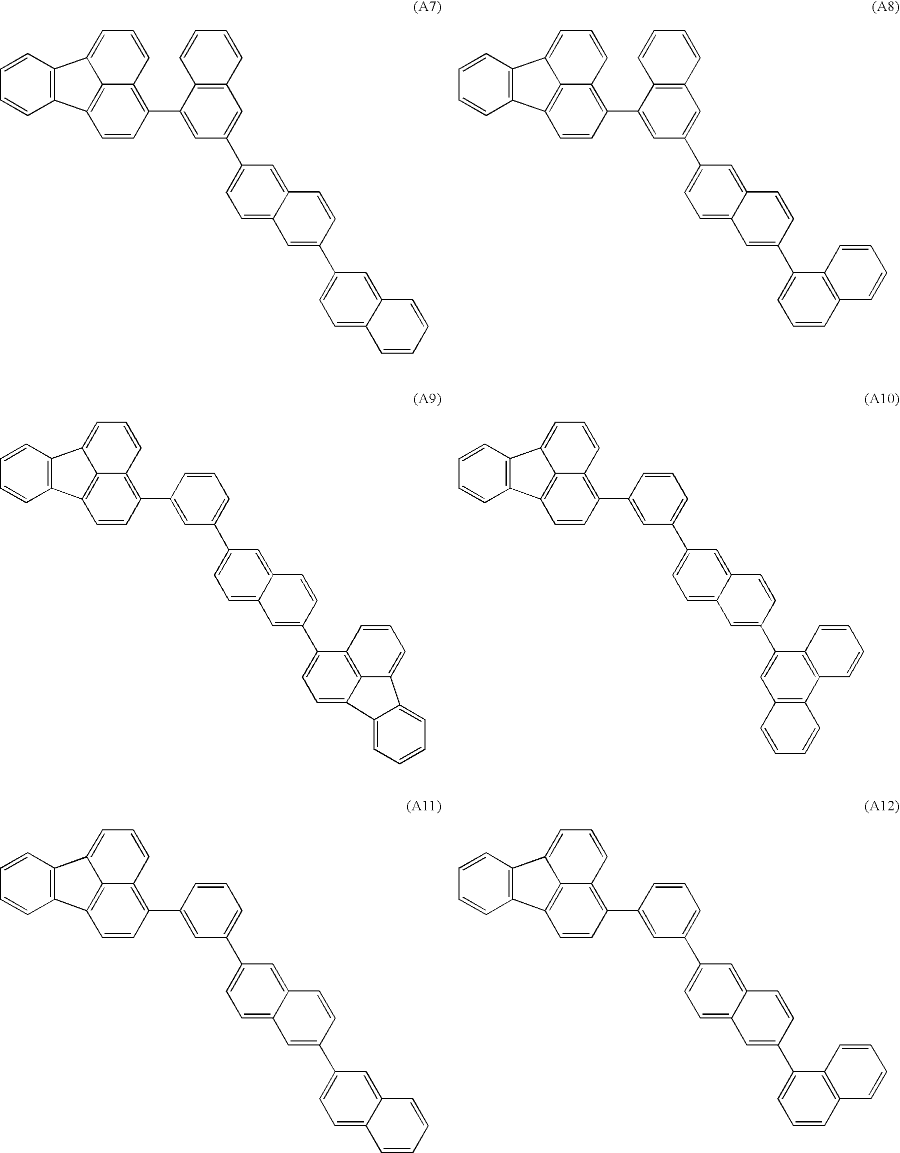

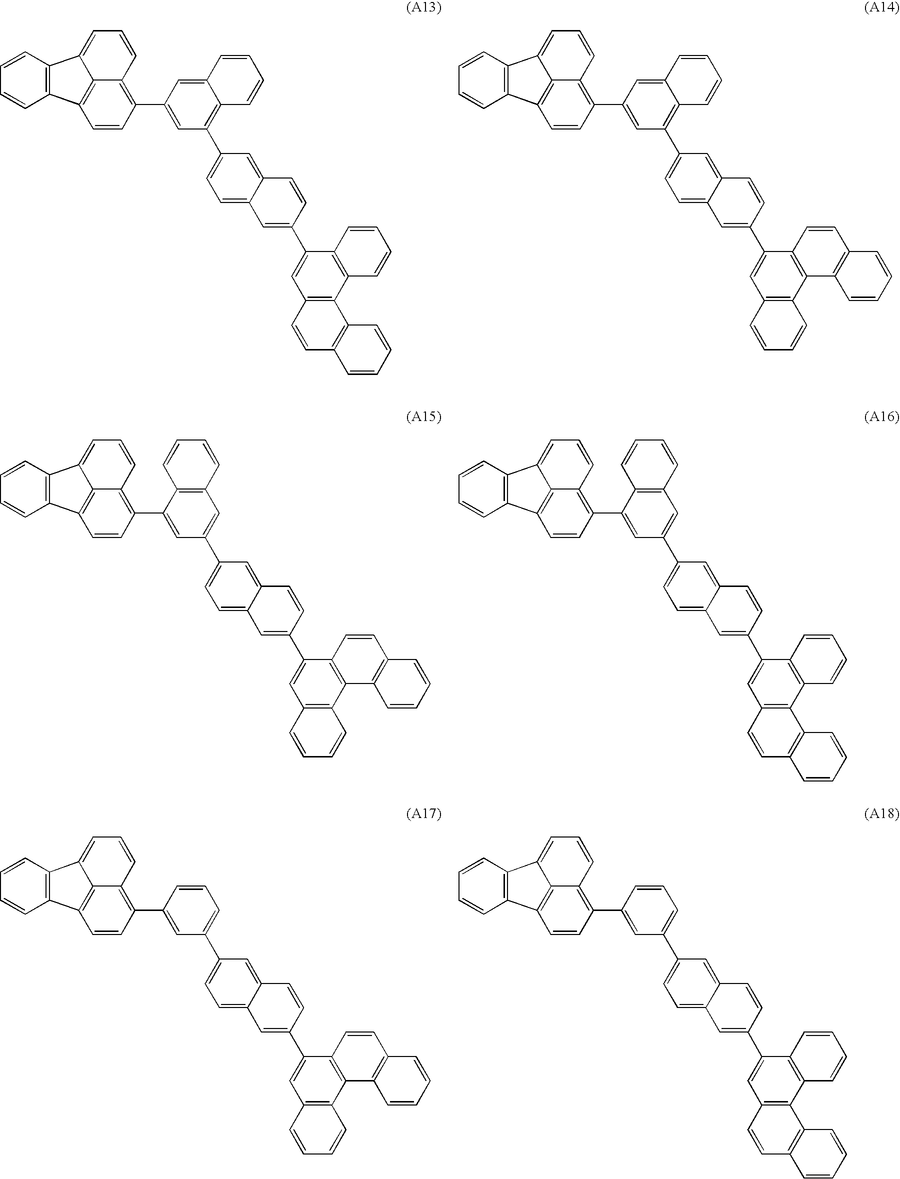

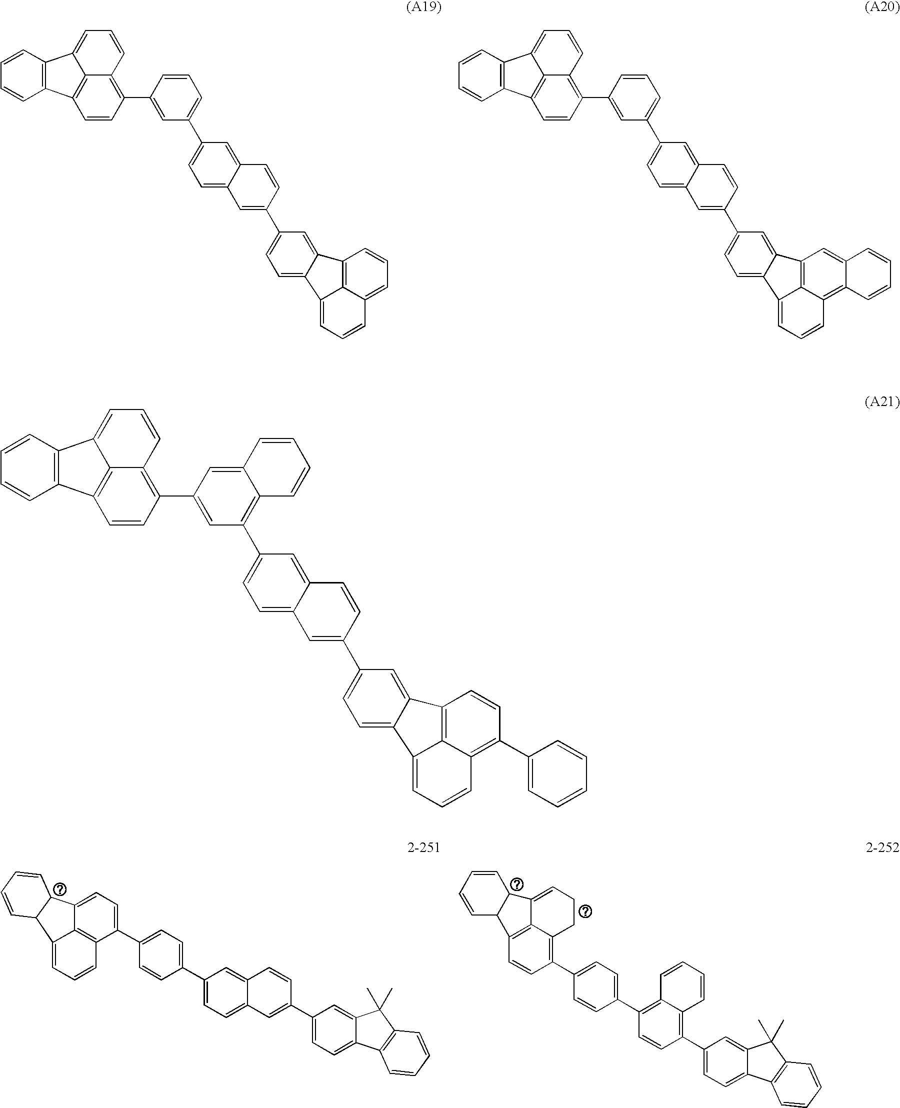

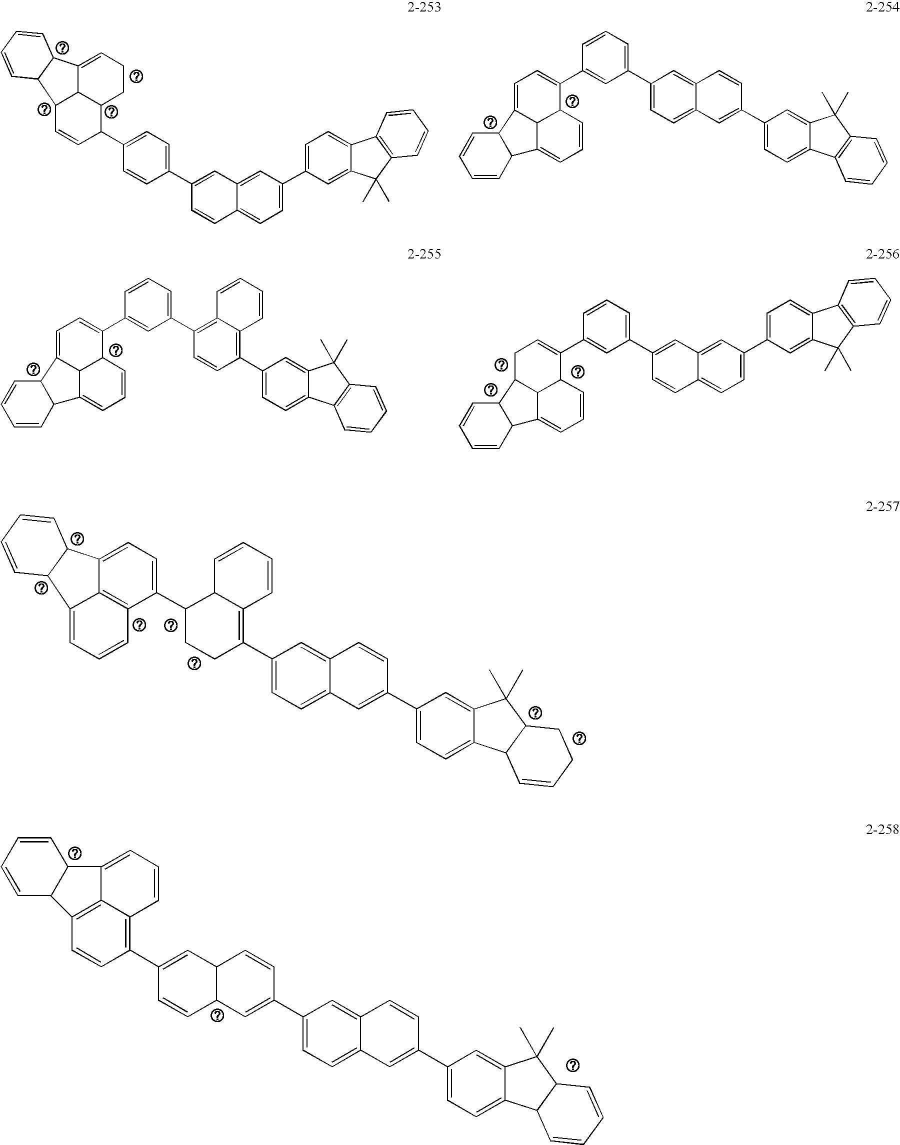

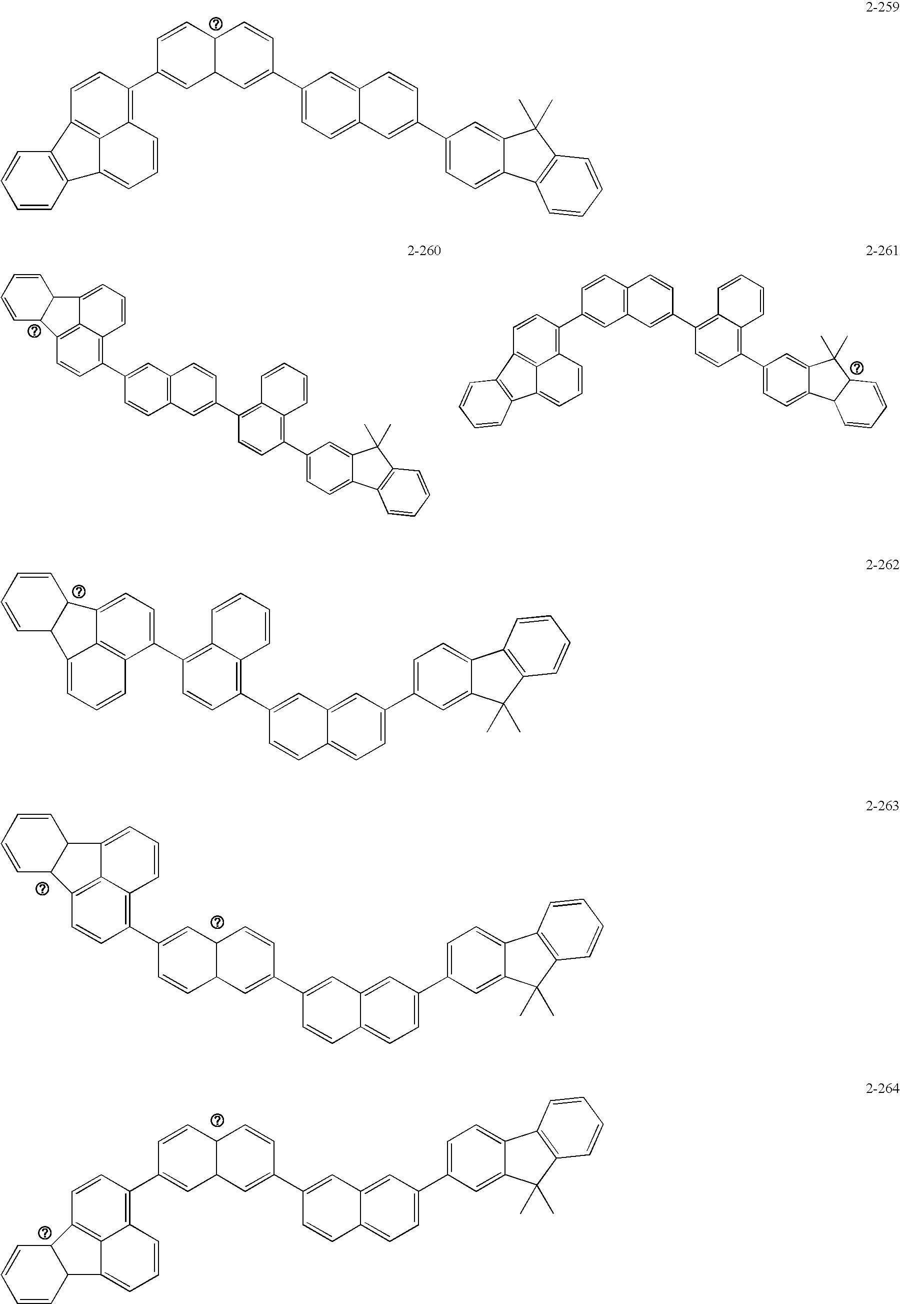

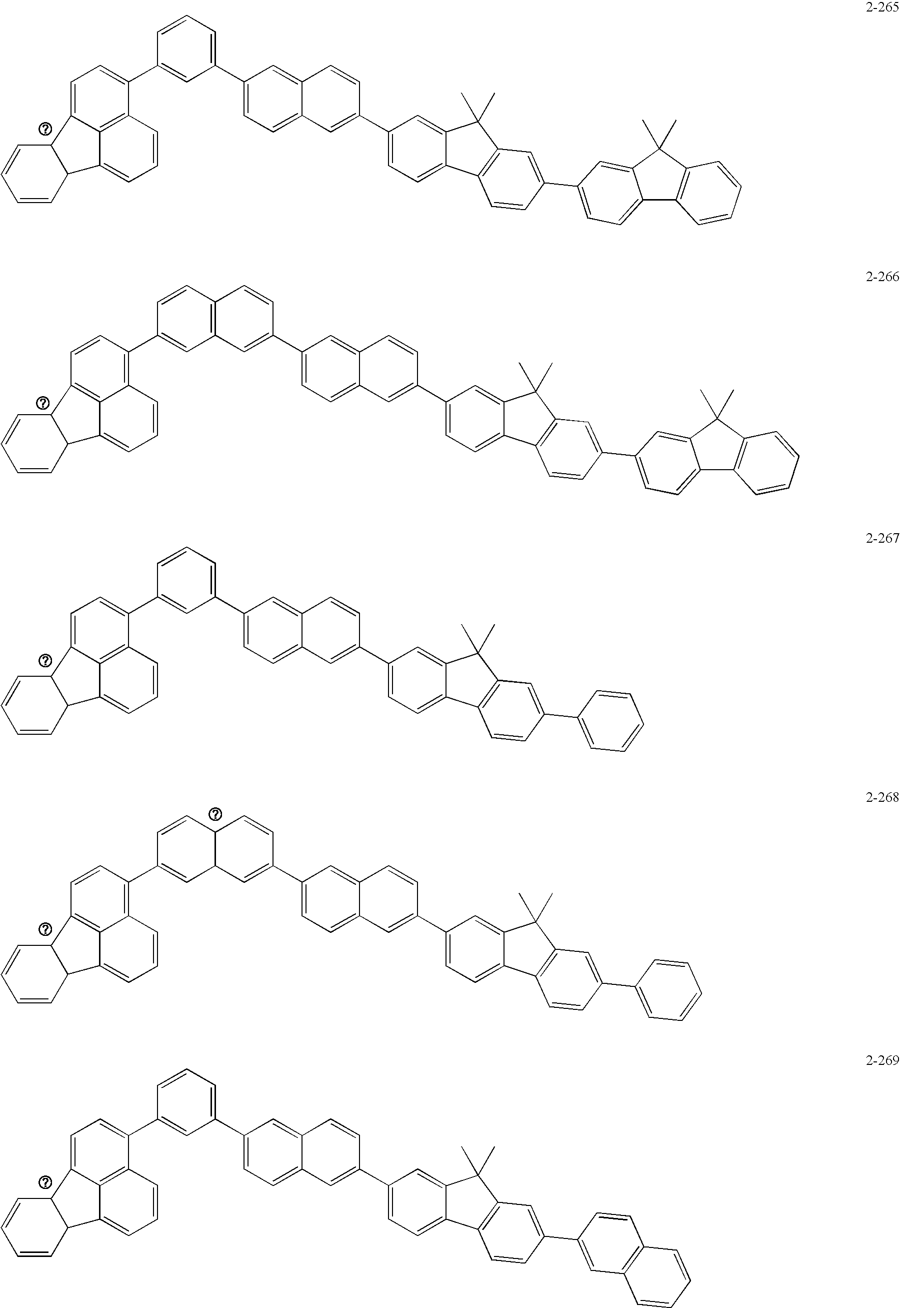

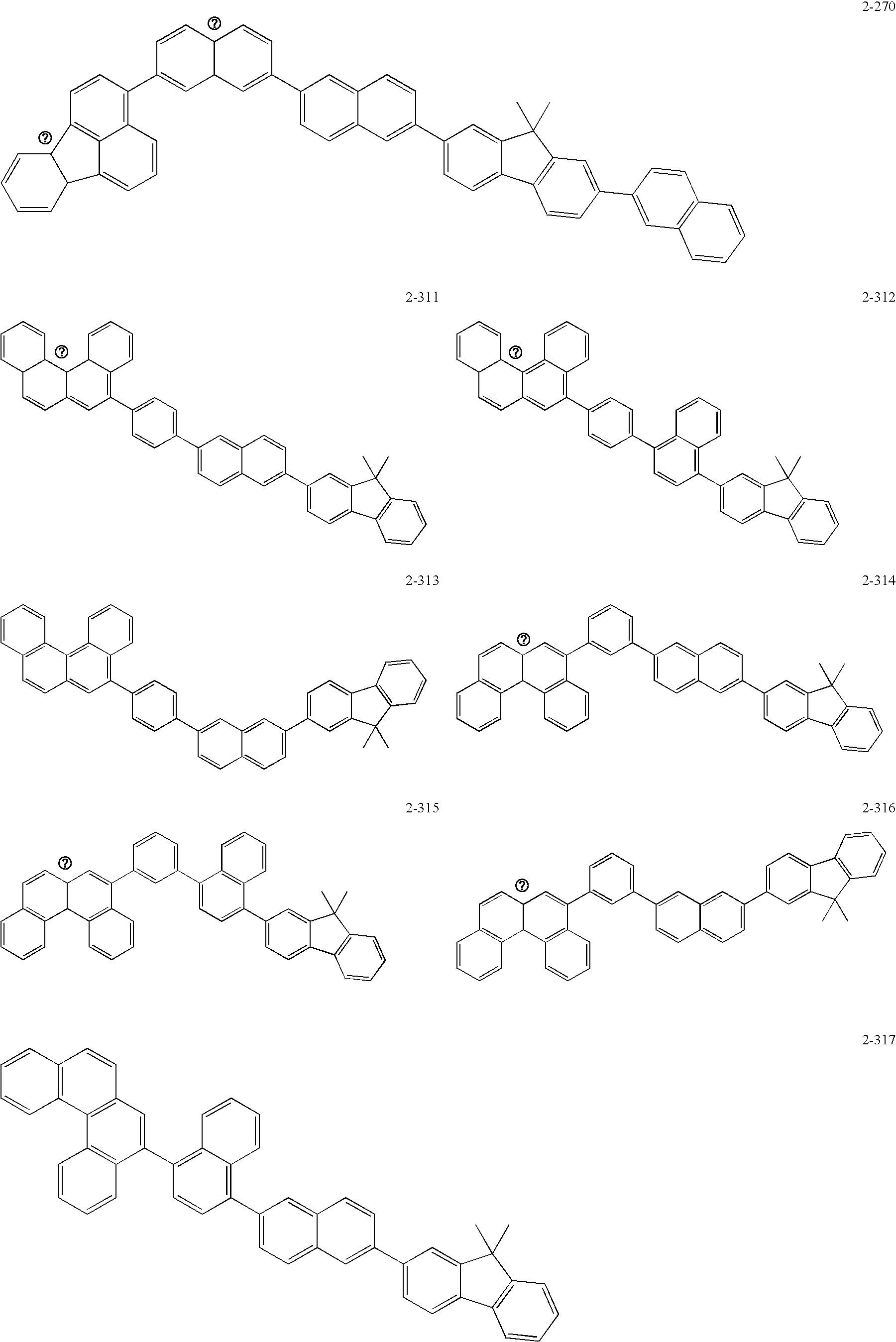

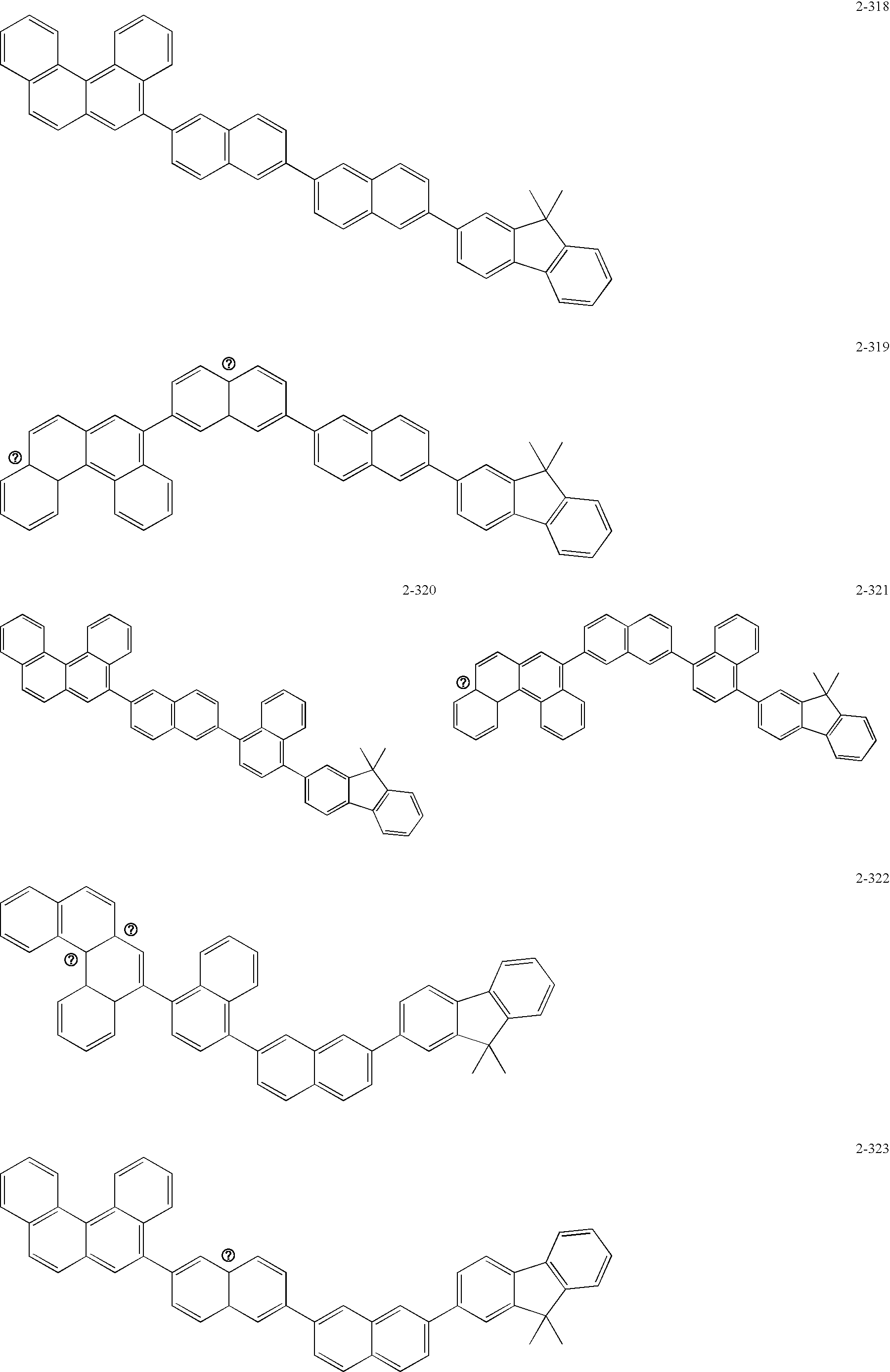

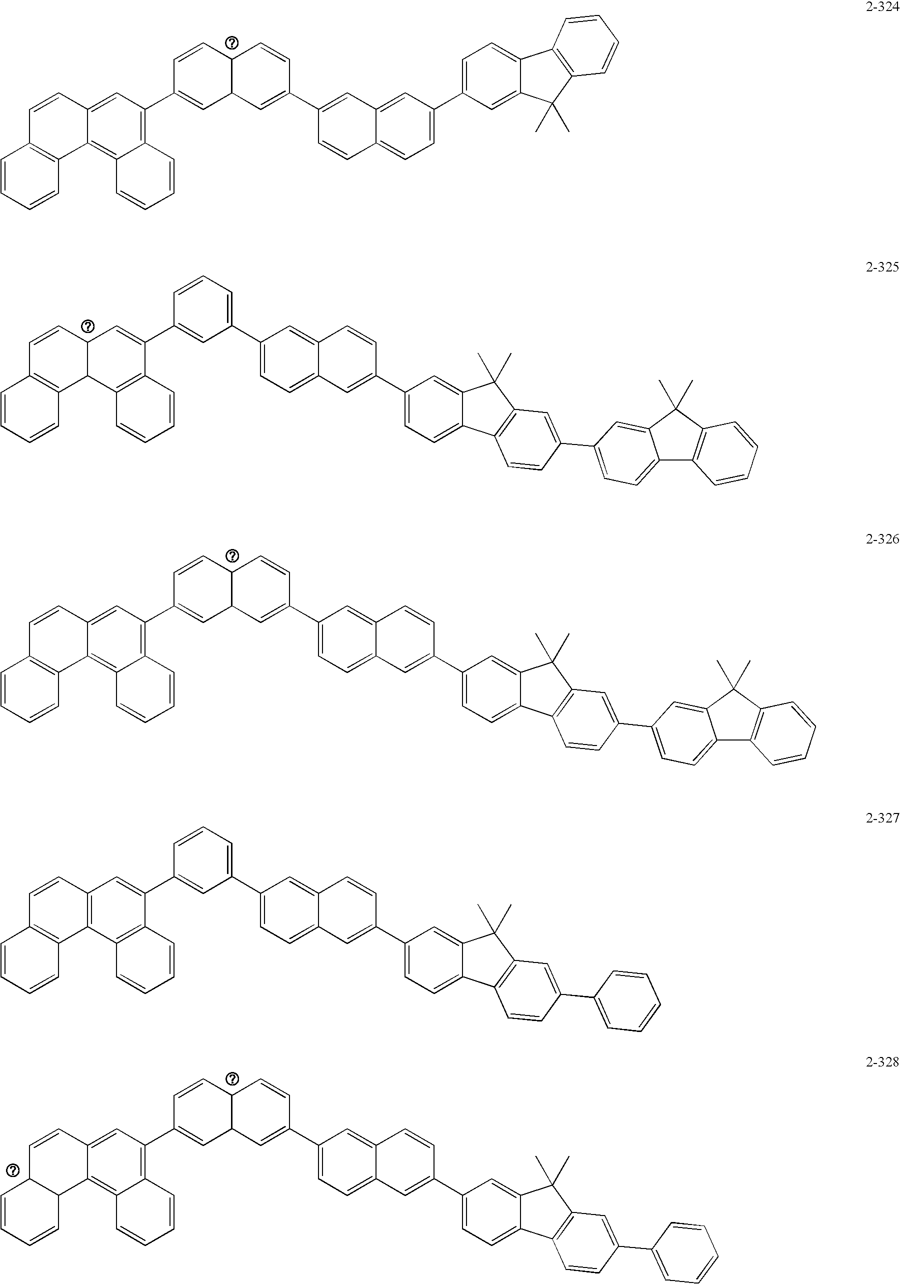

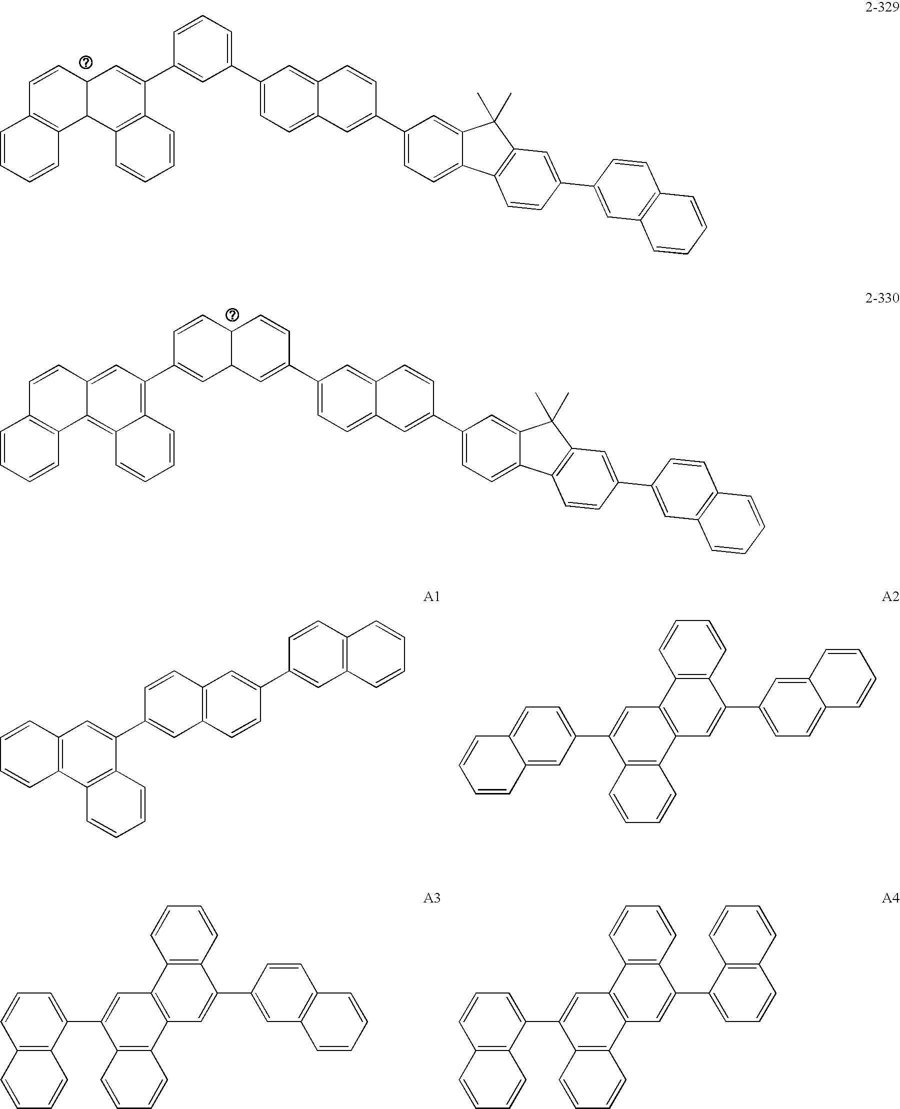

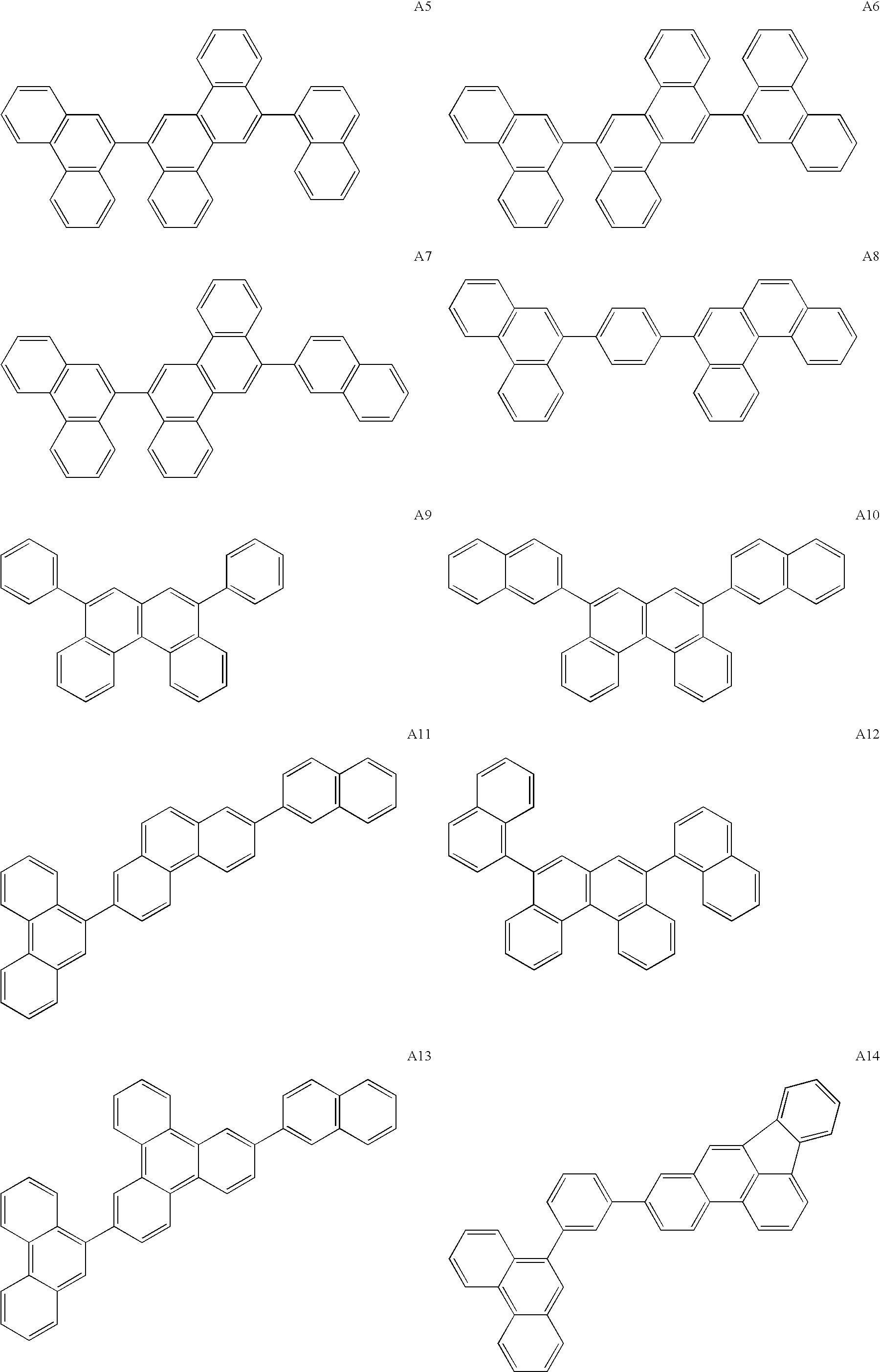

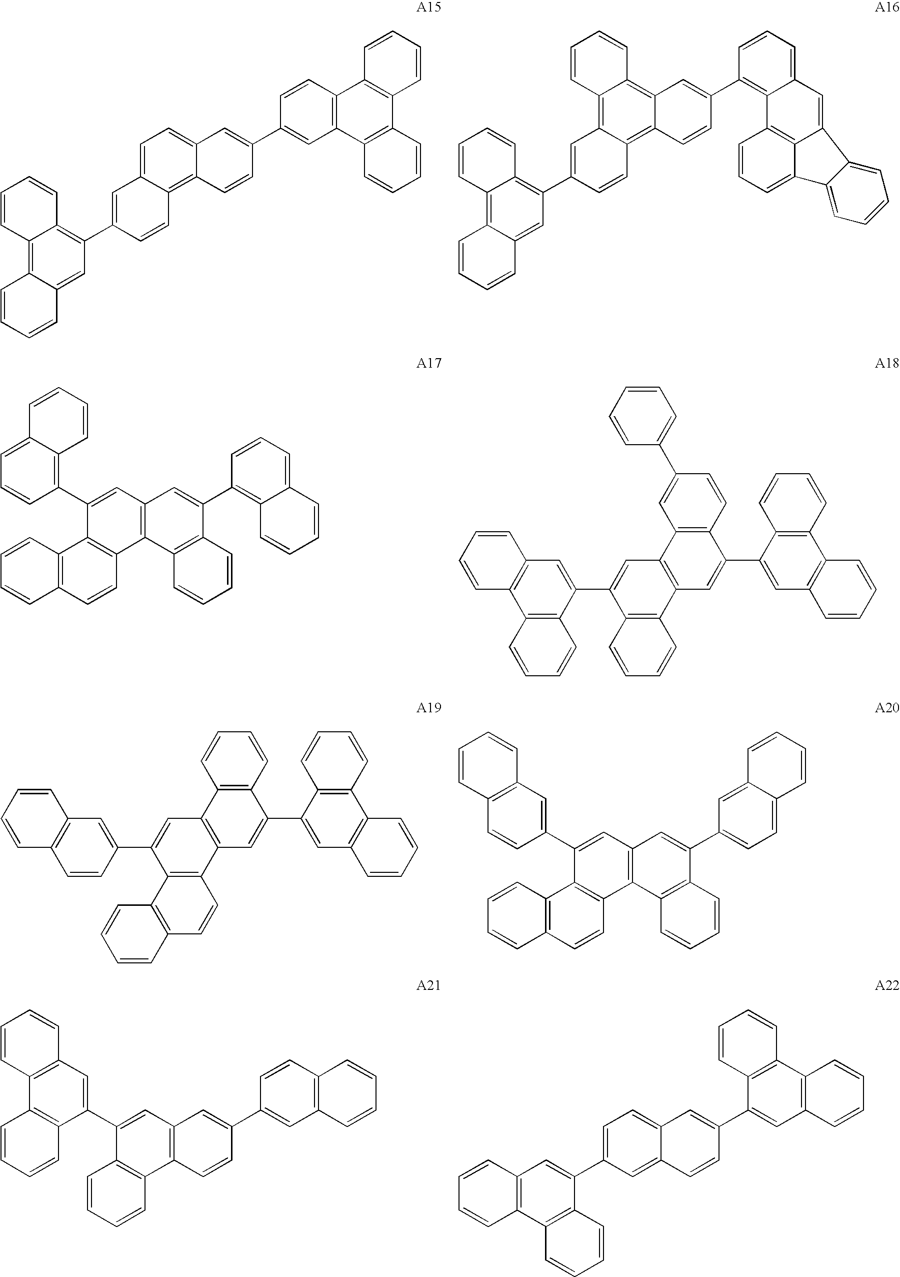

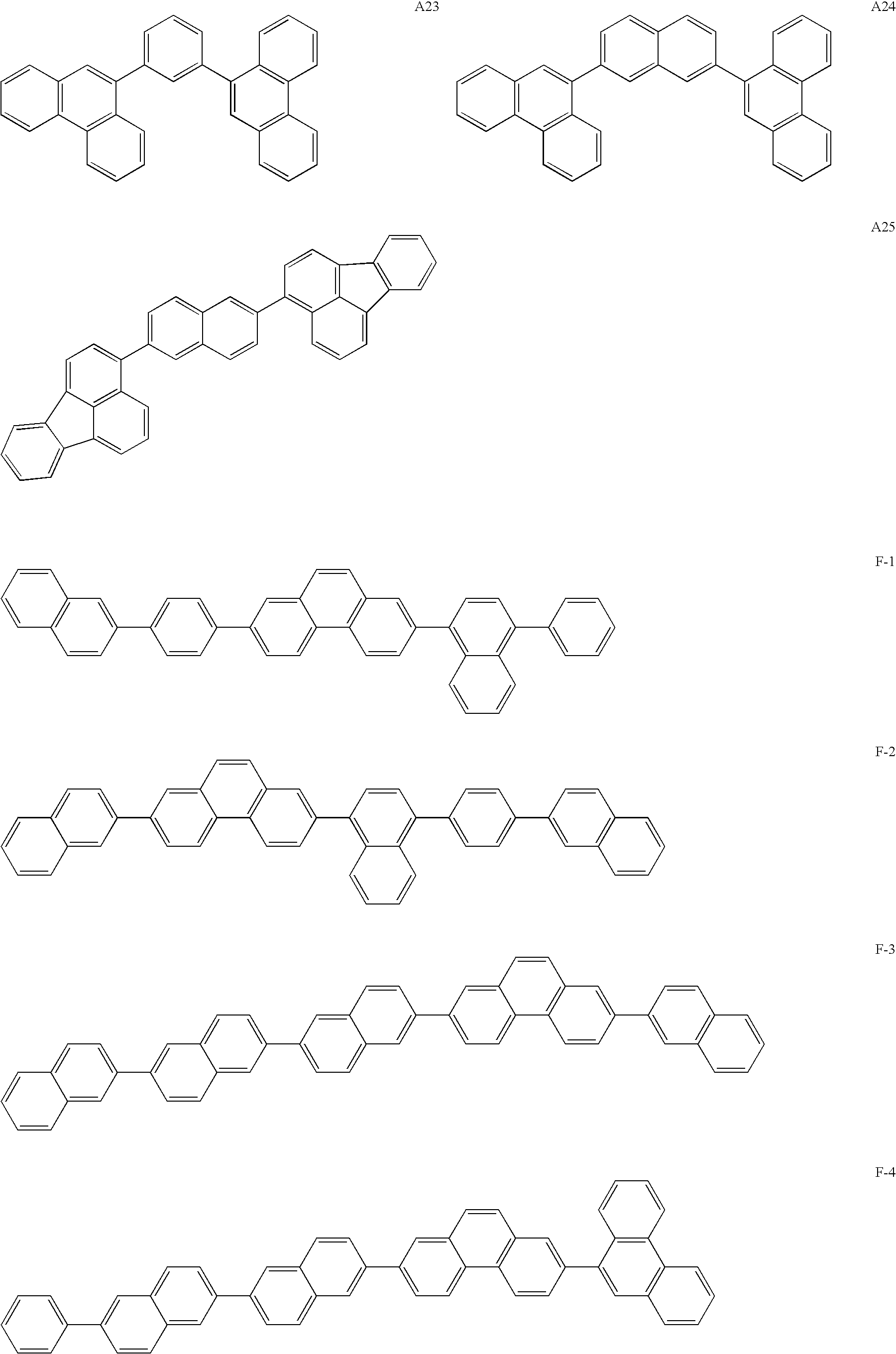

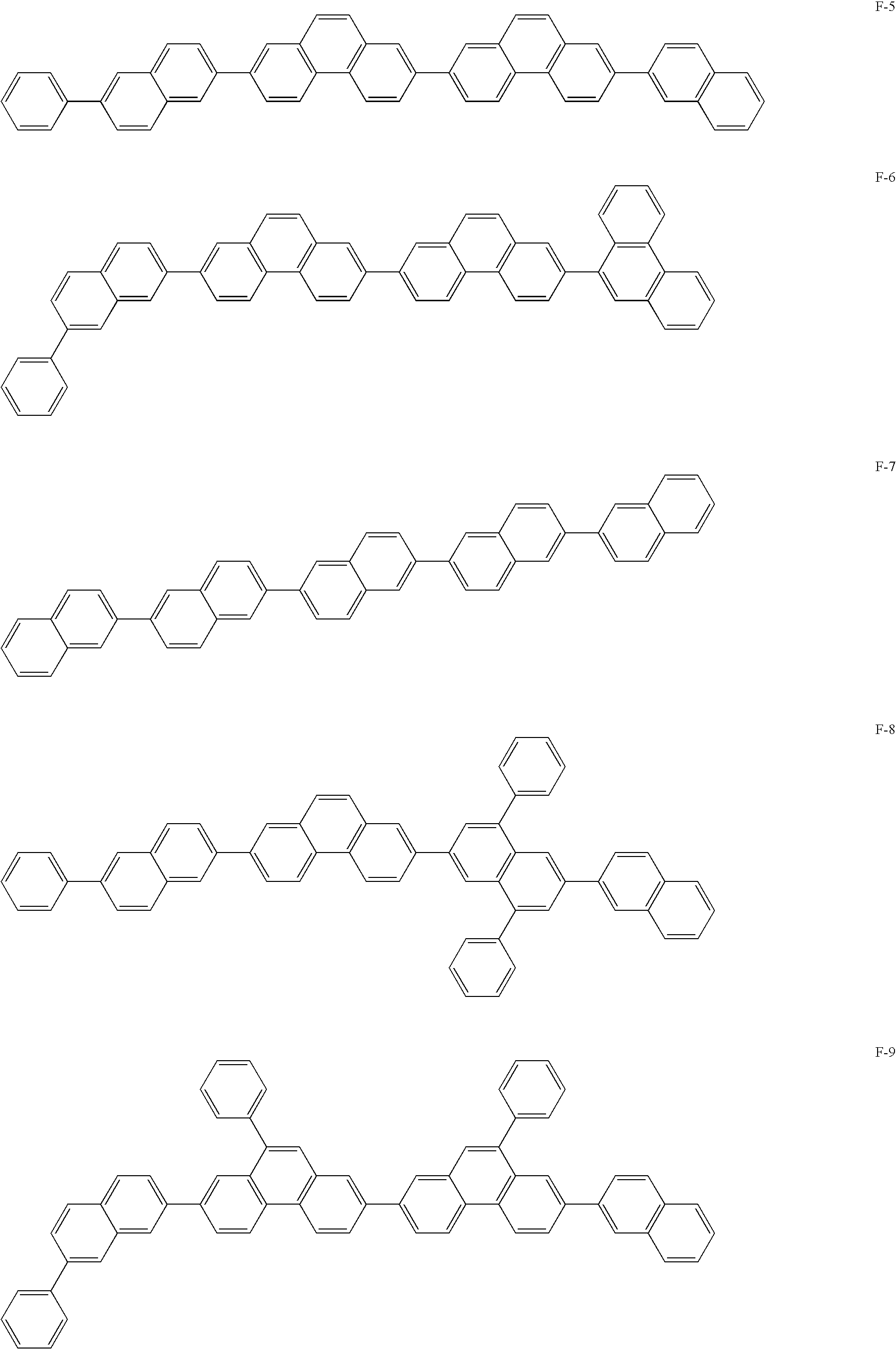

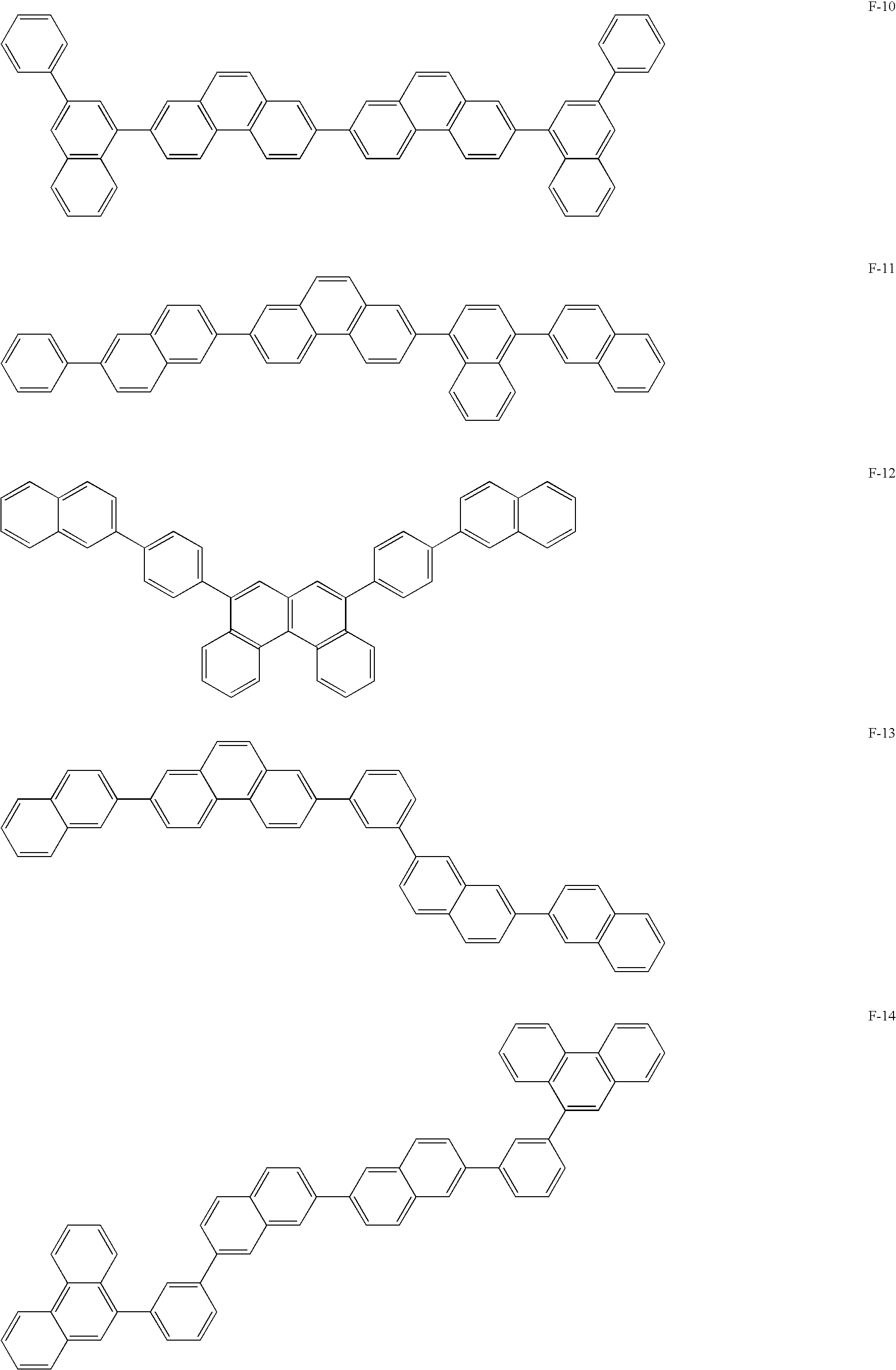

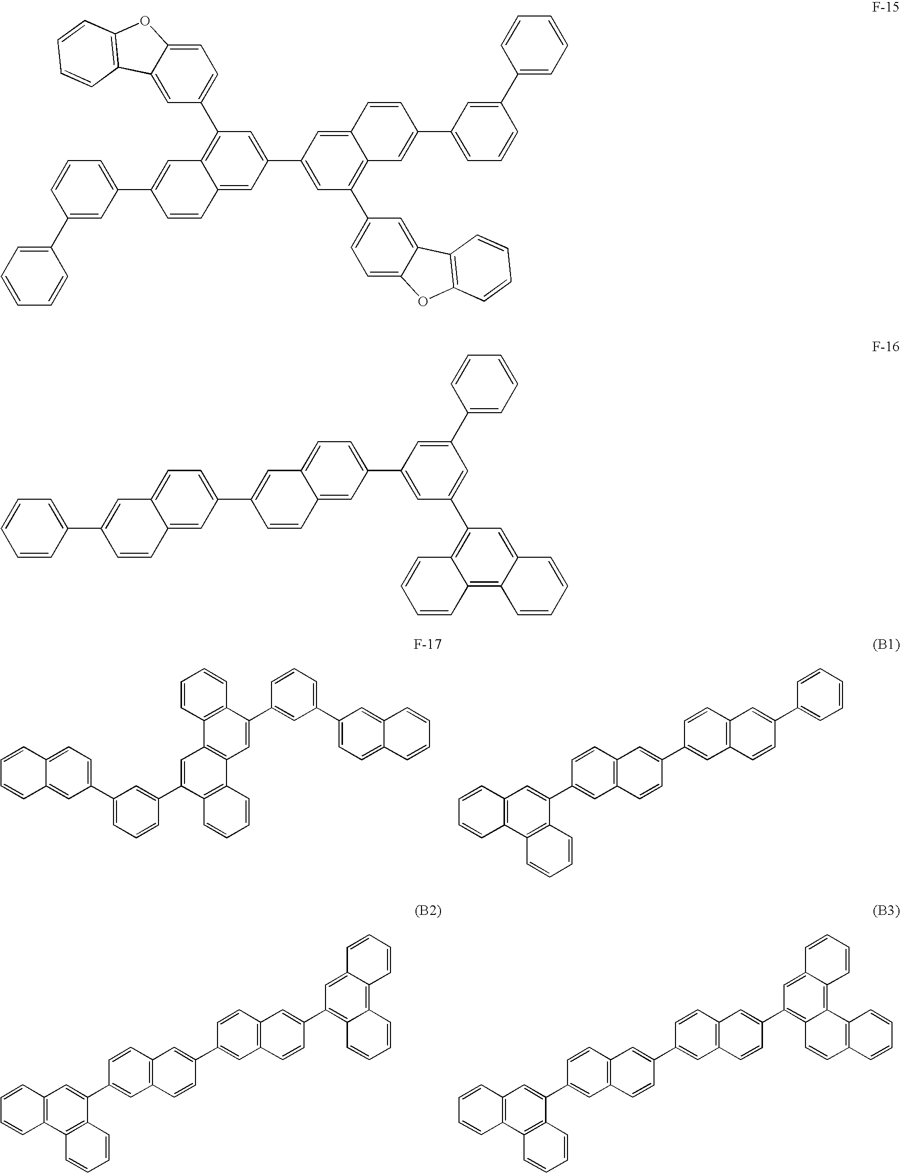

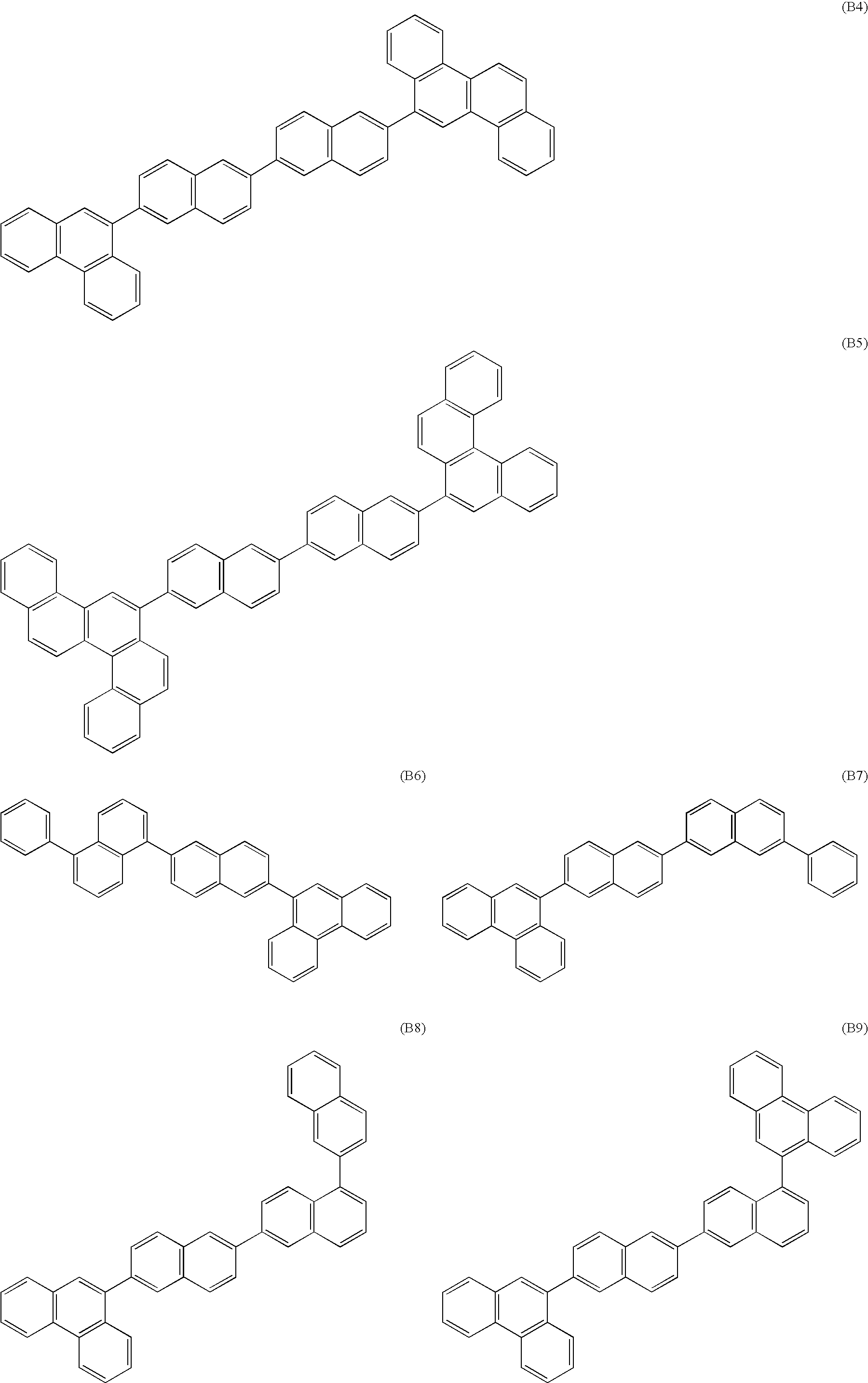

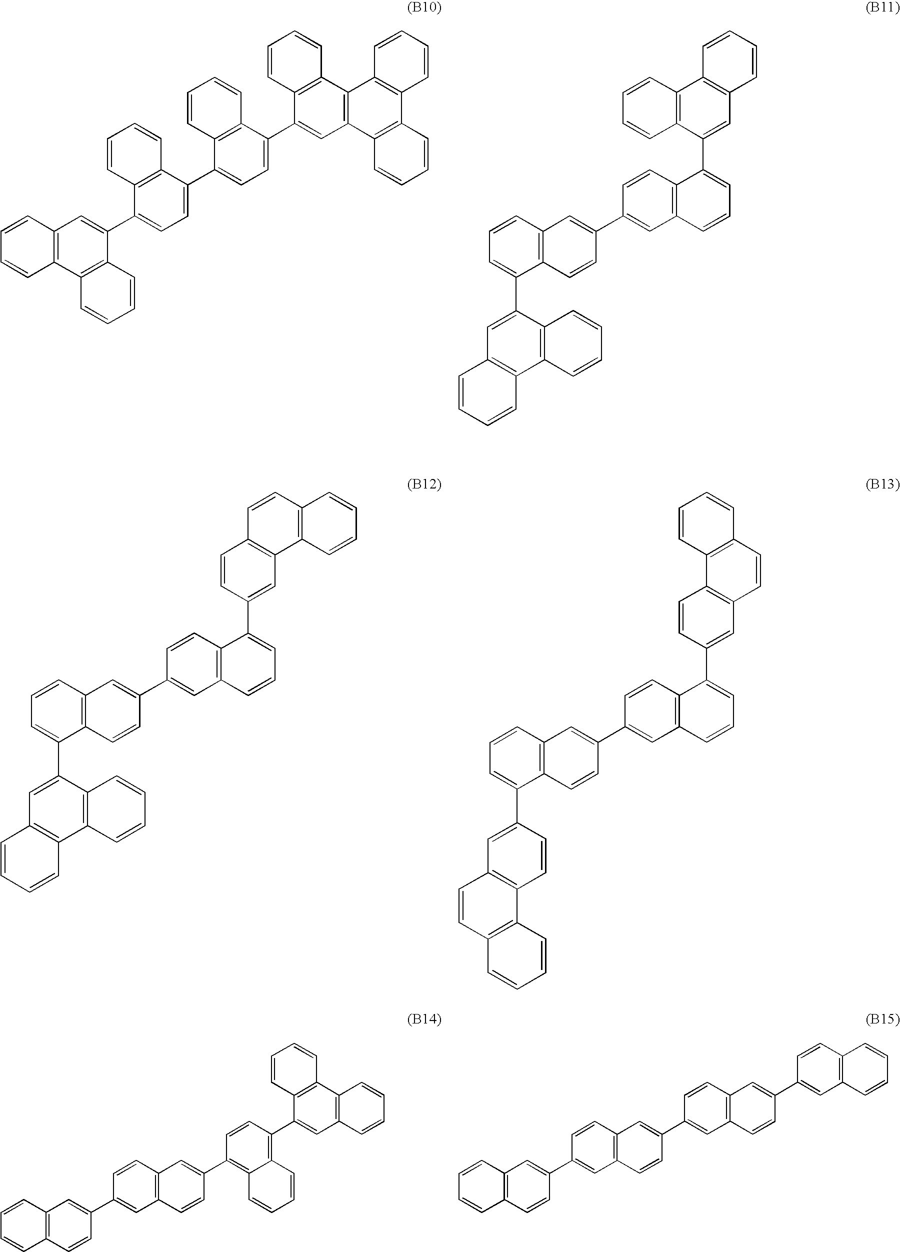

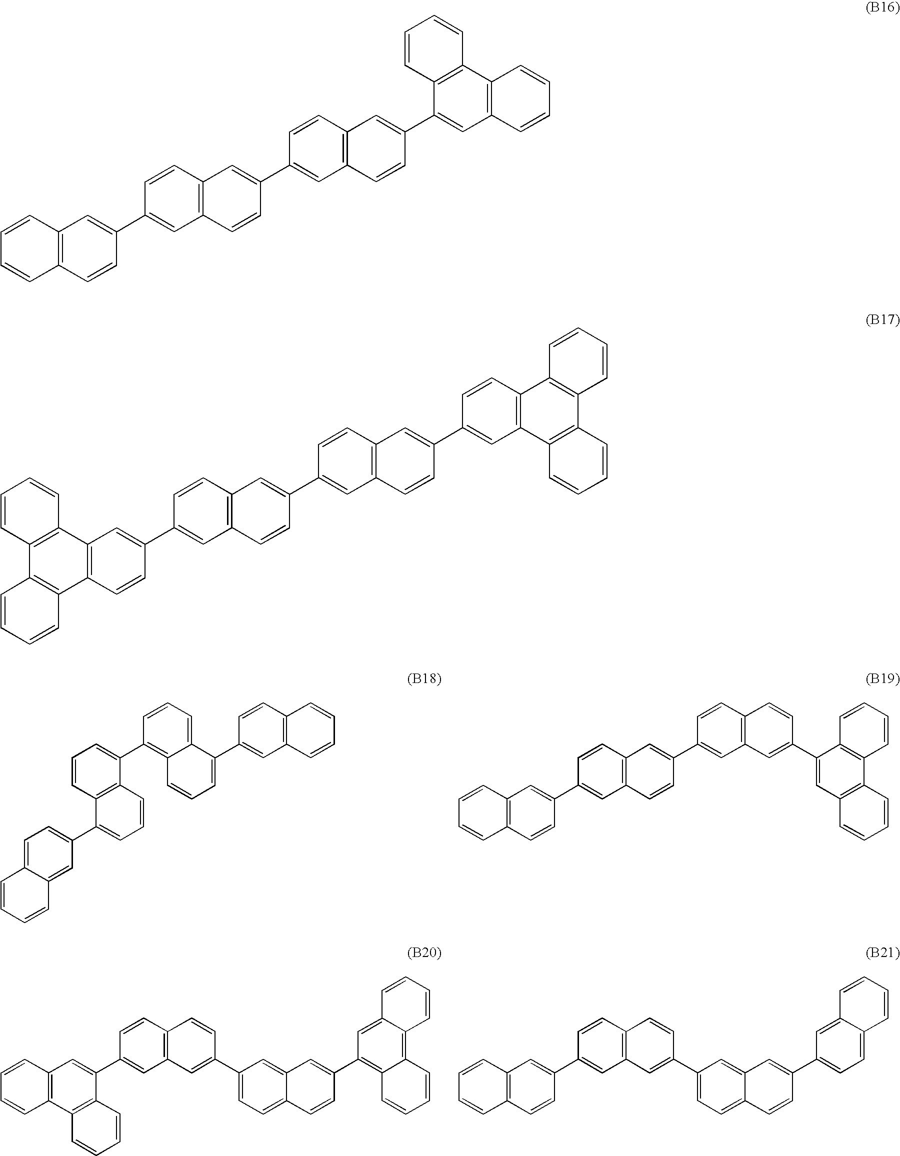

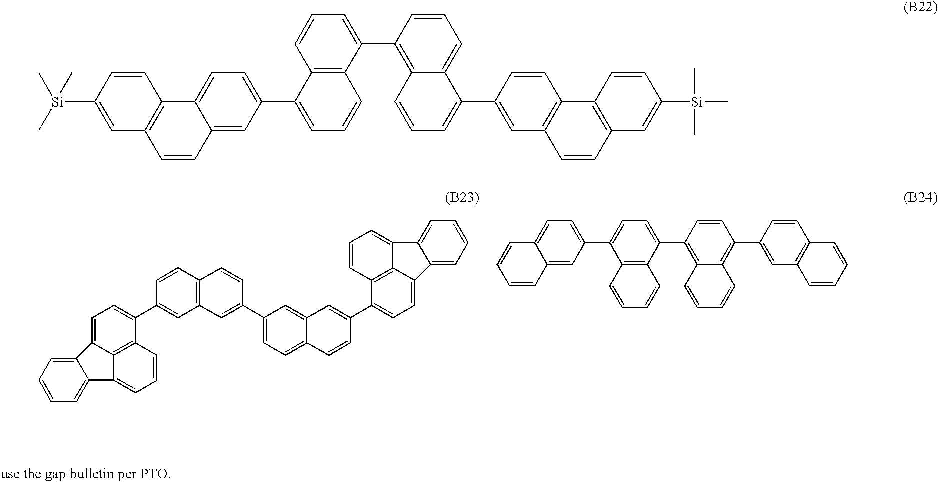

### (Heterocycle-Containing Compound)

The host material contained in the third emitting layer 53 is a heterocycle-containing compound.

The triplet energy of the heterocycle-containing compound is preferably larger than the triplet energy of the host materials for the first emitting layer 51 and the second emitting layer 52. With this arrangement, the triplet energy of the heterocycle-containing compound in the third emitting layer 53 can be dispersed in the fused polycyclic aromatic derivatives in the first emitting layer 51 and the second emitting layer 52, thereby contributing to effective utilization of triplet energy and enhancement of the luminous efficiency.

Further, when the heterocycle-containing compound is a hole-transporting compound, introduction of an electron-transporting host in the second emitting layer 52 can improve the lifetime of the organic EL device 1. Examples of the electron-transporting host are fused polycyclic aromatic hydrocarbon derivatives such as phenanthroline derivatives and metal complexes.

Examples of the heterocycle-containing compound contained in the third emitting layer 53 are a carbazole derivative and azacarbazole derivative represented by the following formulae.

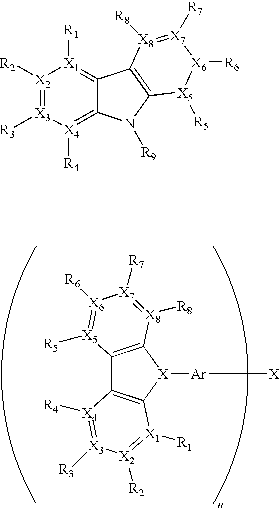

In the above formulae: n is 2 or 3; X₁ to X₈ each represent N or CR; and R₁ to R₈ each represent a substituent and represent a hydrogen atom, alkyl group, aralkyl group, alkenyl group or substituted or unsubstituted aromatic hydrocarbon group.

In addition: Ar represents a substituted or unsubstituted aromatic group; X represents a bonding group and represents N, a substituted or unsubstituted aromatic group or CR; R represents a substituent and represents a hydrogen atom, an alkyl group, an aralkyl group, an alkenyl group, a substituted or unsubstituted aromatic hydrocarbon group or a substituted or unsubstituted aromatic heterocyclic group. In the above formula, Ar and Ar may be directly bonded together.

Examples of such a compound are shown below.

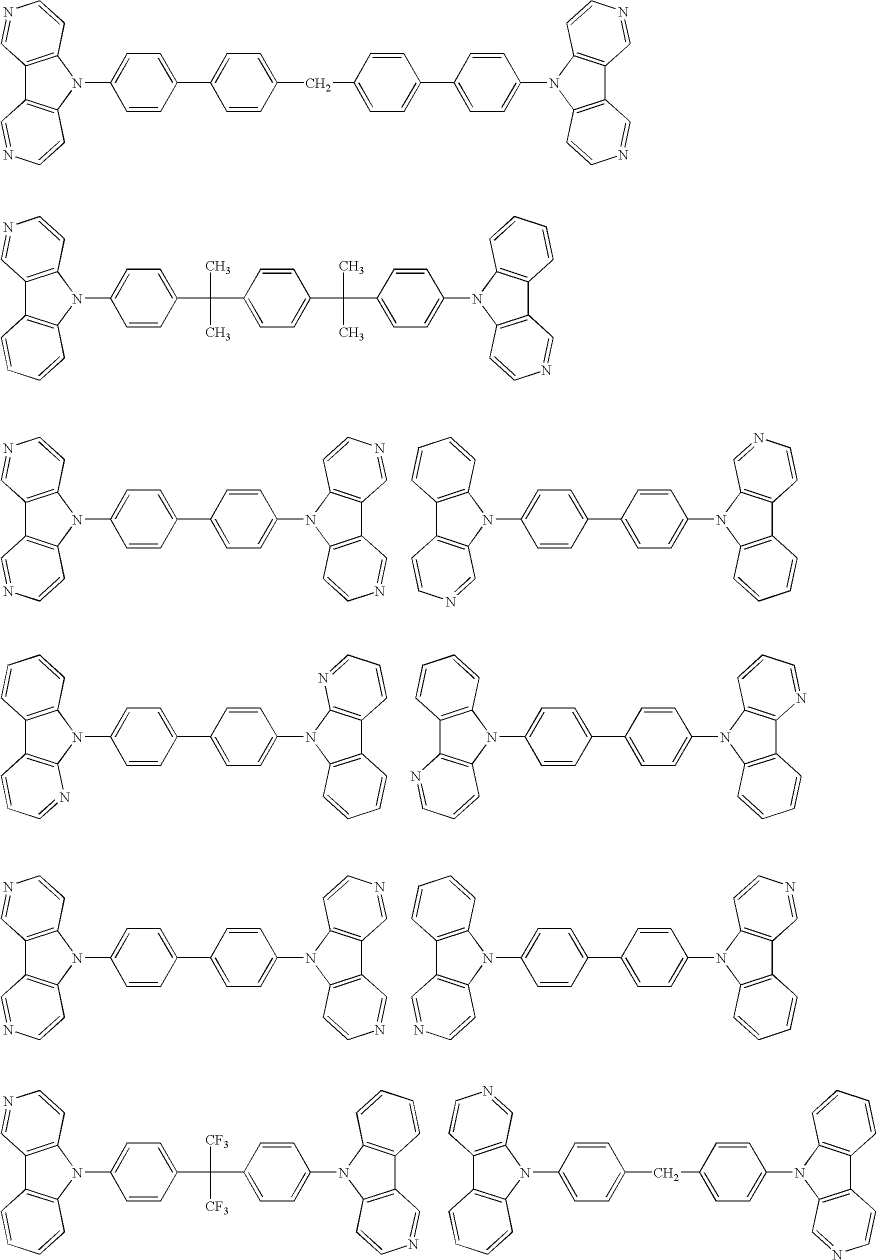

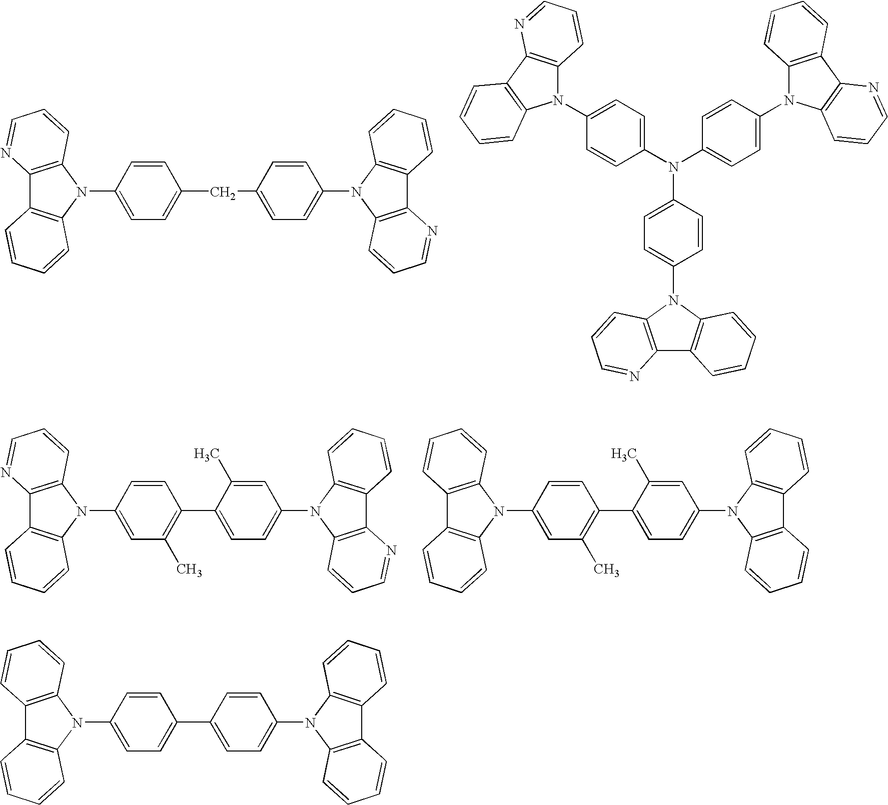

Further examples of the heterocycle-containing compound are carbazole derivatives represented by the following formulae.

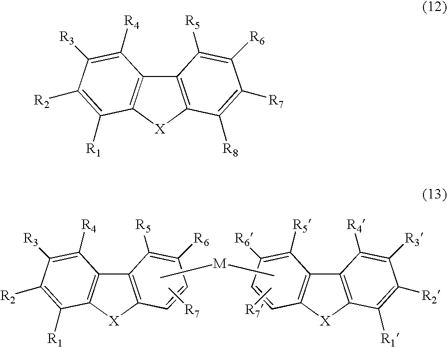

In the formulae (12) and (13), X represents N or O. R₁, R₂, R₃, R₄, R₅, R₆, R₇, R₈, R_{1′}, R_{2′}, R_{3′}, R_{4′}, R_{5′}, R_{6′} and R_{7′} each independently represent H, —OR₂₀₁, —SR₂₀₂ and/or —NR₂₀₃R₂₀₄, C₁-to-C₂₄ alkyl, E-substituted and/or D-interrupted C₁-to-C₂₄ alkyl, C₂-to-C₁₈ alkenyl, E-substituted C₂-to-C₁₈ alkenyl, C₃-to-C₈ cycloalkyl, G-substituted C₃-to-C₈ cycloalkyl, aryl, G-substituted aryl, heteroaryl or G-substituted heteroaryl, silyl,

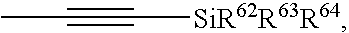

—CN, cyclic ether, —B(OR⁶⁵)₂ and/or halogen (particularly, fluorine). Alternatively, adjoining two of R¹ and R², R² and R³, R³ and R⁴, R⁵ and R⁶, R⁶ and R⁷, R⁷ and R⁸, R^{1′} and R^{2′}, R^{2′} and R^{3′}, R^{3′} and R^{4′}, R^{5′} and R^{6′}, R^{6′} and R^{7′}, and R^{7′} and/or R^{8′} form the following group (13a) or (13b) together.

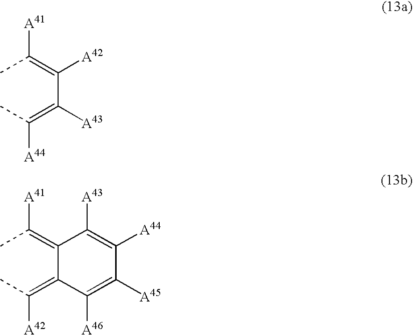

In the formulae (13a) and (13b), A⁴¹, A⁴², A⁴³, A⁴⁴, A⁴⁵ and A⁴⁶ each independently represent H, halogen, hydroxy, C₁-to-C₂₄ alkyl, E-substituted and/or D-interrupted C₁-to-C₂₄ alkyl, C₁-to-C₂₄ perfluoroalkyl, C₅-to-C₁₂ cycloalkyl, G-substituted and/or S—, —O— or —NR⁵— interrupted C₅-to-C₁₂ cycloalkyl, C₅-to-C₁₂ cycloalkoxy, E-substituted C₅-to-C₁₂ cycloalkoxy, C₆-to-C₂₄ aryl, G-substituted C₆-to-C₂₄ aryl, C₂-to-C₂₀ heteroaryl, G-substituted C₂-to-C₂₀ heteroaryl, C₂-to-C₂₄ alkenyl, C₂-to-C₂₄ alkynyl, C₁-to-C₂₄ alkoxy, E-substituted and/or D-interrupted C₁-to-C₂₄ alkoxy, C₇-to-C₂₅ aralkyl, G-substituted C₇-to-C₂₅ aralkyl, C₇-to-C₂₅ aralkoxy, E-substituted C₇-to-C₂₅ aralkoxy or —CO—R⁸.

M is: a bonding group such as single bond (direct bond), —CO—, —COO—, —S—, —SO—, —SO₂— and —O—; C₁-to-C₁₂ alkylene, C₂-to-C₁₂ alkenylene or C₂-to-C₁₂ alkynylene interrupted by one or more —O— or —S— depending on conditions; or a group [M¹]ₙ. Herein, n is an integer of 1 to 20. M¹ is: arylene or heteroarylene substituted by G depending conditions. In particular, M¹ naphthylene, biphenylene, styrylene, anthrylene or pyrenylene substituted by C₁-to-C₁₂ alkyl, halogen, —OR²⁰¹, —SR²⁰² and/or —NR²⁰³R²⁰⁴ depending on conditions (in the formula, R²⁰¹ is hydrogen, C₁-to-C₂₄ alkyl, E-substituted and/or D-interrupted C₁-to-C₂₄ alkyl); C₂-to-C₁₂ alkenyl, C₃-to-C₆ alkenoyl, C₃-to-C₈ cycloalkyl or benzoyl substituted or unsubstituted by one group or more of C₁-to-C₆ alkyl, halogen, —OH and/or C₁-to-C₄ alkoxy depending conditions; or C₆-to-C₁₄ aryl substituted or unsubstituted by halogen, —OH, C₁-to-C₁₂ alkyl, C₁-to-C₁₂ alkoxy, phenoxy, C₁-to-C₁₂ alkylsulfanyl, phenylsulfanyl, —N(C₁-to-C₁₂ alkyl)₂ and/or diphenylamino depending on conditions (particularly phenyl, naphthyl, phenanthryl, anthranil or pyrenyl).

R²⁰² is: C₁-to-C₂₄ alkyl; E-substituted and/or D-interrupted C₁-to-C₂₄ alkyl; C₂-to-C₁₂ alkenyl; C₁-to-C₈ alkanoyl; C₂-to-C₁₂ alkenyl; C₃-to-C₆ alkenoyl; C₃-to-C₈ cycloalkyl or benzoyl substituted or unsubstituted by one group or more of C₁-to-C₆ alkyl, halogen, —OH, C₁-to-C₄ alkoxy or C₁-to-C₄ alkylsufanyl depending on conditions; or C₆-to-C₁₄ aryl substituted or unsubstituted by halogen, C₁-to-C₁₂ alkyl, C₁-to-C₁₂ alkoxy, phenyl-C₁-to-C₃ alkyloxy, phenoxy, C₁-to-C₁₂ alkylsulfanyl, phenylsulfanyl, —N(C₁-to-C₁₂ alkyl)₂, diphenylamino, —(CO)O(C₁-to-C₃ alkyl), —(CO)—C₁-to-C₈ alkyl or (CO)N(C₁-to-C₈ alkyl)₂ depending on conditions (in particular, phenyl, naphthyl, phenanthryl, anthranil or pyrenyl).
R²⁰³ and R²⁰⁴ each independently represent: a hydrogen; C₁-to-C₂₄ alkyl; E-substituted and/or D-interrupted C₁-to-C₂₄ alkyl; C₂-to-C₅ alkenyl, C₃-to-C₈ cycloalkyl or benzoyl substituted or unsubstituted by one group or more of C₁-to-C₆ alkyl, halogen, —OH or C₁-to-C₄ alkoxy depending on conditions; or phenyl-C₁-to-C₃ alkyl, C₁-to-C₈ alkanoyl, C₃-to-C₁₂ alkenoyl or C₆-to-C₁₄ aryl substituted by C₁-to-C₁₂ alkyl, benzoyl or C₁-to-C₁₂ alkoxy depending on conditions (particularly, phenylnaphthyl, phenanthryl, anthranil or pyrenyl). Alternatively, R²⁰³ and R²⁰⁴ may together form C₂-to-C₈ alkylene or branched C₂-to-C₈ alkylene interrupted by —O—, —S— or NR²⁰⁵ and/or substituted by hydroxyl, C₁-to-C₄ alkoxy, C₂-to-C₄ alkanoyloxy or benzoyloxy depending on conditions. Herein, the ring formed by R²⁰³ and R²⁰⁴ may be fused by one time or twice by a phenyl that may be substituted one to three times by C₁-to-C₈ alkyl, C₁-to-C₈ alkoxy, halogen or cyano depending on conditions.
R²⁰⁵ is: a hydrogen; C₁-to-C₂₄ alkyl; E-substituted and/or D-interrupted C₁-to-C₂₄ alkyl; C₂-to-C₅ alkenyl; C₃-to-C₈ cycloalkyl; phenyl-C₁-to-C₃ alkyl; C₁-to-C₈ alkanoyl; C₃-to-C₁₂ alkenoyl; C₆-to-C₁₄ aryl (in particular, benzoyl); or phenyl, naphthyl, phenanthryl, anthranil or pyrenyl substituted by C₁-to-C₁₂ alkyl, benzoyl or C₁-to-C₁₂ alkoxy depending on conditions.
D is —CO—, —COO—, —OCOO—, —S—, —SO—, —SO₂—, —O—, —NR⁵—, —SiR⁶¹R⁶²—, —POR⁵—, —CR⁶³═CR⁶⁴—or —C≡C—.
E is: C₆-to-C₁₄ aryl (in particular, phenyl, naphthyl, phenanthryl, anthranil or pyrenyl) substituted or unsubstituted by halogen, —OR^{S}, —SR⁵, —NR⁵R⁶ or

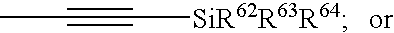

—OR⁵, —SR⁵, —NR⁵R⁶, —COR⁸, —COOR⁷, —CONR⁵R⁶, —CN, halogen, silyl, C₁-to-C₁₈ alkyl or heteroaryl. In the formula, R⁶², R⁶³ and R⁶⁴ each independently represent C₁-to-C₈ alkyl group, C₆-to-C₂₄ aryl group or C₇-to-C₁₂ aralkyl group, —CN, cyclic ether and/or —B(OR⁶⁵)₂. In the formula, R⁶⁵ is a hydrogen, C₁-to-C₂₄ alkyl, C₃-to-C₈ cycloalkyl, C₇-to-C₂₄ aralkyl, C₂-to-C₁₈ alkenyl, C₂-to-C₂₄ alkynyl, hydroxyl, mercapto, C₁-to-C₂₄ alkoxy, C₁-to-C₂₄ alkylthio, C₆-to-C₃₀ aryl, C₂-to-C₃₀ heteroaryl, halogen (particularly fluorine), haloalkane, silyl, siloxanyl and alicyclic ring formed together with the adjoining substituent R⁶⁵.
G is: E or C₁-to-C₁₈ alkyl (in the formula, R⁵ and R⁶ each independently represent H, C₆-to-C₁₈ aryl); C₁-to-C₁₈ alkyl, C₁-to-C₁₈ alkoxy or silyl-substituted C₆-to-C₁₈ aryl; or C₁-to-C₁₈ alkyl or C₁-to-C₁₈ alkyl interrupted by —O—. Alternatively, G may form a five-membered ring or six-membered ring together with R⁵ and R⁶, particularly the structure represented by the following formula (13c) or (13d).

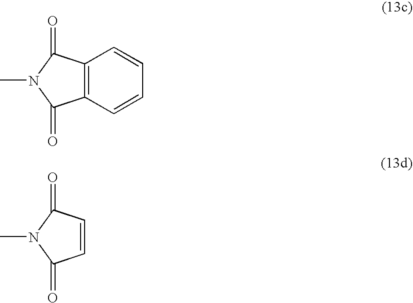

R⁷ is H, C₆-to-C₁₈ aryl, C₇-to-C₁₂ alkylaryl (substituted by C₁-to-C₁₈ alkyl or C₁-to-C₁₈ alkoxy depending on conditions), C₁-to-C₁₈ alkyl or C₁-to-C₁₈ alkyl interrupted by —O—.
R⁸ is: C₆-to-C₁₈ aryl; C₆-to-C₁₈ aryl substituted by C₁-to-C₁₈ alkyl or C₁-to-C₁₈ alkoxy; or C₁-to-C₁₈ alkyl, C₇-to-C₁₂ alkylaryl or C₁-to-C₁₈ alkyl interrupted by —O—.
R⁶¹ and R⁶² each independently represent: C₆-to-C₁₈ aryl; C₁-to-C₁₈ alkyl, C₆-to-C₁₈ aryl substituted by C₁-to-C₁₈ alkoxy; or C₁-to-C₁₈ alkyl interrupted by —O—. R⁶³ and R⁶⁴ each independently represent: H, C₆-to-C₁₈ aryl; C₁-to-C₁₈ alkyl, C₆-to-C₁₈ aryl substituted by C₁-to-C₁₈ alkoxy; or C₁-to-C₁₈ alkyl interrupted by —O—. However, at least one of R⁸¹, R⁸², R⁸³, R⁸⁴, R⁸⁵, R⁸⁶, R⁸⁷ and R⁸⁸ is different from H, —OR²⁰¹, —SR²⁰² and C₁-to-C₂₄ alkyl.

Further, the heterocycle-containing compound may be a compound represented by the following general formula (I).

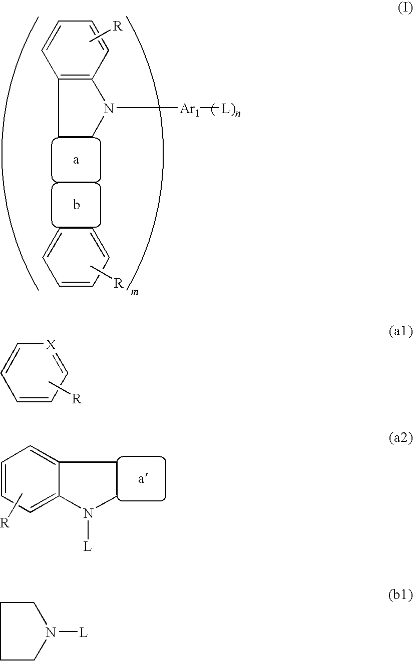

The ring (a) represents an aromatic ring or heterocyclic ring fused with two adjoining rings and represented by the formula (a1) or (a2). The ring (a′) represents an aromatic ring or heterocyclic ring fused with three adjoining rings and represented by the formula (a1). X represents CH or N. The ring (b) represents a heterocyclic ring fused with two adjoining rings and represented by the formula (b1).
Ar₁ represents a m+n-valent group formed of an aromatic heterocyclic group.

L independently represents a substituted or unsubstituted aromatic hydrocarbon or aromatic heterocyclic group, at least one of which has a fused ring structure.

R independently represents hydrogen, an alkyl group, aralkyl group, alkenyl group, alkynyl group, cyano group, dialkylamino group, diarylamino group, diaralkylamino group, amino group, nitro group, acyl group, alkoxycarbonyl group, carboxyl group, alkoxyl group, alkylsulfonyl group, haloalkyl group, hydroxyl group, amide group, substituted or unsubstituted aromatic hydrocarbon group or substituted or unsubstituted aromatic heterocyclic group.

m represents 1 and n represents 1 or 2.
Examples of the heterocycle-containing compound represented by the general formula (I) are compounds represented by the general formulae (II) to (IV).

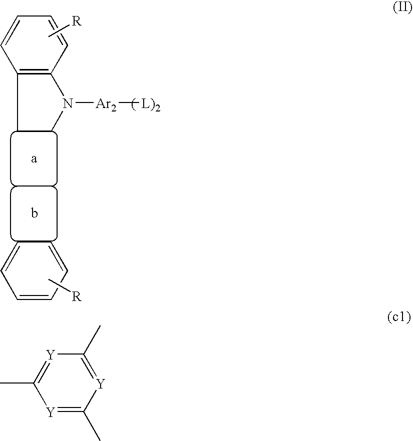

The ring (a), ring (b), L and R each mean the same as the ring (a), ring (b), L and R in the general formula (I).
Ar₂ is a trivalent group represented by the formula (c1). Y independently represents CH or N, at least one of which is N.

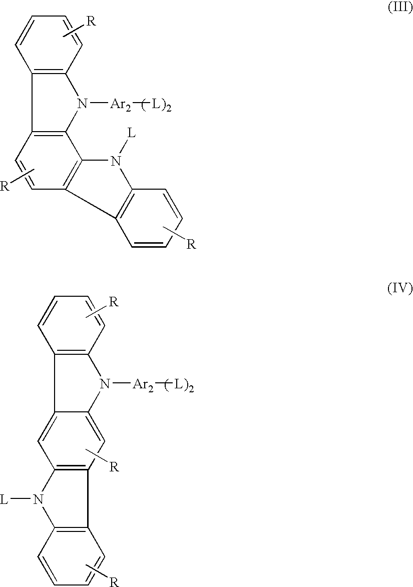

In the general formulae (III) and (IV), L, R and Ar₂ each mean the same as L, R and Ar₂ in the general formula (II).

Examples of the compound represented by the general formula (I) in which m=2 are compounds represented by the general formula (V). Examples of the compound represented by the general formula (V) are compounds represented by the general formulae (VI) to (VII).

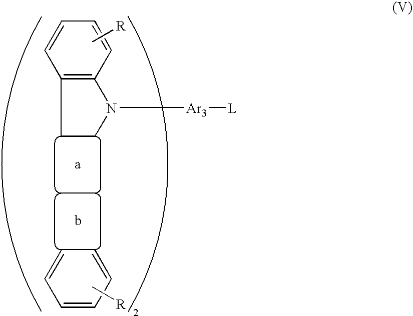

The ring (a), ring (b), L and R each mean the same as the ring (a), ring (b), L and R in the general formula (I).
Ar₃ represents a trivalent group formed of an aromatic heterocyclic group.

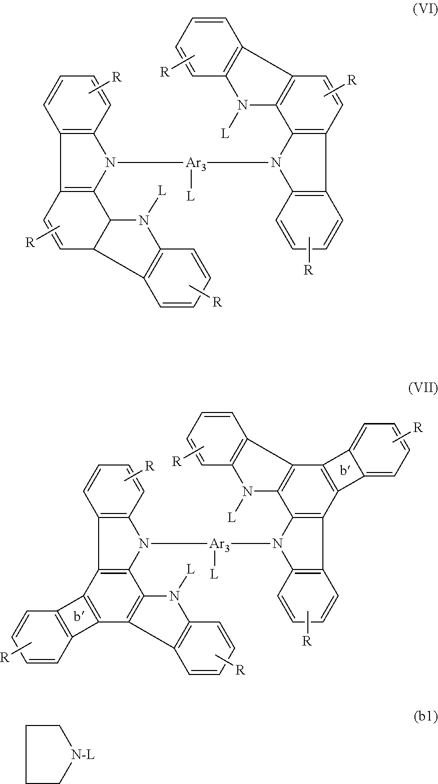

In the general formulae (VI) and (VII), L, R and Ar₃ each mean the same as L, R and Ar₃ in the general formula (V).

The ring (b′) independently represents a heterocyclic ring fused with two adjoining rings and represented by the formula (b1).

The general formula (II) is equivalent to the general formula (I) in which m is equal to 1 and n is equal to 2.

In the general formulae (I) and (II), the ring (a) represents an aromatic ring or heterocyclic ring fused with two adjoining rings and represented by the formula (a1) or (a2). The ring (a′) represents an aromatic ring or heterocyclic ring fused with three adjoining rings and represented by the formula (a1). X represents CH or N. The ring (b) represents a heterocyclic ring fused with two adjoining rings and represented by the formula (b1).

Ar represents a m+n-valent group formed of an aromatic heterocyclic group. Ar may be a divalent to tetravalent group.

L independently represents a substituted or unsubstituted aromatic hydrocarbon or aromatic heterocyclic group, at least one of which has a fused ring structure. The fused ring structure may be an aromatic hydrocarbon ring or aromatic heterocyclic ring in which two to three aromatic rings are fused. When the aromatic hydrocarbon group or the aromatic heterocyclic group has a substituent(s), the substituent(s) is preferably such a group as described with respect to R in the following.

R independently represents hydrogen, an alkyl group, aralkyl group, alkenyl group, alkynyl group, cyano group, dialkylamino group, diarylamino group, diaralkylamino group, amino group, nitro group, acyl group, alkoxycarbonyl group, carboxyl group, alkoxyl group, alkylsulfonyl group, haloalkyl group, hydroxyl group, amide group, substituted or unsubstituted aromatic hydrocarbon group or substituted or unsubstituted aromatic heterocyclic group. R is preferably hydrogen. When R is an alkyl group, alkoxyl group, alkylsulfonyl group, haloalkyl group or alkoxycarbonyl group, the number of carbon atoms contained therein is preferably 1 to 6. When R is an alkenyl group or alkynyl group, the number of carbon atoms is preferably 2 to 6. When R is an acyl group, dialkylamino group, diarylamino group or diaralkylamino group, the number of carbon atoms is preferably 2 to 16.

Further examples of the heterocycle-containing compound are the following dibenzofuran derivatives or carbazole derivatives.

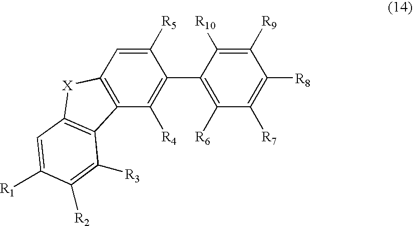

In the general formula (14), R₁ to R₁₀ each independently represent a hydrogen atom, halogen atom, substituted or unsubstituted alkyl group having 1 to 40 carbon atoms, substituted or unsubstituted cycloalkyl group having 3 to 15 carbon atoms, substituted or unsubstituted heterocyclic group having 3 to 20 carbon atoms, substituted or unsubstituted alkoxy group having 1 to 40 carbon atoms, substituted or unsubstituted non-fused aryl group having 6 to 40 carbon atoms, substituted or unsubstituted fused aryl group having 10 to 18 carbon atoms, substituted or unsubstituted aryloxy group having 6 to 20 carbon atoms, substituted or unsubstituted aralkyl group having 7 to 20 carbon atoms, substituted or unsubstituted acylamino group having 6 to 40 carbon atoms, substituted or unsubstituted alkylamino group having 1 to 40 carbon atoms, substituted or unsubstituted aralkylamino group having 7 to 60 carbon atoms, substituted or unsubstituted arylcarbonyl group having 7 to 40 carbon atoms, substituted or unsubstituted halogenated alkyl group having 1 to 40 carbon atoms or cyano group. R₈ and R₉ may be bonded together to form a ring structure. Substituents for R₁ to R₁₀ do not have polymerizable functional groups at their terminals. At least one of R₁ to R₃ is a carbazolyl group or azacarbazolyl group. X represents a sulfur atom or oxygen atom.

The compound represented by the general formula (14) may be represented by the following general formula (15).

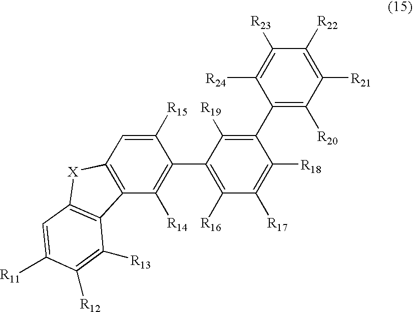

In the general formula (15), definitions of R₁₁ to R₂₄ and X are the same as those of R₁ to R₁₀ and X in the general formula (14). At least one of R₁₁ to R₁₃ is a carbazolyl group or azacarbazolyl group.

The compound represented by the general formula (14) may be represented by the following general formula (16).

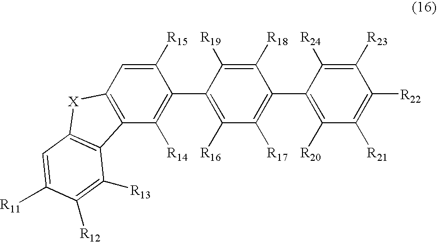

In the general formula (16), definitions of R₁₁ to R₂₄ and X are the same as those of R₄ to R₁₀ and X in the general formula (14). At least one of R₁₁ to R₁₃ is a carbazolyl group or azacarbazolyl group.

The compound represented by the general formula (14) may be represented by the following general formula (17).

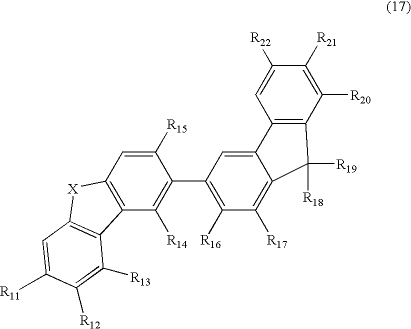

In the general formula (17), definitions of R₁₁ to R₂₂ and X are the same as those of R₁ to R₁₀ and X in the general formula (14). At least one of R₁₁ to R₁₃ is a carbazolyl group or azacarbazolyl group.

The compound represented by the general formula (14) may be represented by the following general formula (18).

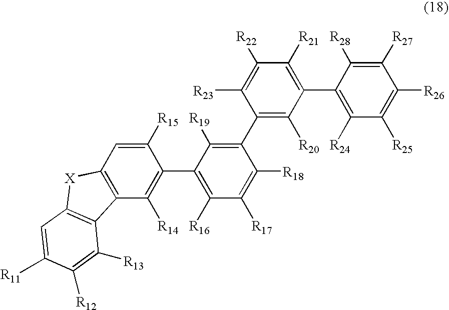

In the general formula (18), definitions of R₁₁ to R₂₈ and X are the same as those of R₁ to R₁₀ and X in the general formula (14). At least one of R₁₁ to R₁₃ is a carbazolyl group or azacarbazolyl group.

At least one of the substituents R₁₆ to R₂₄ in the formulae (15) and (16) or at least one of the substituents R₁₆ to R₁₇ and R₂₀ to R₂₂ in the formula (17) may be selected from a substituted or unsubstituted carbazolyl group, substituted or unsubstituted dibenzofuranyl group, substituted or unsubstituted azacarbazolyl group and substituted or unsubstituted dibenzothiophenyl group.

At least one of the substituents R₁₆ to R₂₈ in the formula (18) may be selected from a substituted or unsubstituted carbazolyl group, substituted or unsubstituted dibenzofuranyl group, substituted or unsubstituted azacarbazolyl group and substituted or unsubstituted dibenzothiophenyl group.

Examples of such a compound are as follows.

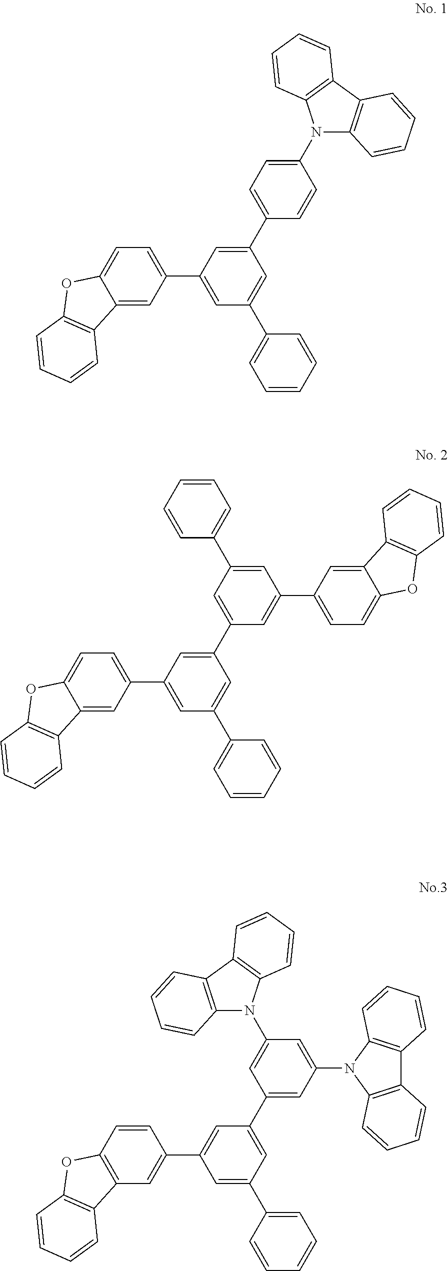

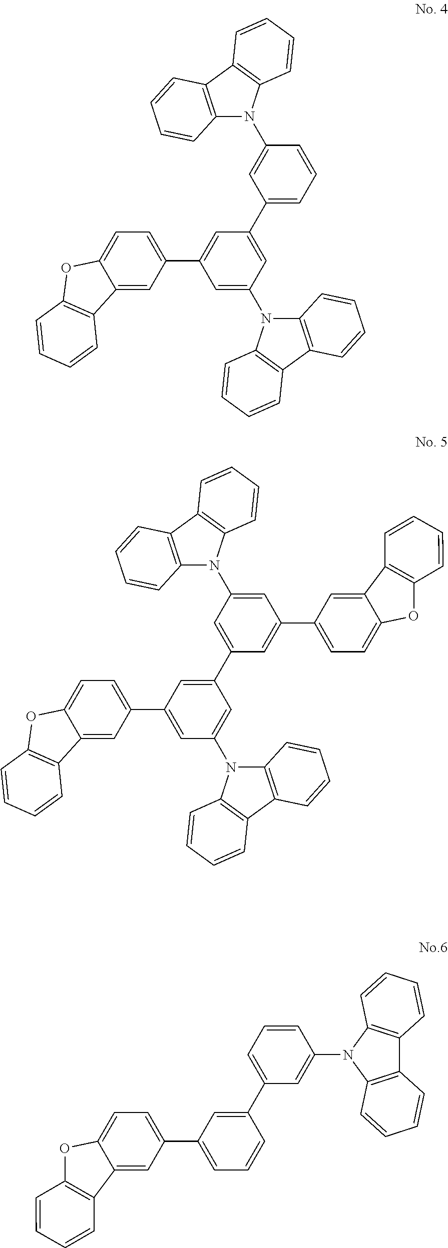

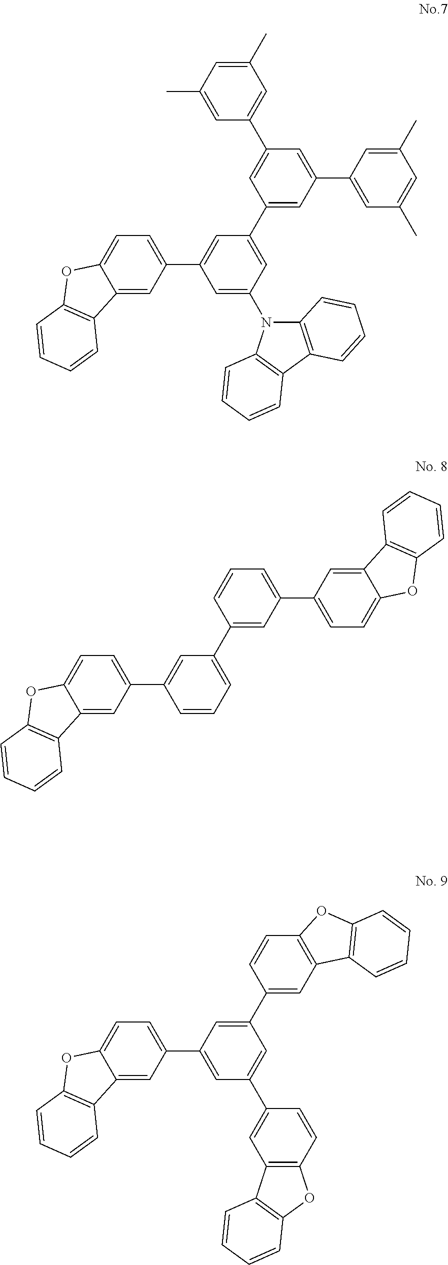

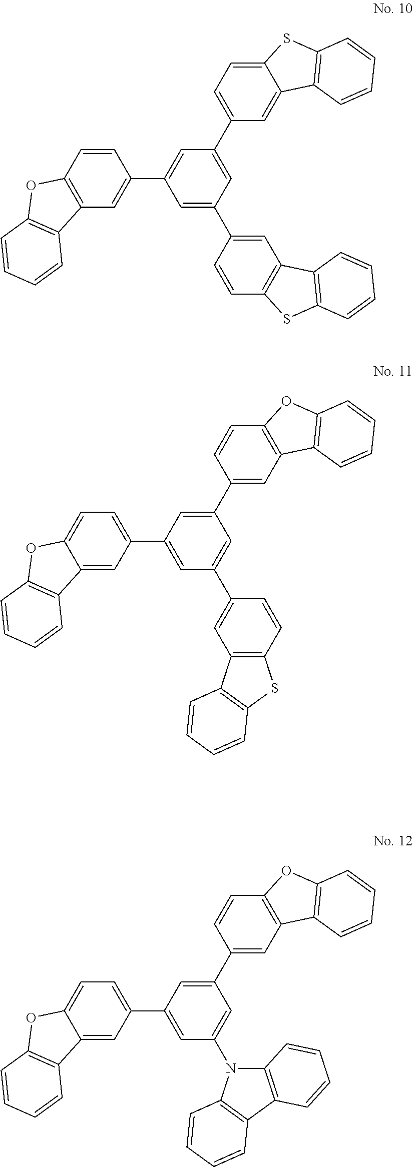

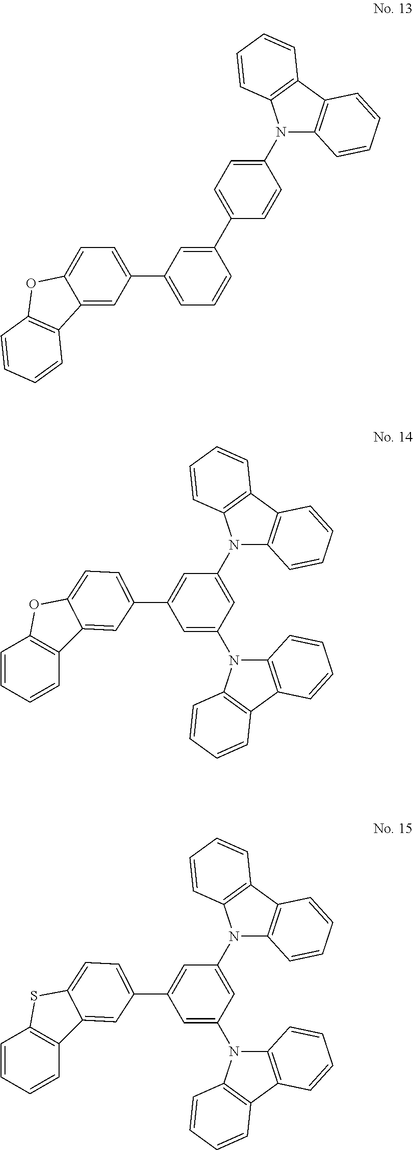

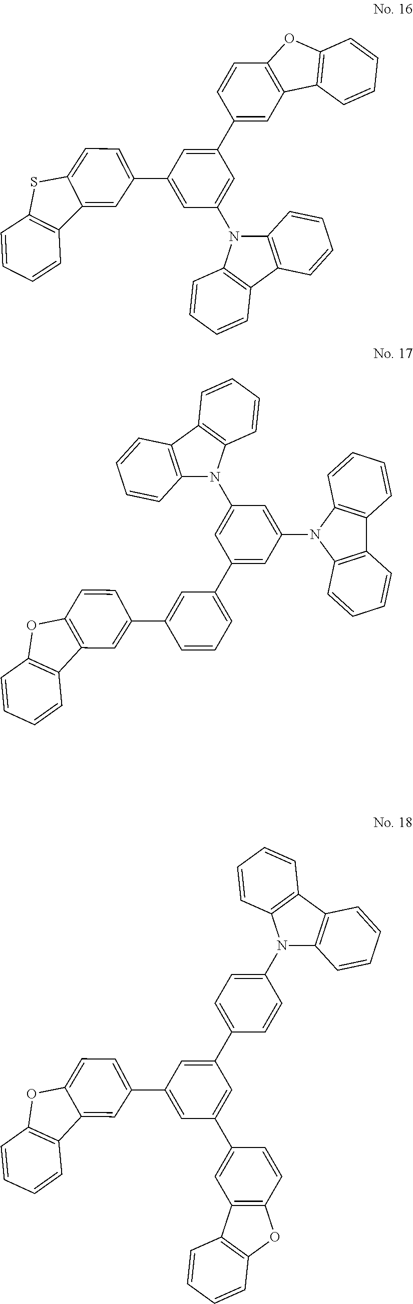

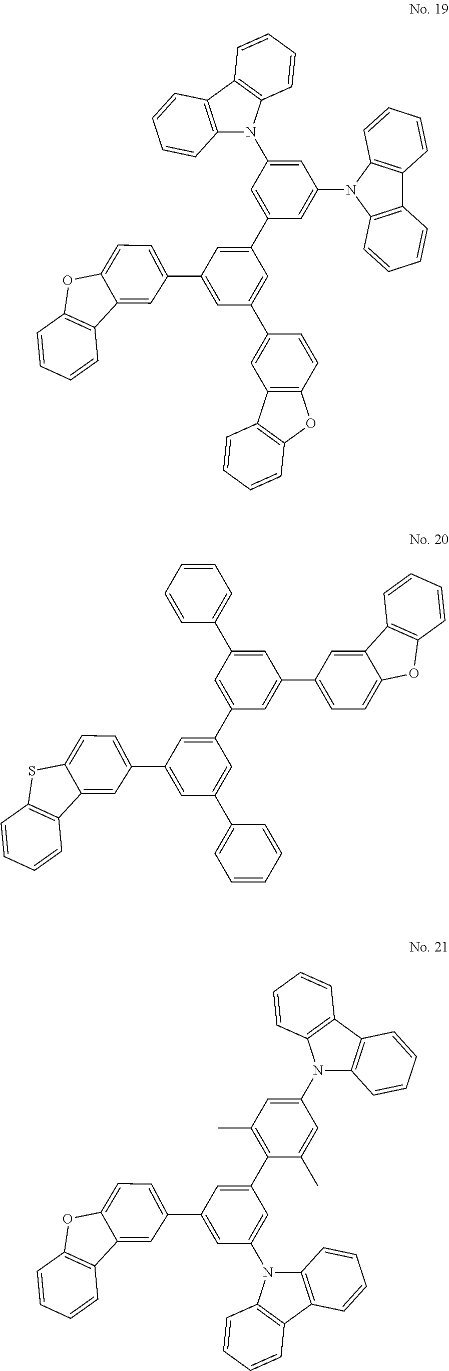

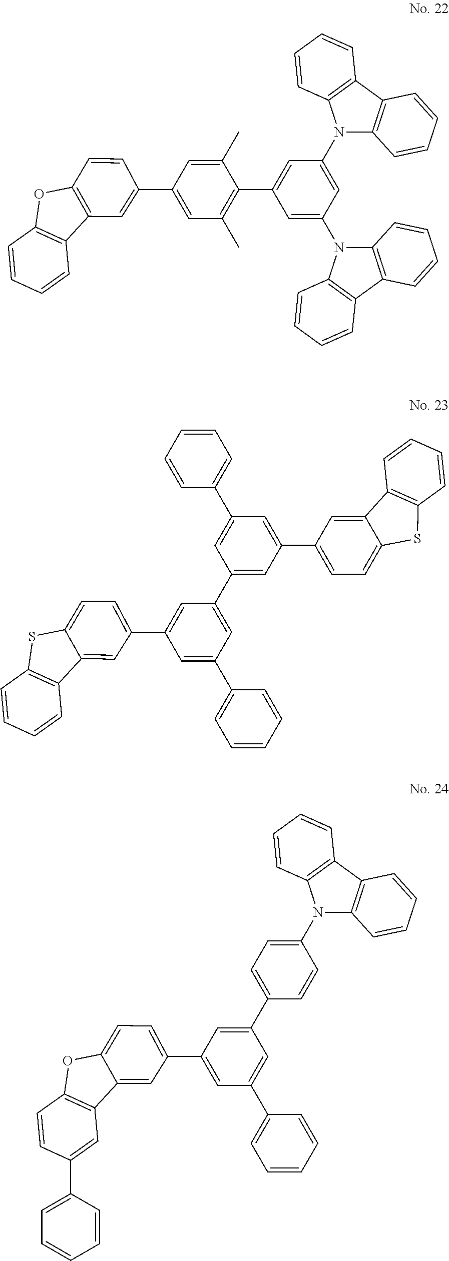

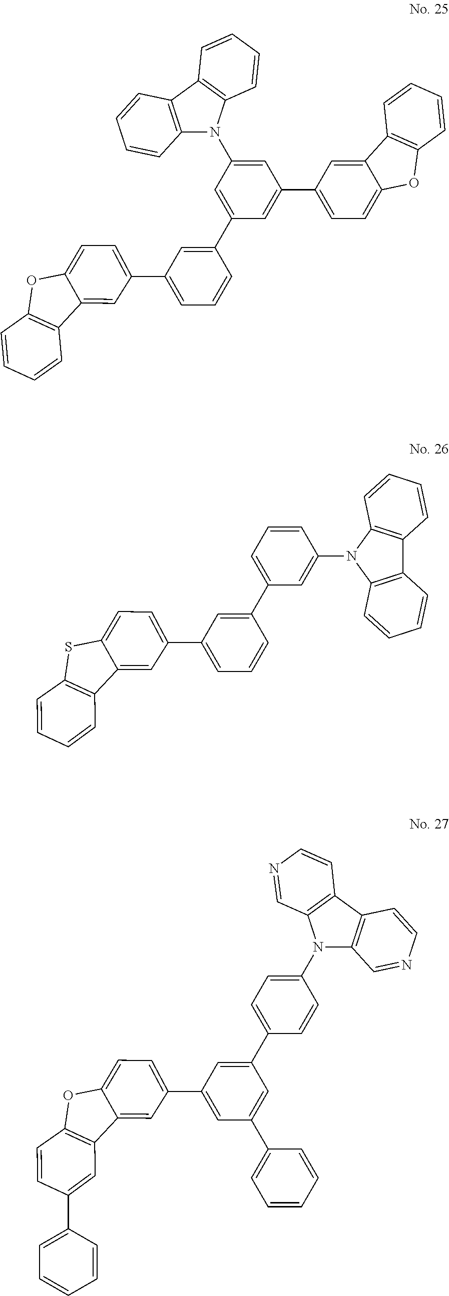

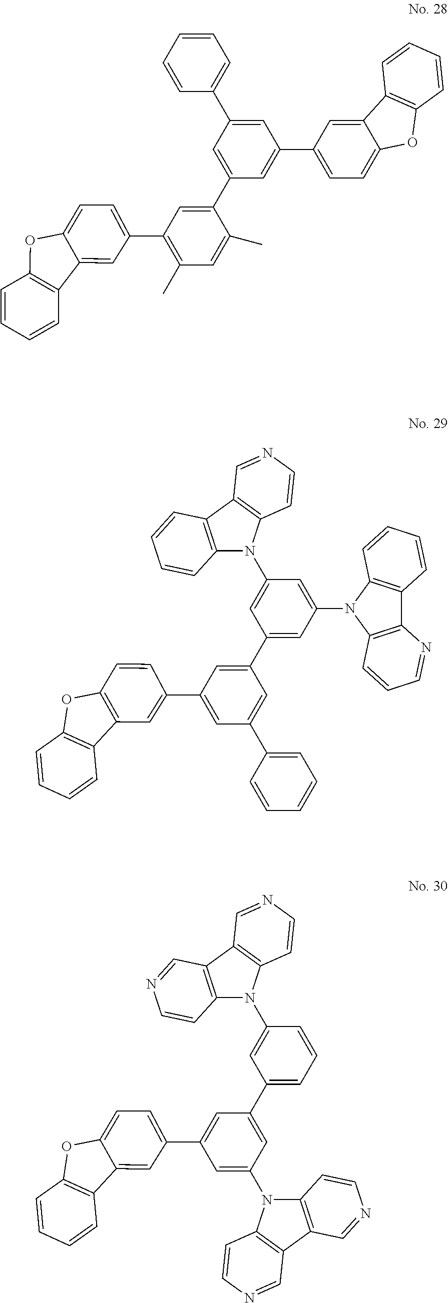

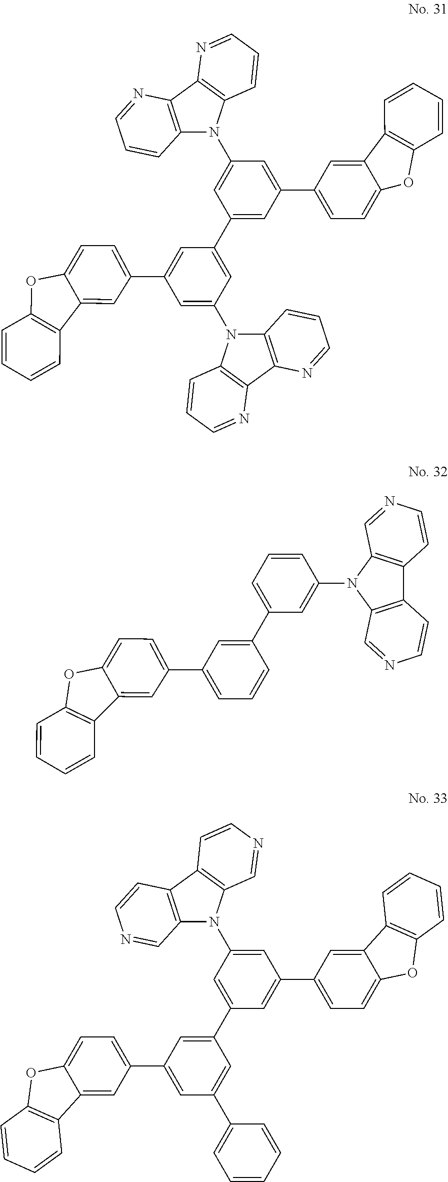

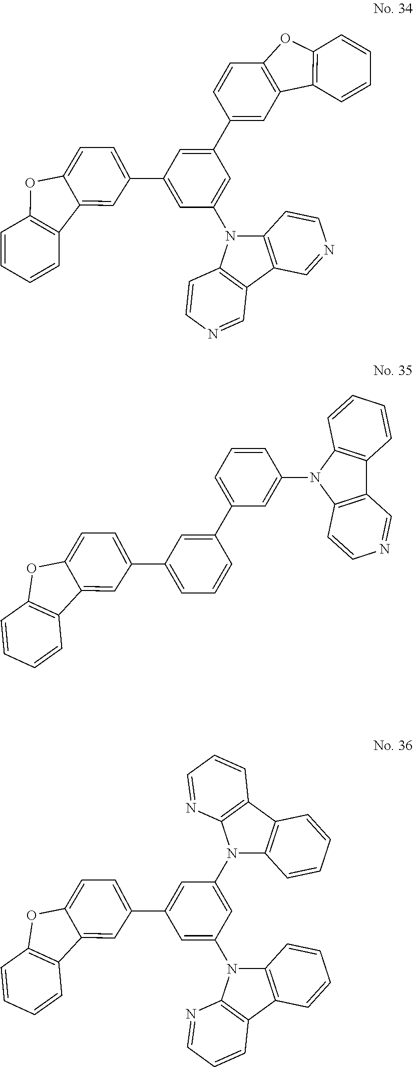

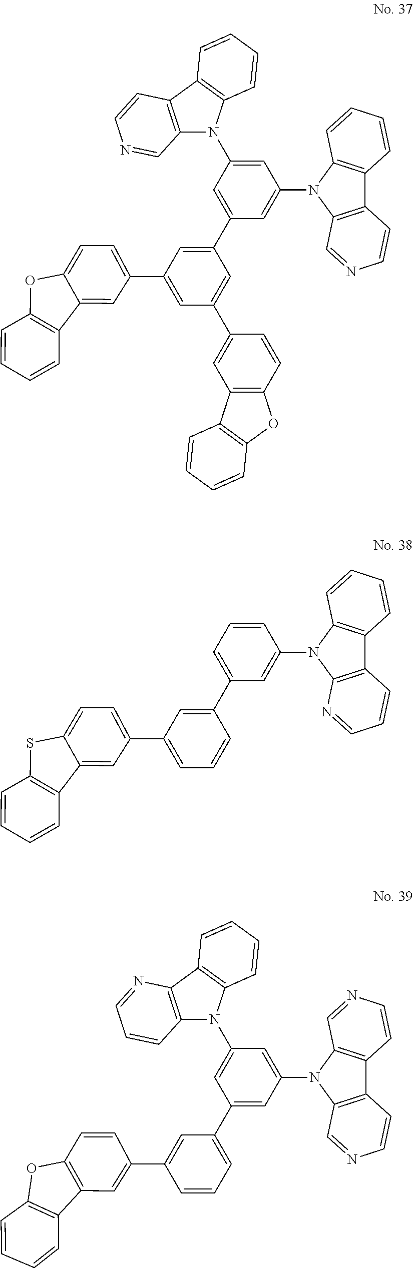

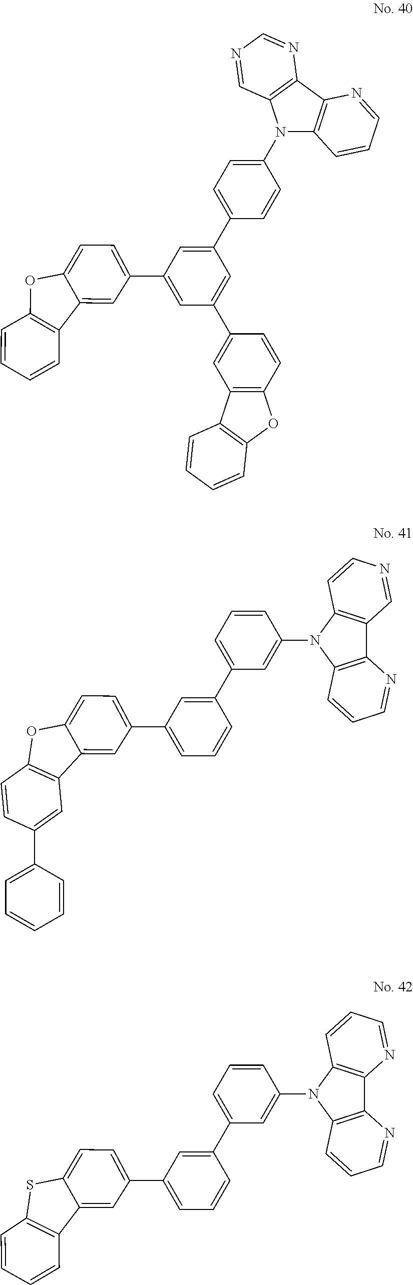

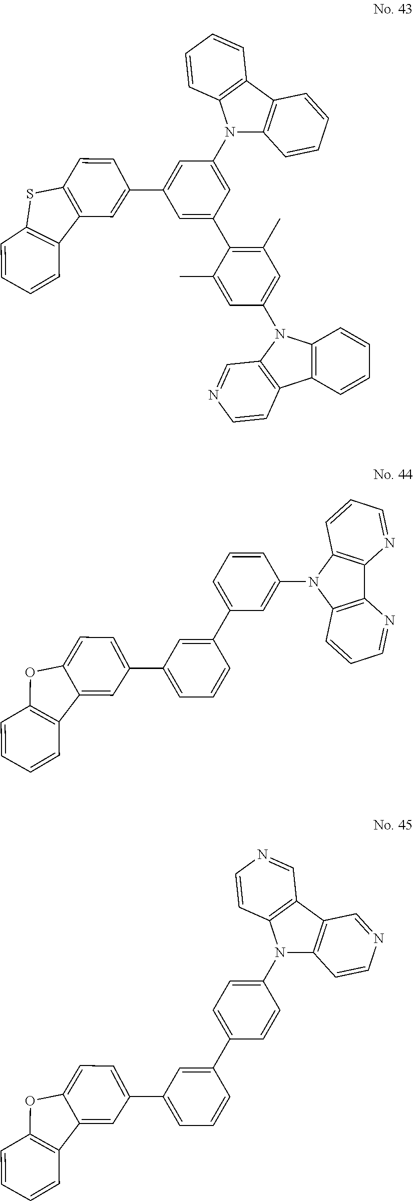

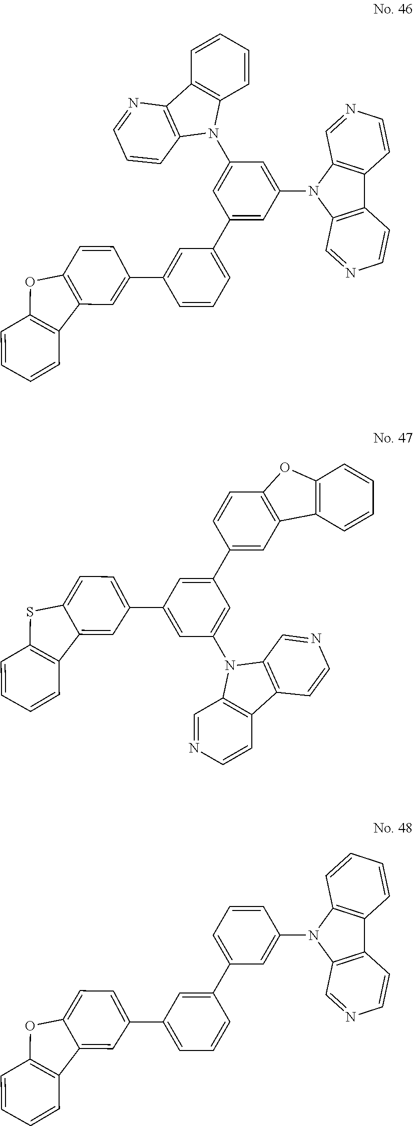

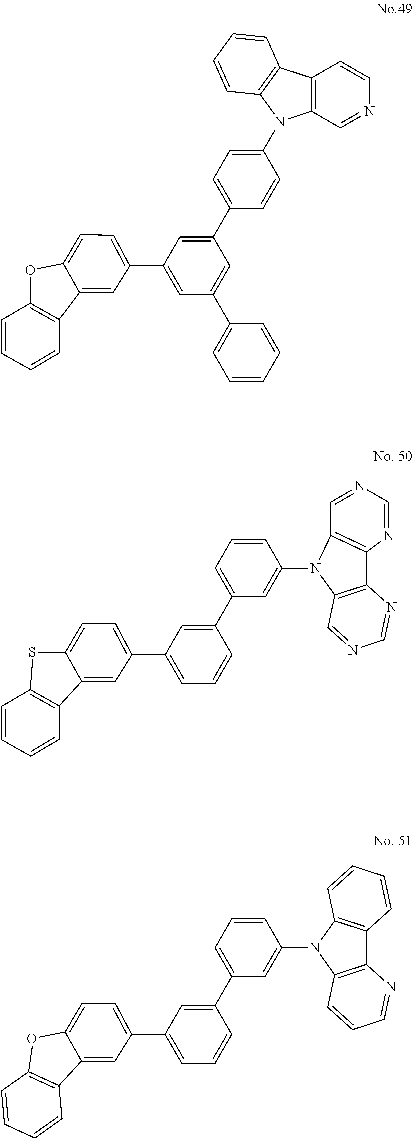

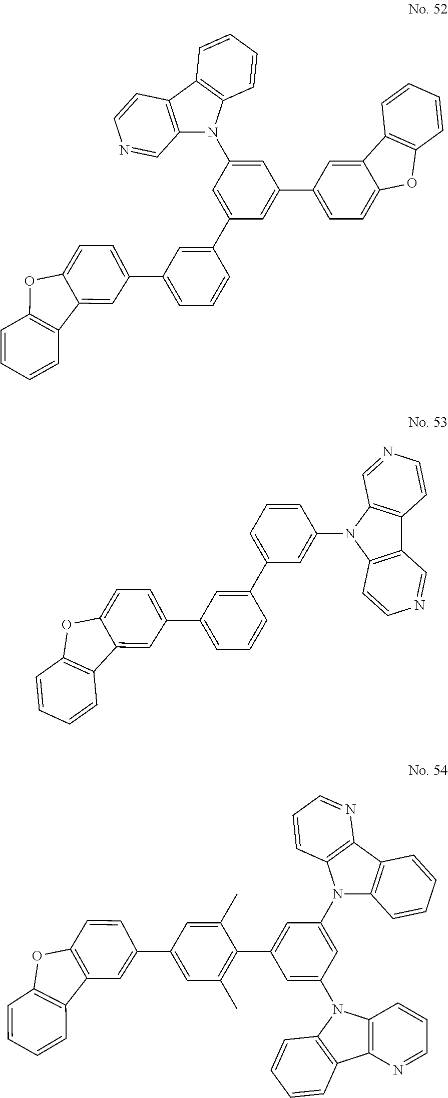

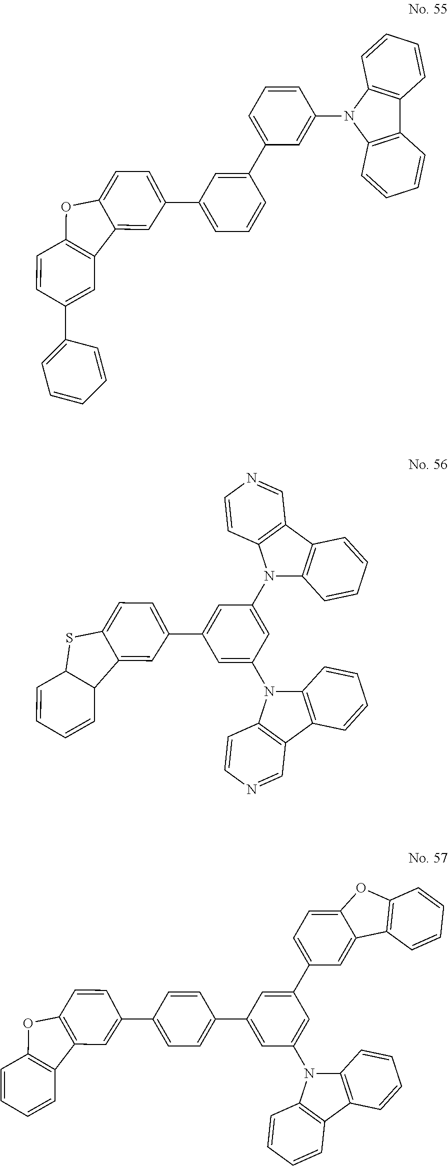

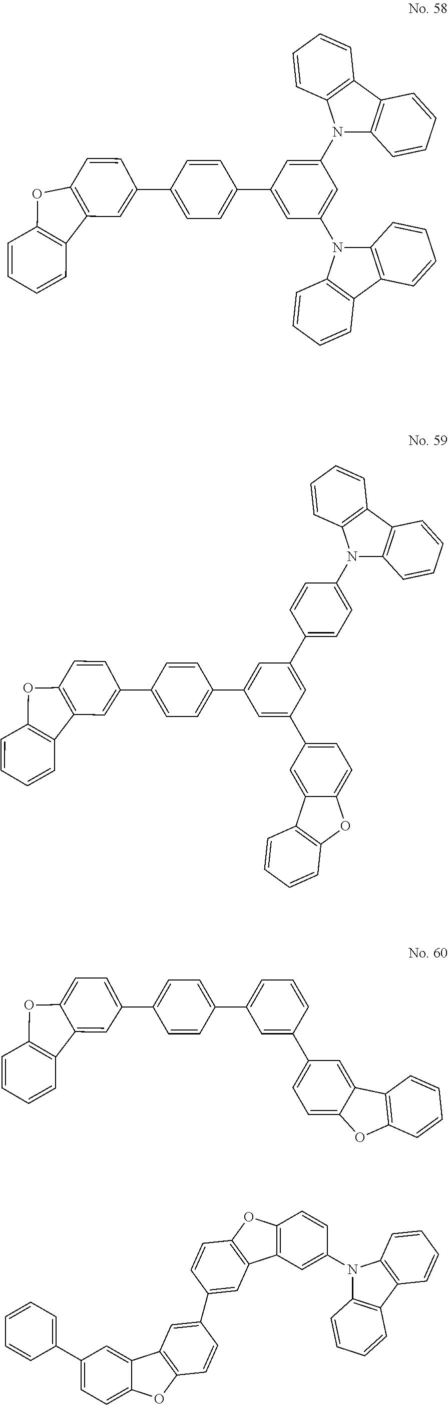

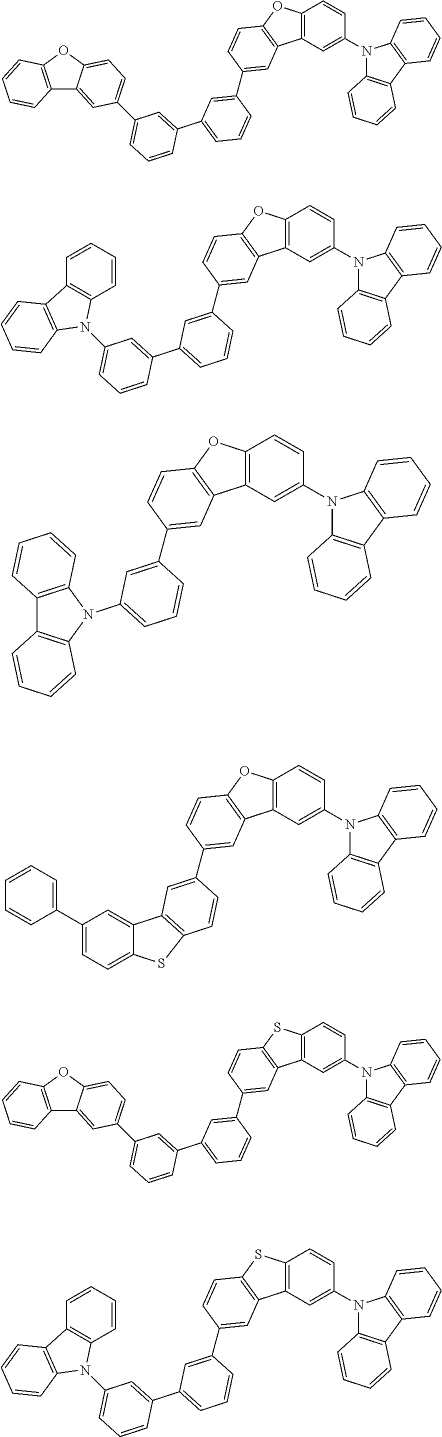

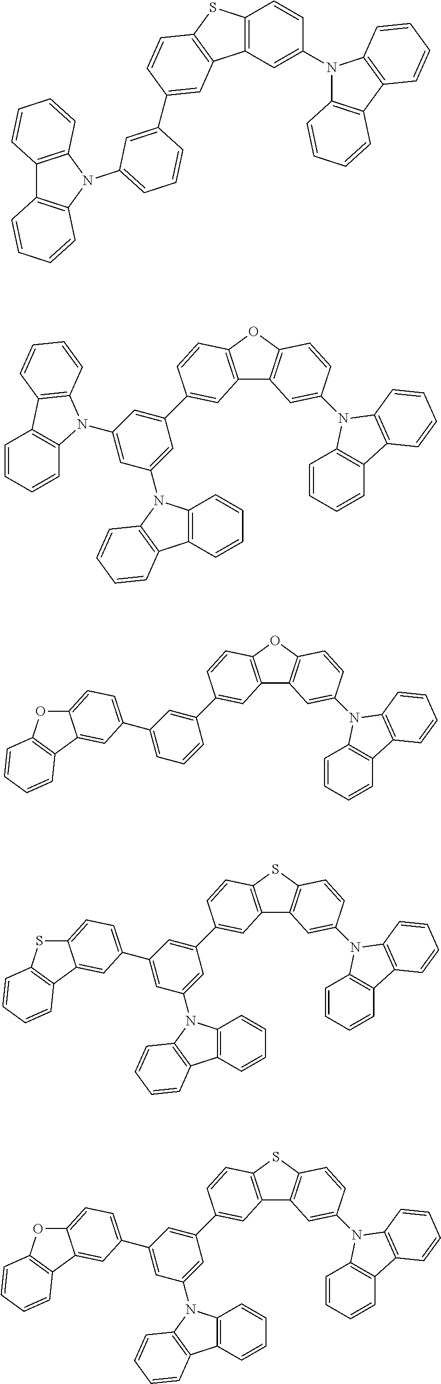

Further, the heterocycle-containing compound may be a ladder-type heterocycle-containing compound represented by the following general formula (21) or (22). In this exemplary embodiment, a ladder-type furan compound is preferable among ladder-type heterocycle-containing compounds. Like carbazole and dibenzofuran derivatives, for instance, such a ladder-type furan compound can provide relatively large triplet energy.

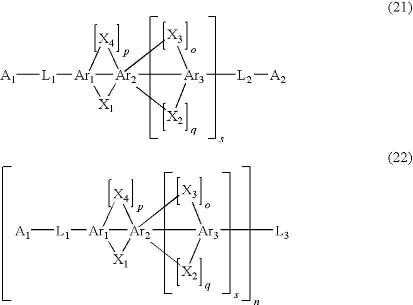

In the above formulae (21) and (22), Ar₁, Ar₂ and Ar₃ each independently represent a substituted or unsubstituted aryl group having 6 to 24 ring-forming carbon atoms or a substituted or unsubstituted heteroaryl group having 3 to 24 ring-forming atoms. However, Ar₁, Ar₂ and Ar₃ may have a single substituent Y or a plurality of substituents Y. The plurality of substituents Y may be mutually the same or different. Y represents an alkyl group having 1 to 20 carbon atoms, substituted or unsubstituted cycloalkyl group having 3 to 20 ring-forming carbon atoms, alkoxy group having 1 to 20 carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded with Ar₁, Ar₂ and Ar₃ in carbon-carbon bonding.

In the formulae (21) and (22), X₁, X₂, X₃ and X₄ each independently represent O, S or N—R₁ or CR₂R₃.

In the formulae (21) and (22), R₁, R₂ and R₃ each independently represent an alkyl group having 1 to 20 carbon atoms, substituted or unsubstituted cycloalkyl group having 3 to 20 ring-forming carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms. However, when: both of X₁ and X₂ represent N—R₁; o and p are 0; and q is 1, or when: both of X₁ and X₃ represent N—R₁; p and q are 0; and o is 1, at least one R₁ represents a substituted or unsubstituted monovalent fused heteroaryl group having 8 to 24 ring-forming atoms.

In the formulae (21) and (22), o, p and q represent 0 or 1, and s represents 1, 2 or 3. n represents 2, 3 or 4, which respectively mean a dimer, trimer and tetramer each of which uses L₃ as the bonding group.

In the formulae (21) and (22), L₁ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded with Ar₁ in carbon-carbon bonding.

In the formula (21), L₂ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded with Ar₃ in carbon-carbon bonding. However, when: both of X₁ and X₂ represent CR₂R₃; o and p are 0; q is 1; and both of L₁ and L₂ are substituted or unsubstituted monovalent or divalent aryl group having 6 to 24 ring-forming carbon atoms, or when: both of X₁ and X₃ represent CR₂R₃; p and q are 0; o is 1; and both of L₁ and L₂ are substituted or unsubstituted monovalent or divalent aryl group having 6 to 24 ring-forming carbon atoms, L₁ and L₂ are not bonded to Ar₂ in para positions at the same time.

In the formula (22), when n is 2, L₃ represents a single bond, alkylene group having 1 to 20 carbon atoms, substituted or unsubstituted cycloalkylene group having 3 to 20 ring-forming carbon atoms, divalent silyl group having 2 to 20 carbon atoms, substituted or unsubstituted divalent aryl group having 6 to 24 ring-forming carbon atoms or substituted or unsubstituted divalent heteroaryl group having 3 to 24 ring-forming atoms and being bonded to Ar₃ in carbon-carbon bonding. When n is 3, L₃ represents a trivalent alkane having 1 to 20 carbon atoms, substituted or unsubstituted trivalent cycloalkane having 3 to 20 ring-forming carbon atoms, trivalent silyl group having 1 to 20 carbon atoms, substituted or unsubstituted trivalent aryl group having 6 to 24 ring-forming carbon atoms or substituted or unsubstituted trivalent heteroaryl group having 3 to 24 ring-forming atoms and being bonded to Ar₃ in carbon-carbon bonding. When n is 4, L₃ represents tetravalent alkane having 1 to 20 carbon atoms, substituted or unsubstituted tetravalent cycloalkane having 3 to 20 ring-forming carbon atoms, silicon atom, substituted or unsubstituted tetravalent aryl group having 6 to 24 ring-forming carbon atoms or substituted or unsubstituted tetravalent heteroaryl group having 3 to 24 ring-forming atoms and being bonded to Ar₃ in carbon-carbon bonding. However, when: both of X₁ and X₂ represent CR₂R₃; o and p are 0; q is 1; and both of L₁ and L₃ are substituted or unsubstituted monovalent, divalent, trivalent or tetravalent aryl group having 6 to 24 ring-forming carbon atoms, or when: both of X₁ and X₃ represent CR₂R₃; p and q are 0; o is 1; and both of L₁ and L₃ are substituted or unsubstituted monovalent, divalent, trivalent or tetravalent aryl group having 6 to 24 ring-forming carbon atoms, L₁ and L3 are not bonded to Ar₂ in para positions at the same time.

In the formulae (21) and (22), Ar₁ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₁ in carbon-carbon bonding.

In the formula (21), Ar₂ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₂ in carbon-carbon bonding. However, when: both of X₁ and X₂ are O, S or CR₂R₃; o and p are 0; q is 1; and both of L₁ and L₂ are single bonds, or when: both of X₁ and X₃ are O, S or CR₂R₃; p and q are 0; o is 1; and both of L₁ and L₂ are single bonds, A₁ and A₂ are not hydrogen atoms at the same time.

In the formulae (21) and (22), A₁, A₂, L₁, L₂ and L₃ do not contain any carbonyl groups.

Further, the ladder-type heterocycle-containing compound may be a compound represented by any one of the following general formulae (23) to (26).

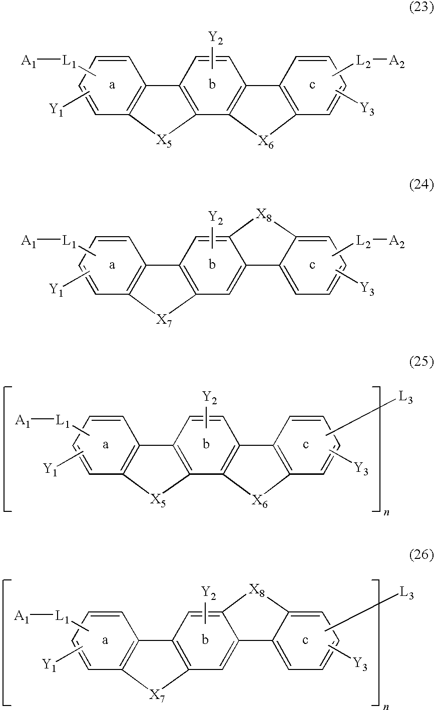

In the formulae (23) and (26), X₅, X₆, X₇ and X₈ each independently represent O, S or N—R₁.

In the formulae (23) to (26), R₁ represents an alkyl group having 1 to 20 carbon atoms, substituted or unsubstituted cycloalkyl group having 3 to 20 ring-forming carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms. However, when X₅ and X₆ or X₇ and X₈ are both N—R₁, at least one R₁ is a substituted or unsubstituted monovalent fused heteroaryl group having 8 to 24 ring-forming atoms.

In the formulae (25) and (26), n represents 2, 3 or 4, which respectively mean a dimer, trimer and tetramer each of which uses L₃ as the bonding group.

In the formulae (23) to (26), L₁ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (a) in carbon-carbon bonding.

In the Formulae (23) and (24), L₂ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (c) in carbon-carbon bonding.

In the formulae (25) and (26), when n is 2, L₃ represents a single bond, alkylene group having 1 to 20 carbon atoms, substituted or unsubstituted cycloalkylene group having 3 to 20 ring-forming carbon atoms, divalent silyl group having 2 to 20 carbon atoms, substituted or unsubstituted divalent aryl group having 6 to 24 ring-forming carbon atoms or substituted or unsubstituted divalent heteroaryl group having 3 to 24 ring-forming atoms and being bonded to the benzene ring (c) in carbon-carbon bonding. When n is 3, L₃ represents a trivalent alkane having 1 to 20 carbon atoms, substituted or unsubstituted trivalent cycloalkane having 3 to 20 ring-forming carbon atoms, trivalent silyl group having 1 to 20 carbon atoms, substituted or unsubstituted trivalent aryl group having 6 to 24 ring-forming carbon atoms or substituted or unsubstituted trivalent heteroaryl group having 3 to 24 ring-forming atoms and being bonded to the benzene ring (c) in carbon-carbon bonding. When n is 4, L₃ represents tetravalent alkane having 1 to 20 carbon atoms, substituted or unsubstituted tetravalent cycloalkane having 3 to 20 ring-forming carbon atoms, silicon atom, substituted or unsubstituted tetravalent aryl group having 6 to 24 ring-forming carbon atoms or substituted or unsubstituted tetravalent heteroaryl group having 3 to 24 ring-forming atoms and being bonded to the benzene ring (c) in carbon-carbon bonding.

In the formulae (23) to (26), A₁ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₁ in carbon-carbon bonding.

In the formulae (23) and (24), A₂ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₂ in carbon-carbon bonding. However, when X₅ and X₆ or X₇ and X₈ are O or S and both of L₁ and L₂ are single bonds, A₁ and A₂ are not hydrogen atoms at the same time.

In the formulae (23) to (26), Y₁, Y₂ and Y₃ each represent an alkyl group having 1 to 20 carbon atoms, substituted or unsubstituted cycloalkyl group having 3 to 20 ring-forming carbon atoms, alkoxy group having 1 to 20 carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to the benzene rings (a), (b) and (c) in carbon-carbon bonding. The number of Y₁ and Y₃ is 0, 1, 2 or 3 while the number of Y₂ is 0, 1 or 2.

In the formulae (23) to (26), A₁, A₂, L₁, L₂ and L₃ do not contain any carbonyl groups.

Further, the ladder-type heterocycle-containing compound may be a compound represented by any one of the following general formulae (27) to (32).

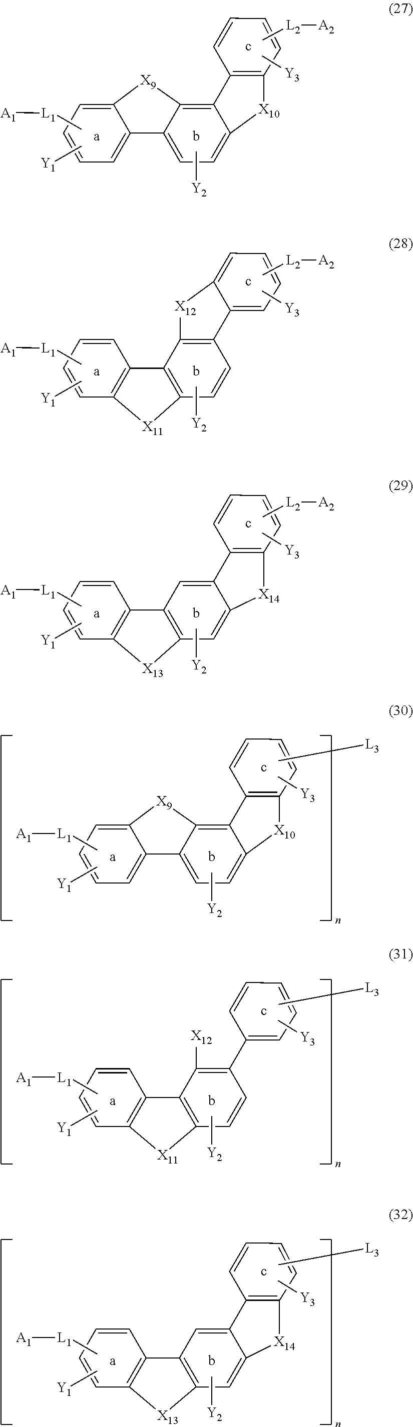

In the formulae (27) to (32), X₉, X₁₀, X₁₁, X₁₂, X₁₃ and X₁₄ each independently represent O, S or N—R₁.

In the formulae (27) to (32), R₁ represents an alkyl group having 1 to 20 carbon atoms, substituted or unsubstituted cycloalkyl group having 3 to 20 ring-forming carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms. However, when X₉ and X₁₀, X₁₁ and X₁₂ or X₁₃ and X₁₄ are both N—R₁, at least one R₁ is a substituted or unsubstituted monovalent fused heteroaryl group having 8 to 24 ring-forming atoms.

In the formulae (30) to (32), n represents 2, 3 or 4, which respectively mean a dimer, trimer and tetramer each of which uses L₃ as the bonding group.

In the formulae (27) to (32), L₁ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (a) in carbon-carbon bonding.

In the formulae (27) to (29), L₂ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (c) in carbon-carbon bonding.

In the formulae (30) to (32), when n is 2, L₃ represents a single bond, alkylene group having 1 to 20 carbon atoms, substituted or unsubstituted cycloalkylene group having 3 to 20 ring-forming carbon atoms, divalent silyl group having 2 to 20 carbon atoms, substituted or unsubstituted divalent aryl group having 6 to 24 ring-forming carbon atoms or substituted or unsubstituted divalent heteroaryl group having 3 to 24 ring-forming atoms and being bonded to the benzene ring (c) in carbon-carbon bonding. When n is 3, L₃ represents a trivalent alkane having 1 to 20 carbon atoms, substituted or unsubstituted trivalent cycloalkane having 3 to 20 ring-forming carbon atoms, trivalent silyl group having 1 to 20 carbon atoms, substituted or unsubstituted trivalent aryl group having 6 to 24 ring-forming carbon atoms or substituted or unsubstituted trivalent heteroaryl group having 3 to 24 ring-forming atoms and being bonded to the benzene ring (c) in carbon-carbon bonding. When n is 4, L₃ represents tetravalent alkane having 1 to 20 carbon atoms, substituted or unsubstituted tetravalent cycloalkane having 3 to 20 ring-forming carbon atoms, silicon atom, substituted or unsubstituted tetravalent aryl group having 6 to 24 ring-forming carbon atoms or substituted or unsubstituted tetravalent heteroaryl group having 3 to 24 ring-forming atoms and being bonded to the benzene ring (c) in carbon-carbon bonding.

In the formulae (27) to (32), A₁ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₁ in carbon-carbon bonding.

In the formulae (27) to (29), A₂ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₂ in carbon-carbon bonding. However, when X₉ and X₁₀, X₁₁ and X₁₂ or X₁₃ and X₁₄ are O or S and both of L₁ and L₂ are single bonds, A₁ and A₂ are not hydrogen atoms at the same time.

In the formulae (27) to (32), Y₁, Y₂ and Y₃ each represent an alkyl group having 1 to 20 carbon atoms, substituted or unsubstituted cycloalkyl group having 3 to 20 ring-forming carbon atoms, alkoxy group having 1 to 20 carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to the benzene rings (a), (b) and (c) in carbon-carbon bonding. The number of Y₁ and Y₃ is 0, 1, 2 or 3 while the number of Y₂ is 0, 1 or 2.

In the formulae (27) to (32), A₁, A₂, L₁, L₂ and L₃ do not contain any carbonyl groups.

Further, the ladder-type heterocycle-containing compound may be a compound represented by the following general formulae (33) or (34).

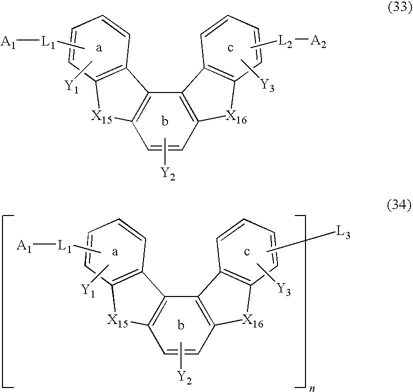

In the formulae (33) and (34), X₁₅ and X₁₆ each independently represent O, S or N—R₁.

In the formulae (33) and (34), R₁ represents an alkyl group having 1 to 20 carbon atoms, substituted or unsubstituted cycloalkyl group having 3 to 20 ring-forming carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms. However, when X₁₅ and X₁₆ are both N—R₁, at least one R₁ is a substituted or unsubstituted monovalent fused heteroaryl group having 8 to 24 ring-forming atoms.

In the formula (34), n represents 2, 3 or 4, which respectively mean a dimer, trimer and tetramer each of which uses L₃ as the bonding group.

In the formulae (33) and (34), L₁ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (a) in carbon-carbon bonding.

In the formula (33), L₂ represents a single bond, an alkyl group or alkylene group having 1 to 20 carbon atoms, substituted or unsubstituted cycloalkyl group or cycloalkylene group having 3 to 20 ring-forming carbon atoms, monovalent or divalent silyl group having 2 to 20 carbon atoms, substituted or unsubstituted monovalent or divalent aryl group having 6 to 24 ring-forming carbon atoms or substituted or unsubstituted monovalent or divalent heteroaryl group having 3 to 24 ring-forming atoms and being bonded to the benzene ring (c) in carbon-carbon bonding.

In the formula (34), when n is 2, L₃ represents a single bond, alkylene group having 1 to 20 carbon atoms, substituted or unsubstituted cycloalkylene group having 3 to 20 ring-forming carbon atoms, divalent silyl group having 2 to 20 carbon atoms, substituted or unsubstituted divalent aryl group having 6 to 24 ring-forming carbon atoms or substituted or unsubstituted divalent heteroaryl group having 3 to 24 ring-forming atoms and being bonded to the benzene ring (c) in carbon-carbon bonding. When n is 3, L₃ represents a trivalent alkane having 1 to 20 carbon atoms, substituted or unsubstituted trivalent cycloalkane having 3 to 20 ring-forming carbon atoms, trivalent silyl group having 1 to 20 carbon atoms, substituted or unsubstituted trivalent aryl group having 6 to 24 ring-forming carbon atoms or substituted or unsubstituted trivalent heteroaryl group having 3 to 24 ring-forming atoms and being bonded to the benzene ring (c) in carbon-carbon bonding. When n is 4, L₃ represents tetravalent alkane having 1 to 20 carbon atoms, substituted or unsubstituted tetravalent cycloalkane having 3 to 20 ring-forming carbon atoms, silicon atom, substituted or unsubstituted tetravalent aryl group having 6 to 24 ring-forming carbon atoms or substituted or unsubstituted tetravalent heteroaryl group having 3 to 24 ring-forming atoms and being bonded to the benzene ring (c) in carbon-carbon bonding.

In the formulae (33) and (34), A₁ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₁ in carbon-carbon bonding.

In the formula (33), A₂ represents a hydrogen atom, substituted or unsubstituted cycloalkyl group having 3 to 20 ring-forming carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to L₂ in carbon-carbon bonding. However, when X₁₅ and X₁₆ are O or S and both of L₁ and L₂ are single bonds, A₁ and A₂ are not hydrogen atoms at the same time.

In the formulae (33) and (34), Y₁, Y₂ and Y₃ each represent an alkyl group having 1 to 20 carbon atoms, substituted or unsubstituted cycloalkyl group having 3 to 20 ring-forming carbon atoms, alkoxy group having 1 to 20 carbon atoms, aralkyl group having 7 to 24 carbon atoms, silyl group having 3 to 20 carbon atoms, substituted or unsubstituted aryl group having 6 to 24 ring-forming carbon atoms or substituted or unsubstituted heteroaryl group having 3 to 24 ring-forming atoms and being bonded to the benzene rings (a), (b) and (c) in carbon-carbon bonding. The number of Y₁ and Y₃ is 0, 1, 2 or 3 while the number of Y₂ is 0, 1 or 2.

In the formulae (33) and (34), A₁, A₂, L₁, L₂ and L₃ do not contain any carbonyl groups.

In the general formula (22), n is preferably 2. In the general formula (25) or (26), n is preferably 2. In the general formula (30), (31) or (32), n is preferably 2. In the general formula (34), n is preferably 2. In the general formula (23) or (24), the total number of the substituents represented by Y₁, Y₂ and Y₃ is preferably 3 or less. In the general formula (25) or (26), the total number of the substituents represented by Y₁, Y₂ and Y₃ in a single structure within [ ]ₙ is preferably 3 or less. In the general formula (27), (28) or (29), the total number of the substituents represented by Y₁, Y₂ and Y₃ is preferably 3 or less. In the general formula (30), (31) or (32), the total number of the substituents represented by Y₁, Y₂ and Y₃ in a single structure within [ ]ₙ is preferably 3 or less.

In the general formula (33), the total number of the substituents represented by Y₁, Y₂ and Y₃ is preferably 3 or less. In the general formula (34), the total number of the substituents represented by Y₁, Y₂ and Y₃ in a single structure within [ ]ₙ is preferably 3 or less. In the general formula (21) or (22), it is preferable that: both of X₁ and X₂ or both of X₃ and X₄ are represented by N—R₁; and N—R₁ of X₁ and N—R₁ of X₂ or N—R₁ of X₃ and N—R₁ of X₄ are different. In the general formulae (23) to (26), it is preferable that: both of X₅ and X₆ or both of X₇ and X₈ are represented by N—R₁; and N—R₁ of X₅ and N—R₁ of X₆ or N—R₁ of X₇ and N—R₁ of X₈ are different. In the general formulae (27) to (32), it is preferable that: both of X₉ and X₁₀, both of X₁₁ and X₁₂ or both of X₁₃ and X₁₄ are represented by N—R₁; and N—R₁ of X₉ and N—R₁ of X₁₀, N—R₁ of X₁₁ and N—R₁ of X₁₂ or N—R₁ of X₁₃ and N—R₁ of X₁₄ are different. In the general formula (33) or (34), it is preferable that: both of X₁₅ and X₁₆ are represented by N—R₁; and N—R₁ of X₁₅ and N—R₁ of X₁₆ are different. In the general formula (21) or (22), both of X₁ and X₂ or both of X₃ and X₄ are preferably oxygen atoms. In the general formulae (23) to (26), both of X₅ and X₆ or both of X₇ and X₈ are preferably oxygen atoms.

In the general formulae (27) to (32), both of X₉ and X₁₀, both of X₁₁ and X₁₂ or both of X₁₃ and X₁₄ are preferably oxygen atoms. In the general formula (33) or (34), both of X₁₅ and X₁₆ are preferably oxygen atoms.

Examples of the ladder-type heterocycle-containing compounds represented by the above general formulae (21) to (34) are shown below.

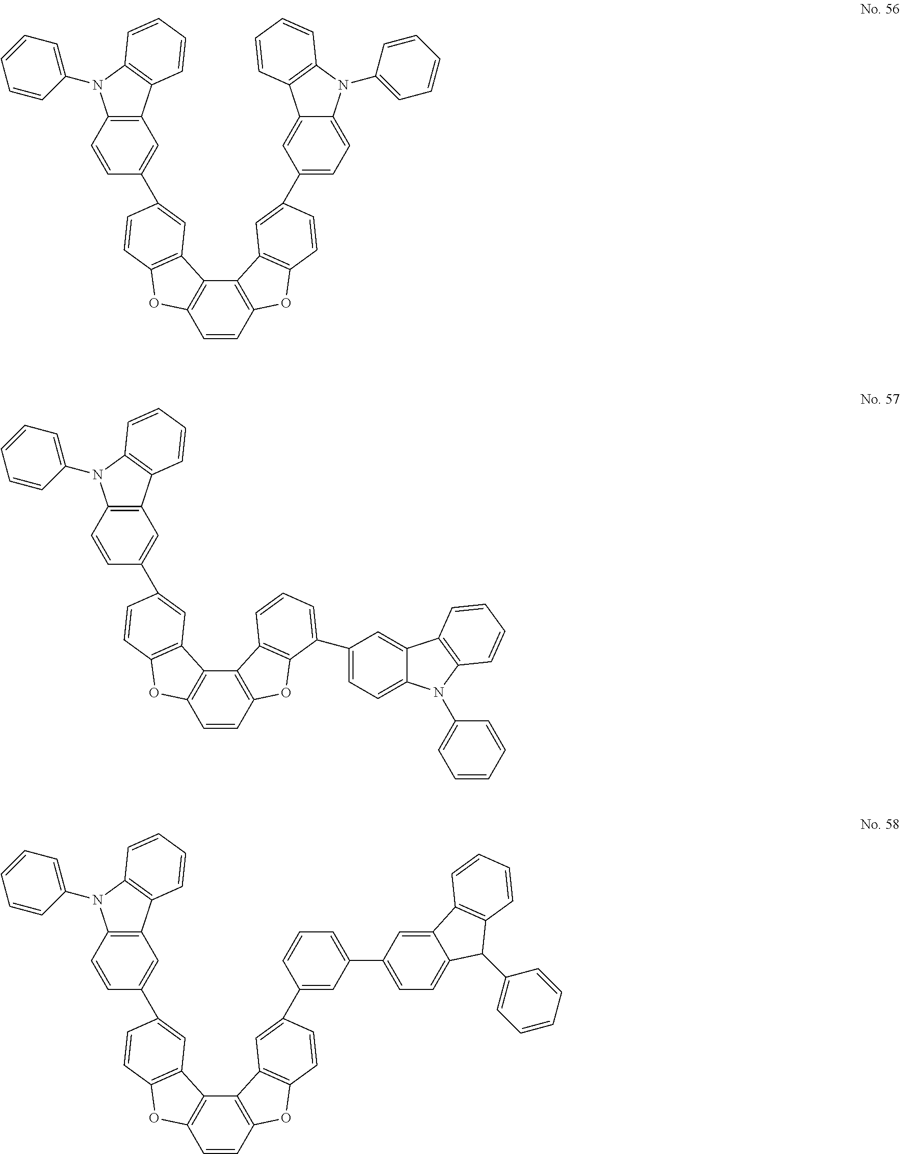

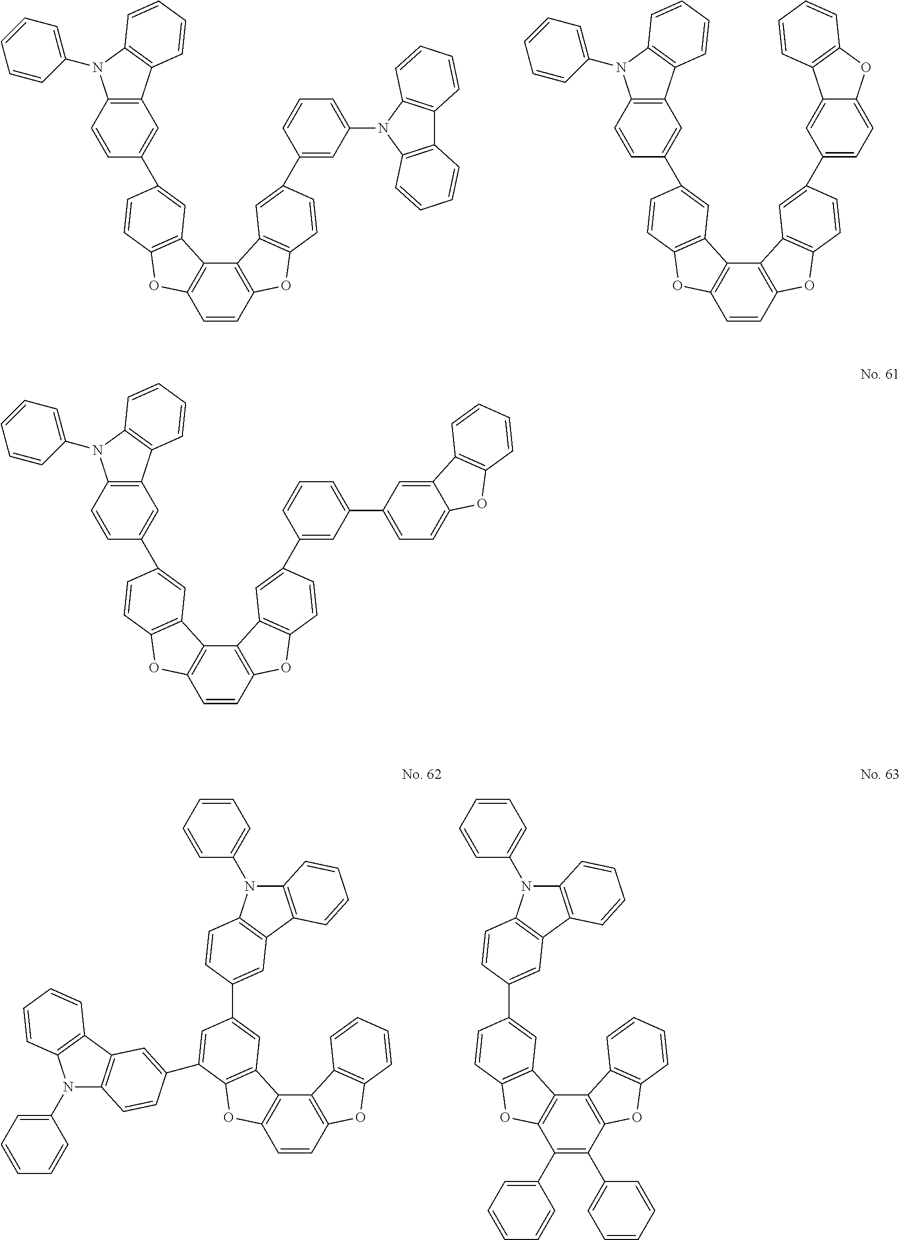

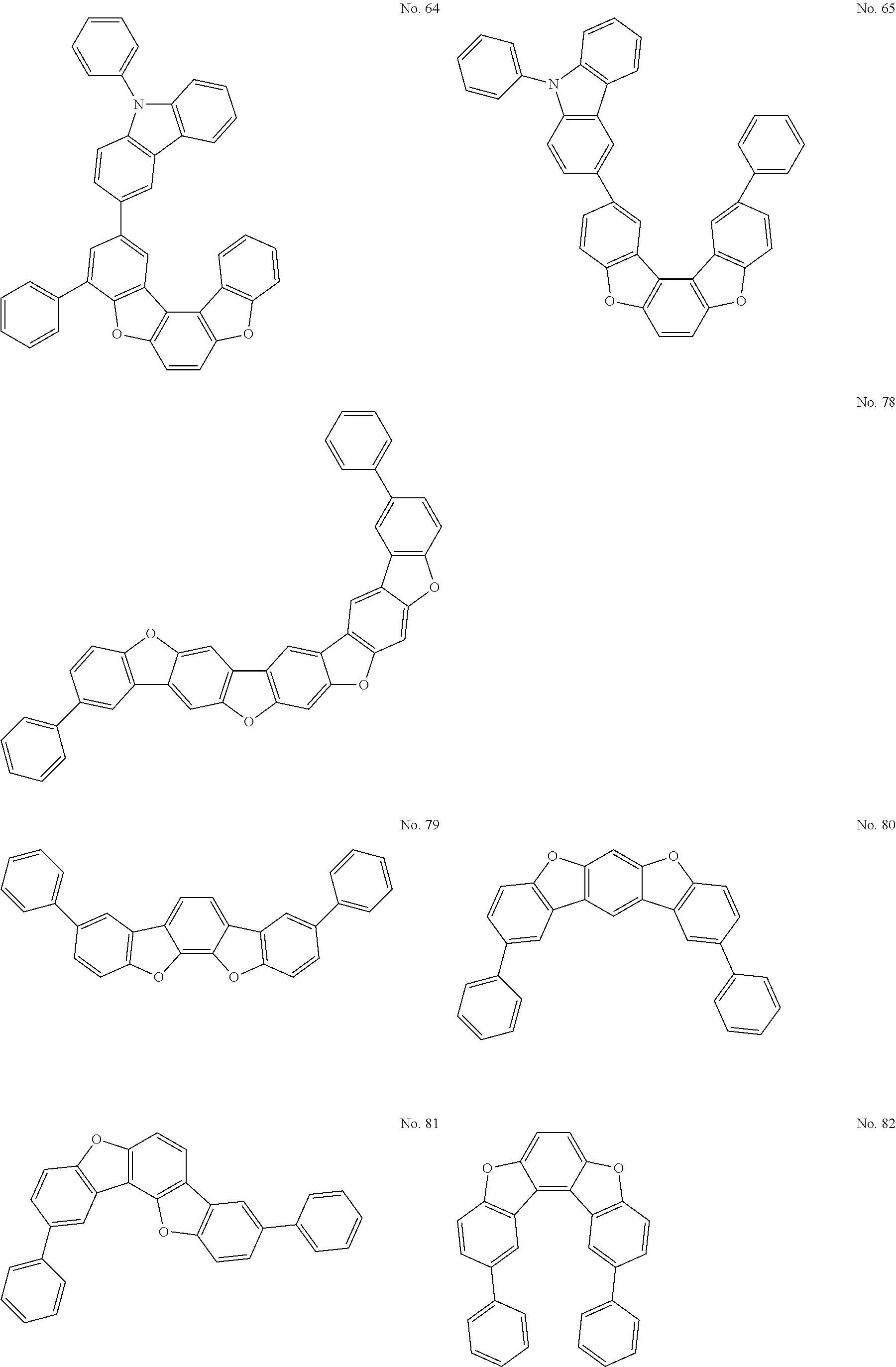

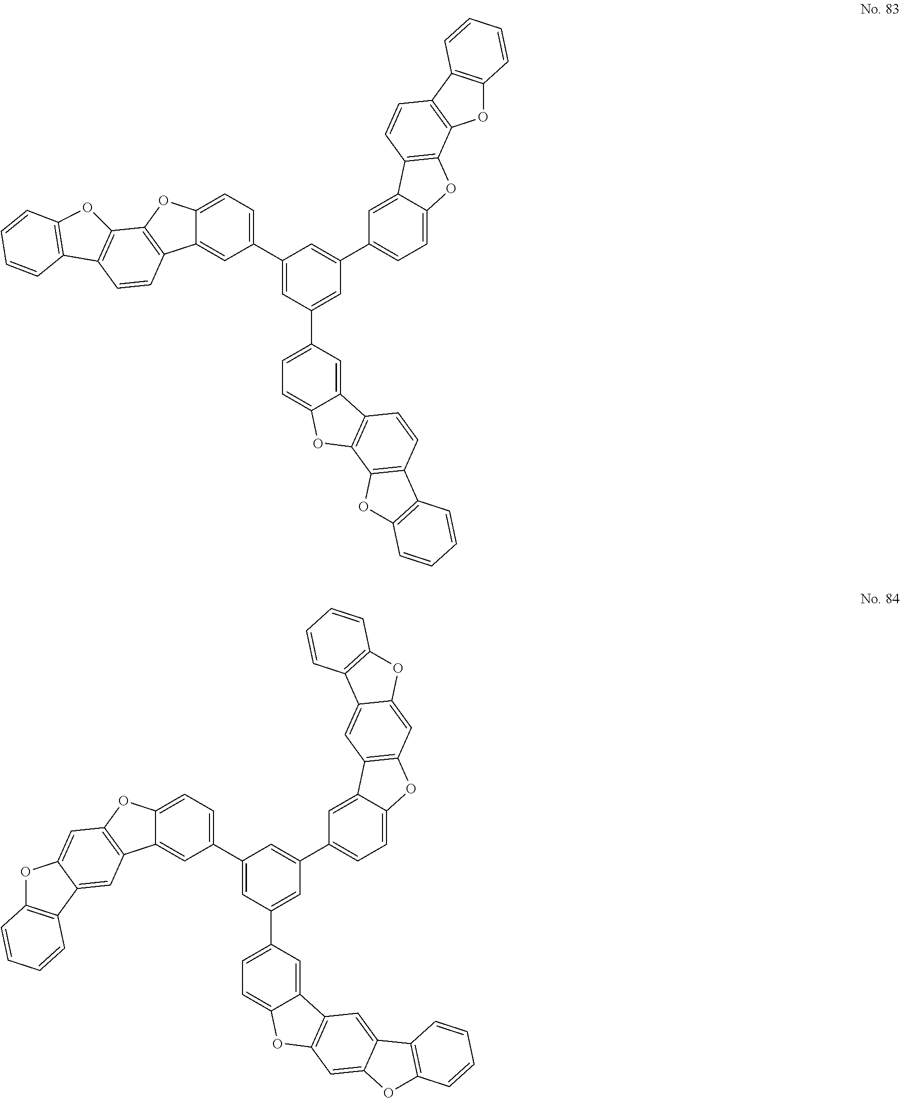

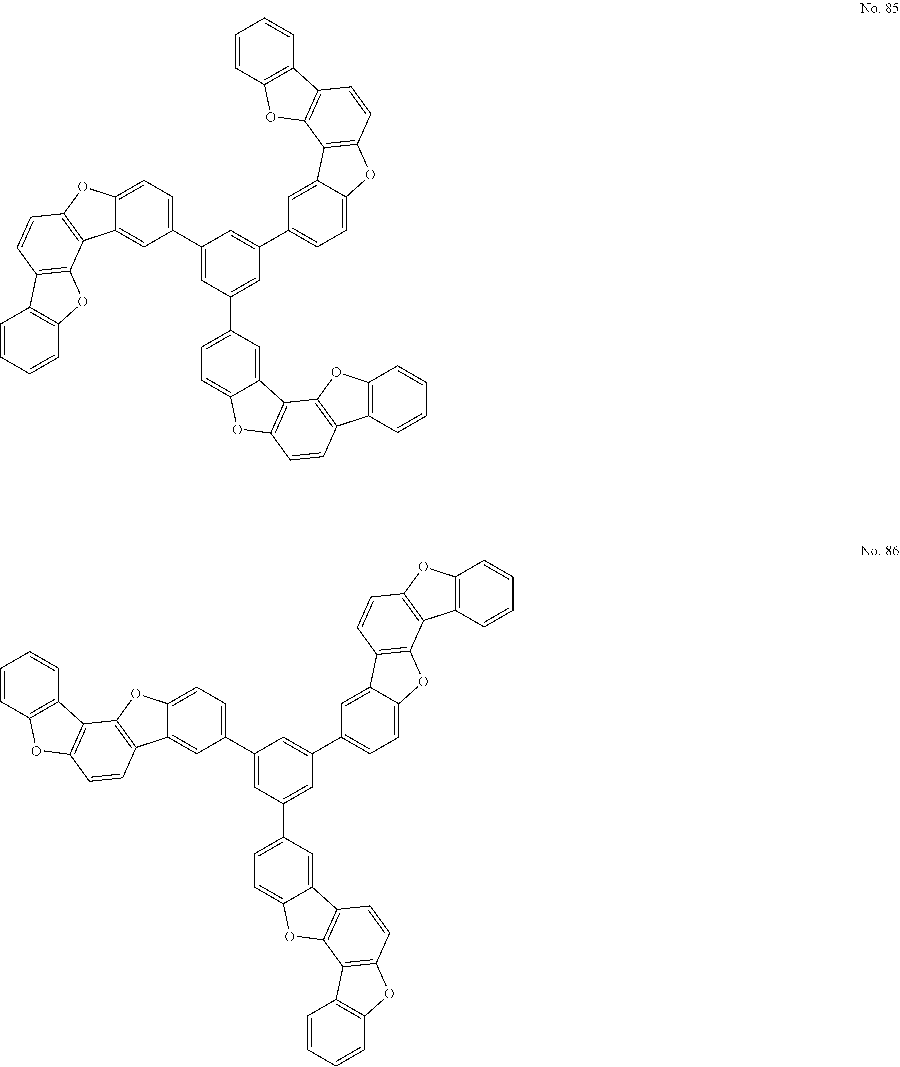

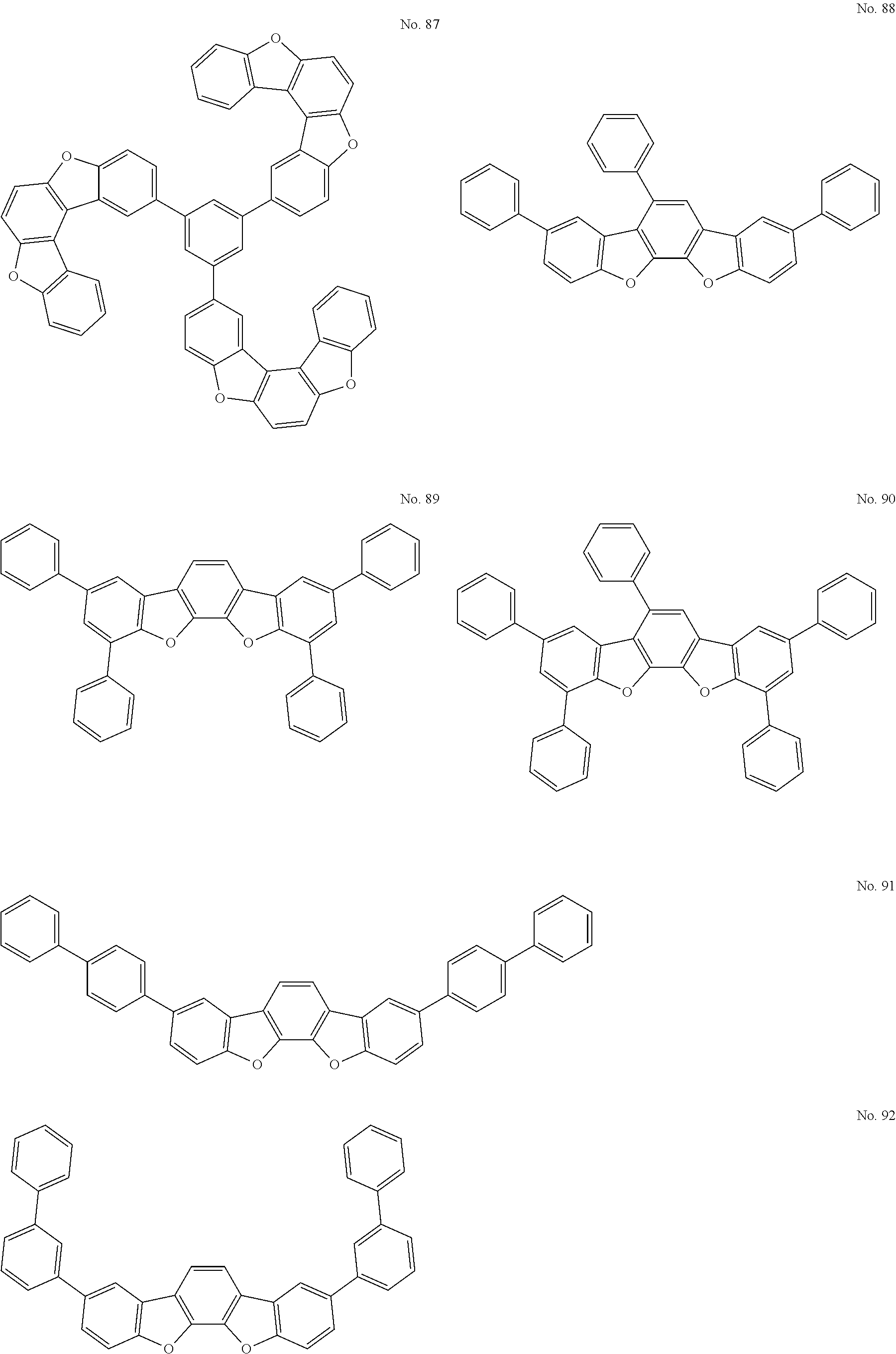

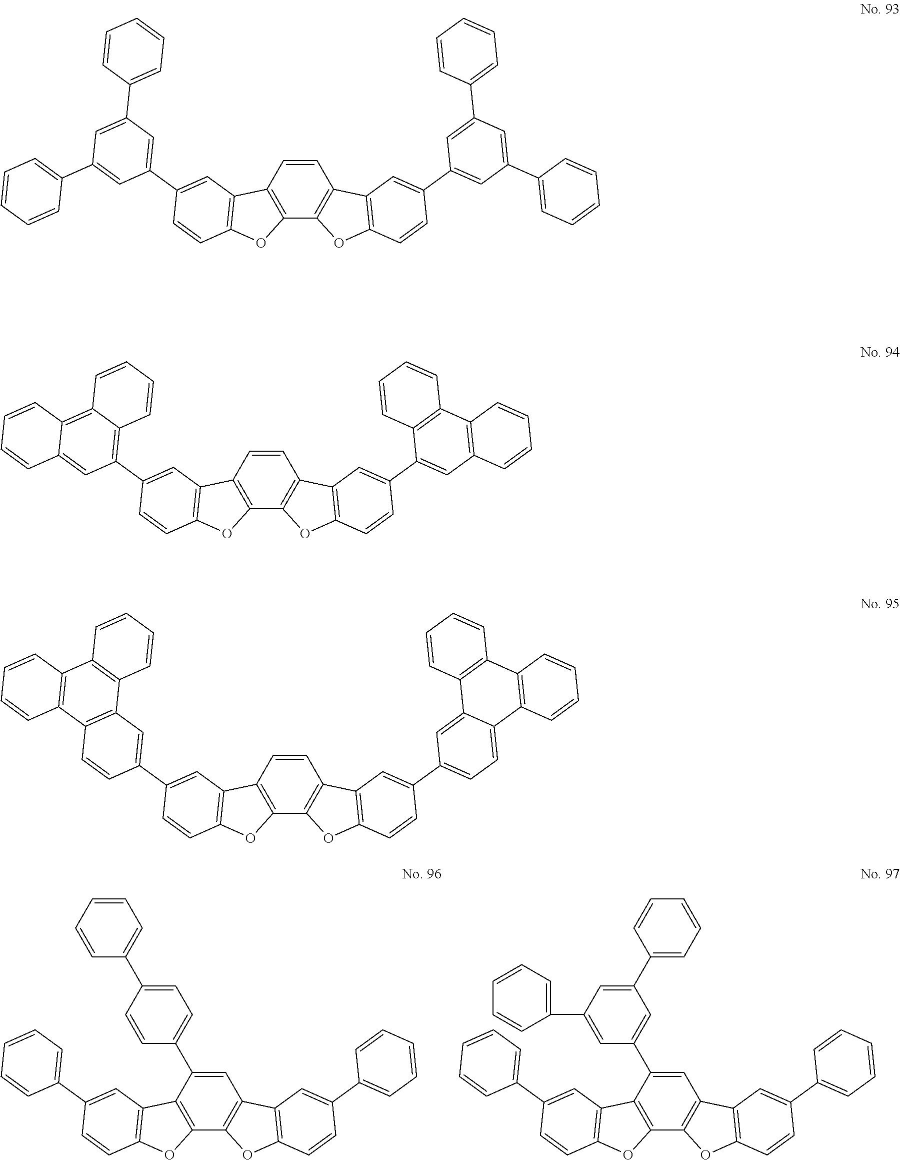

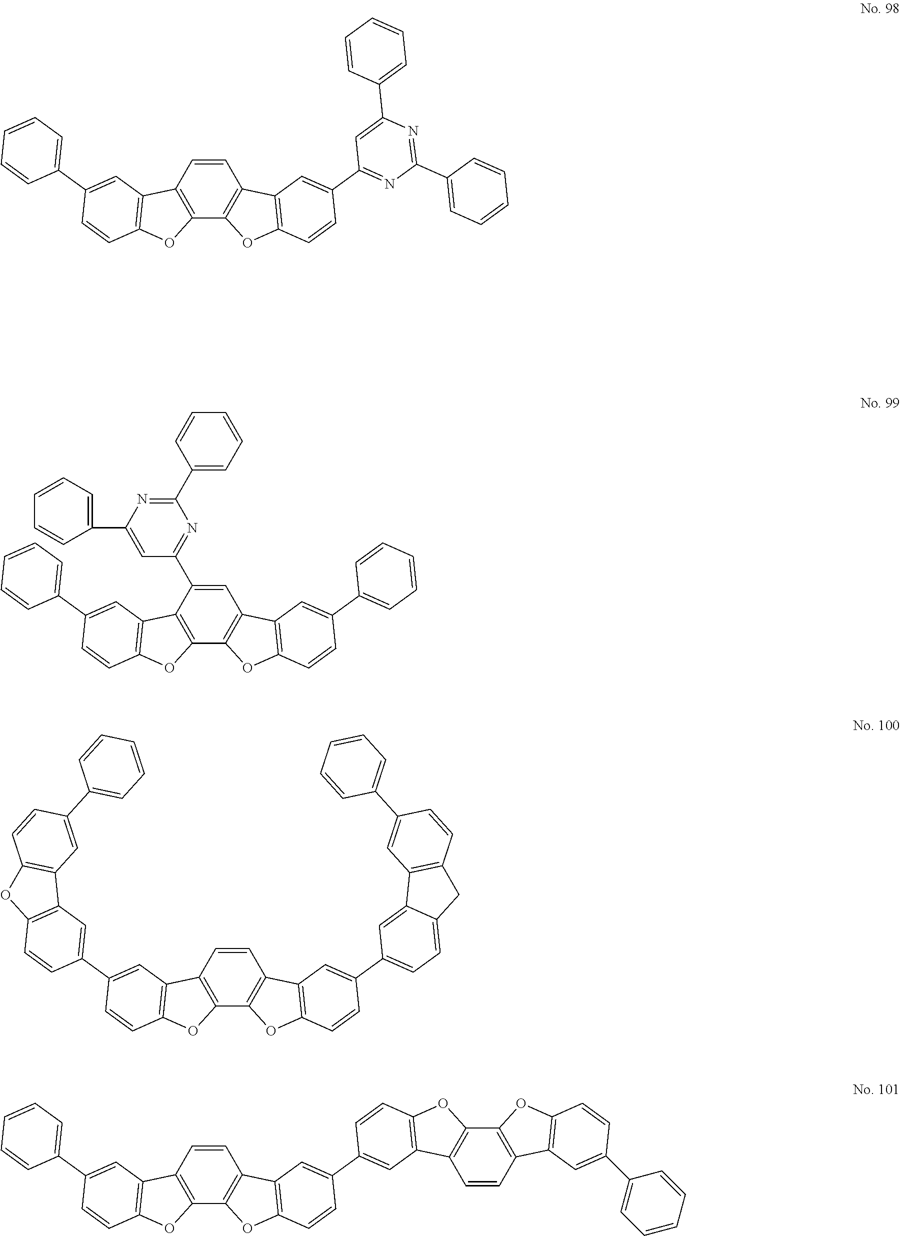

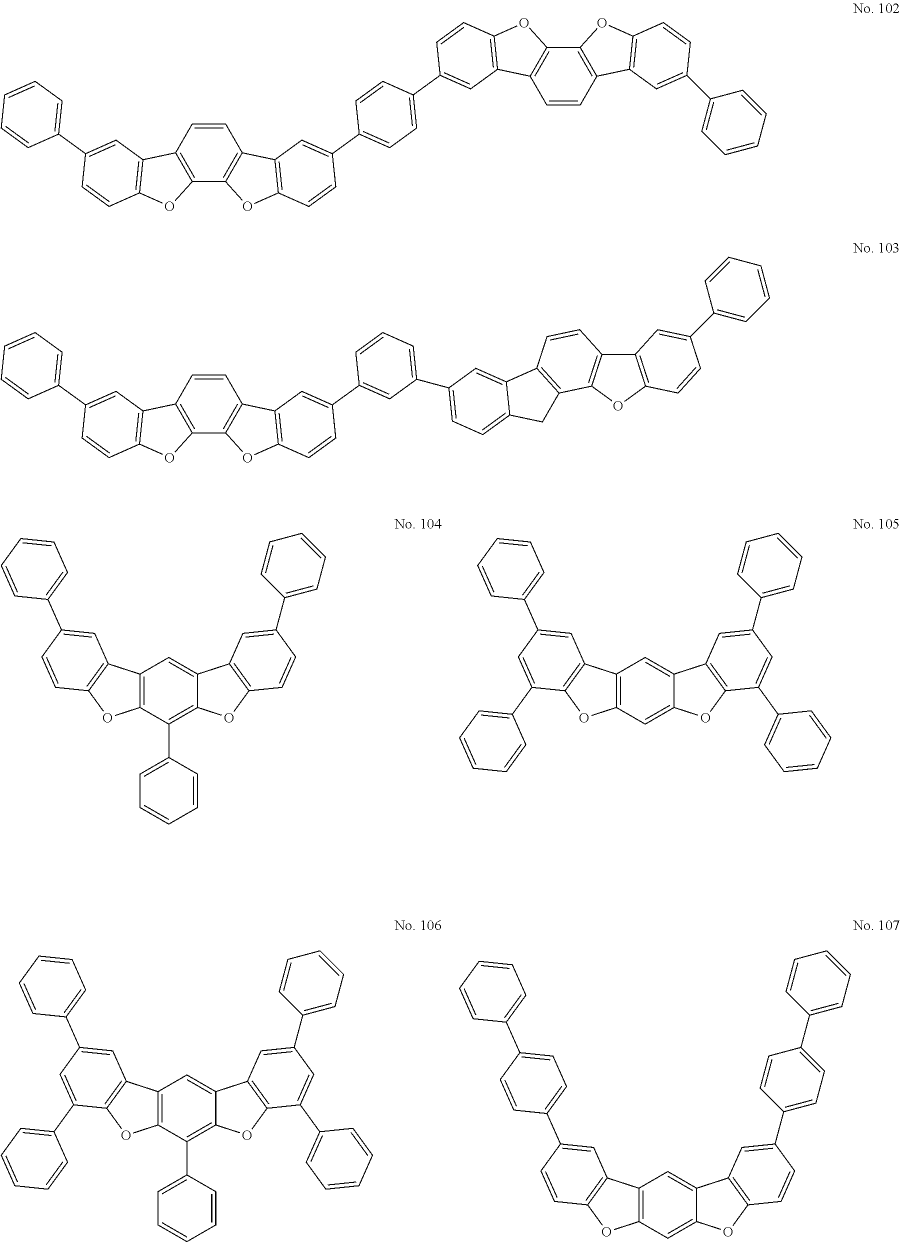

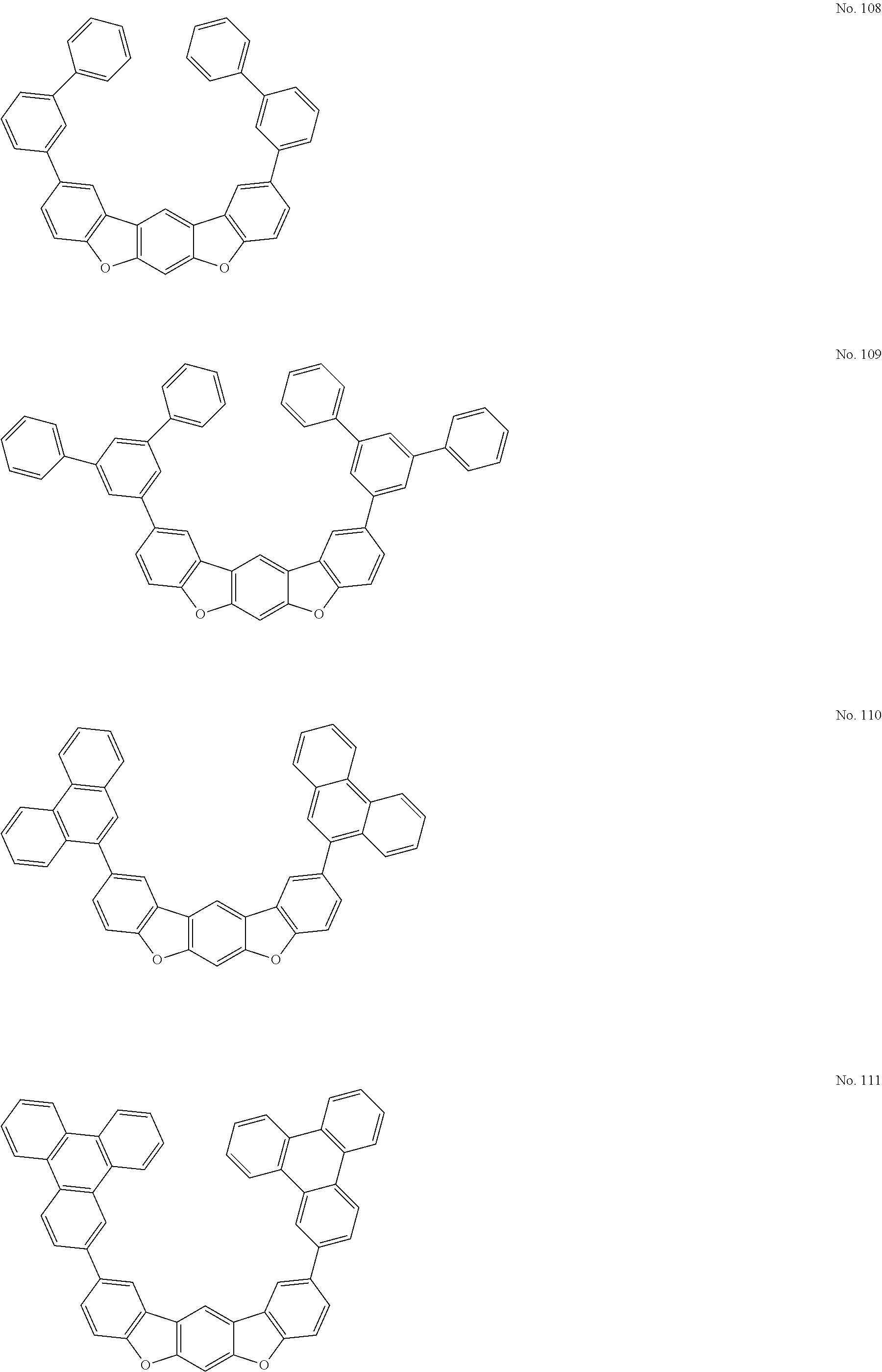

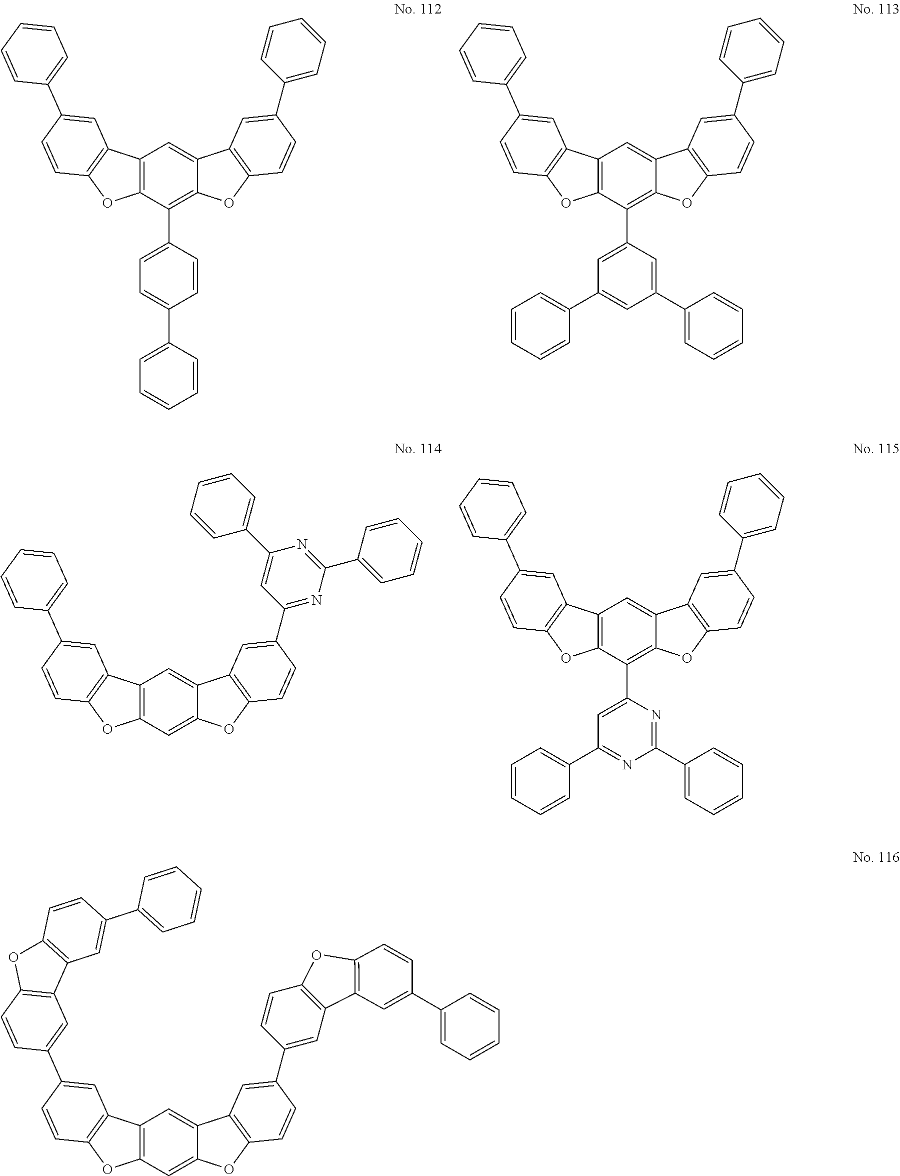

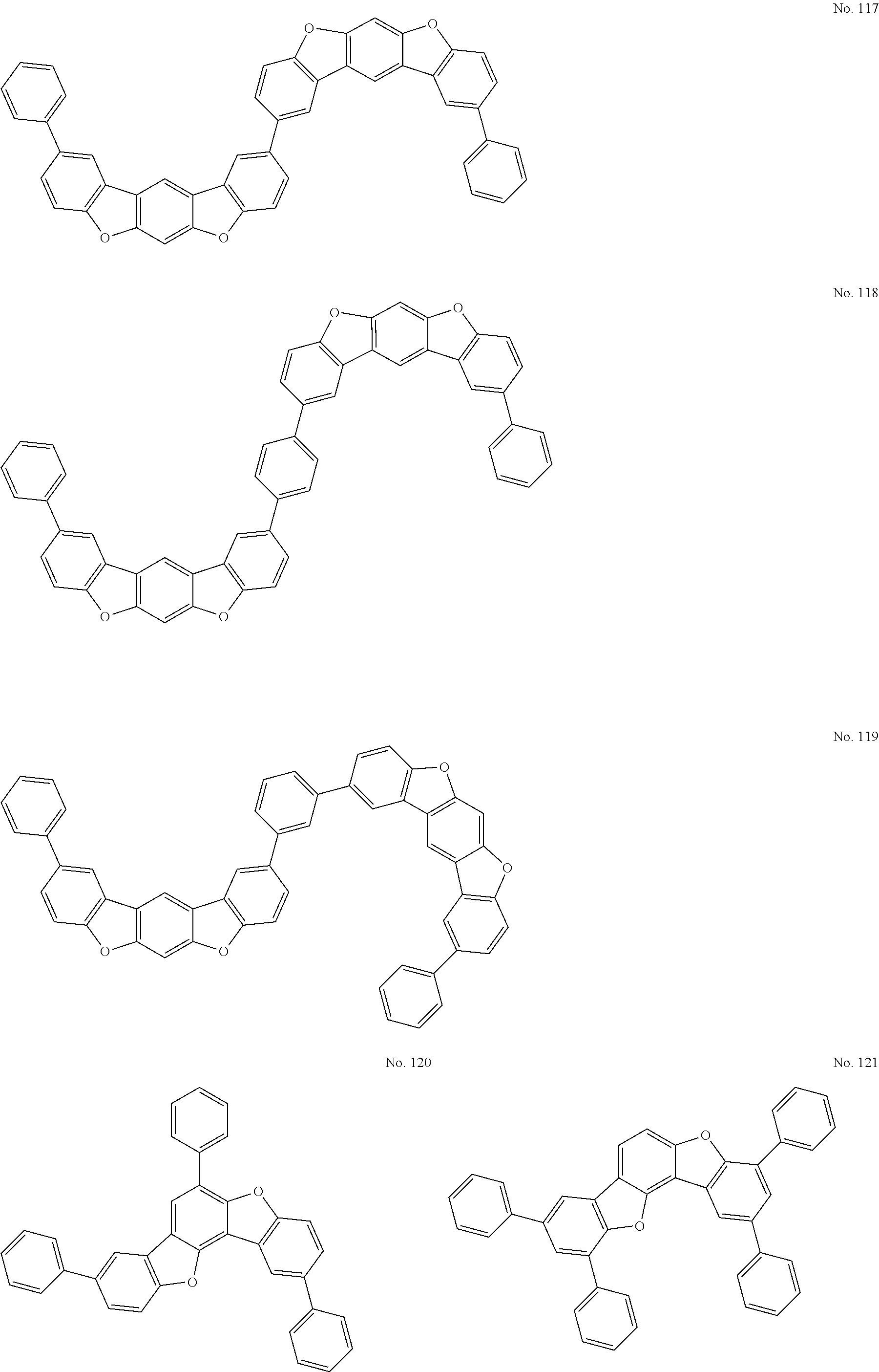

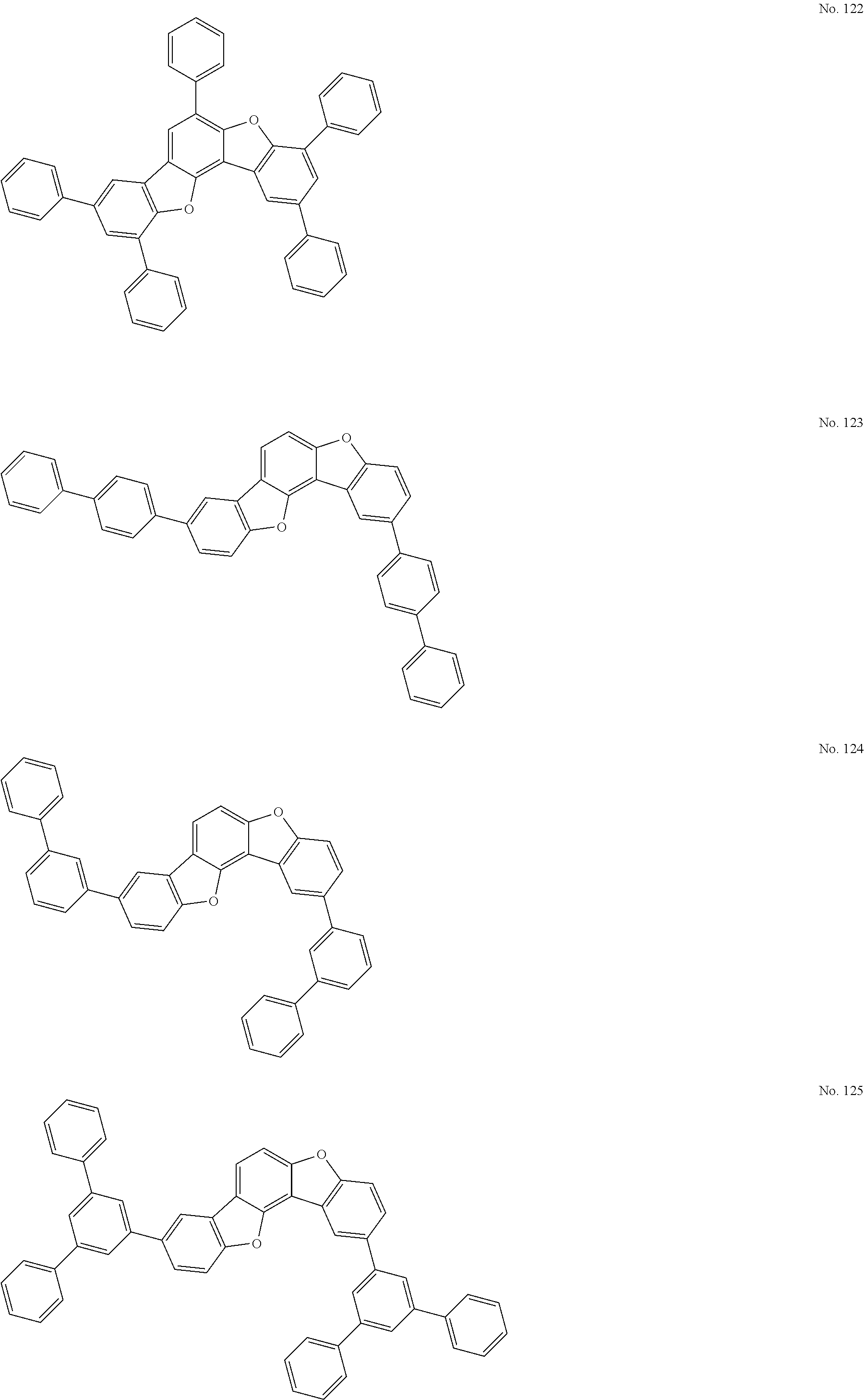

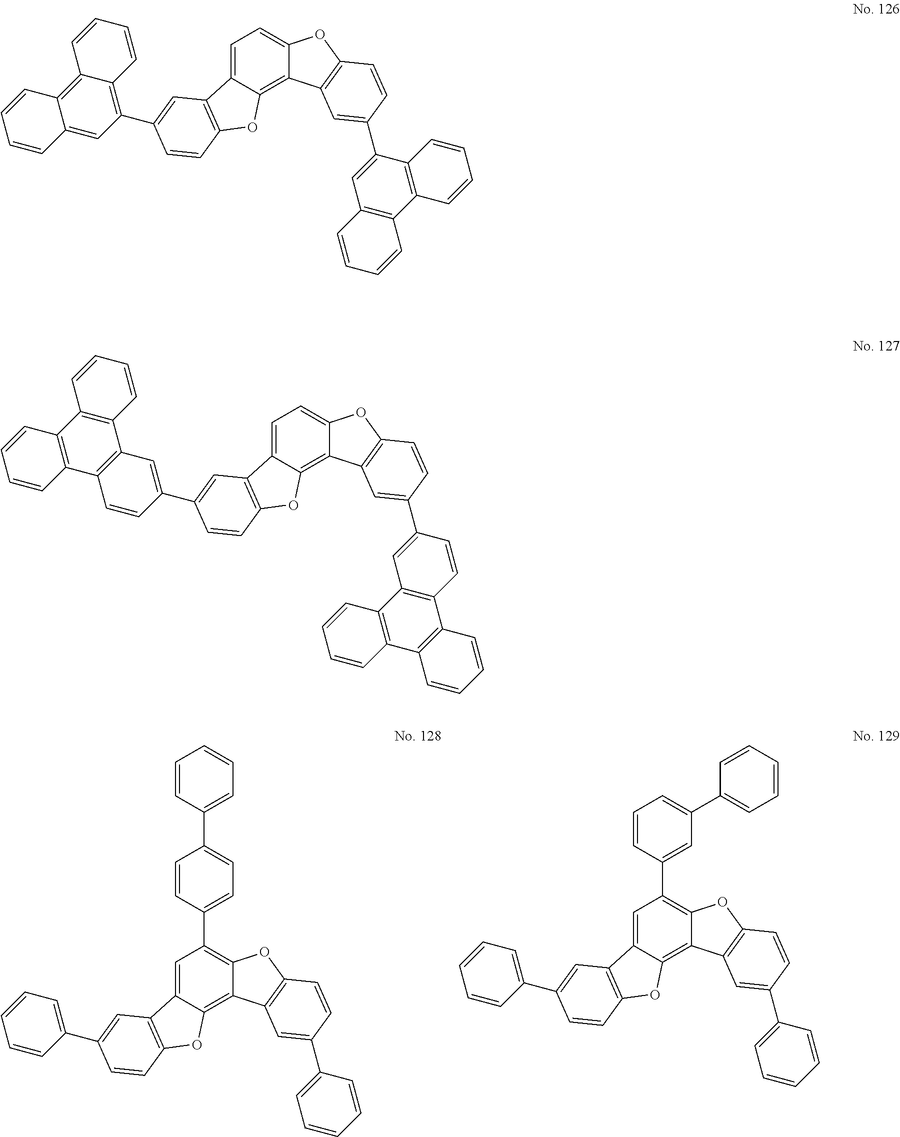

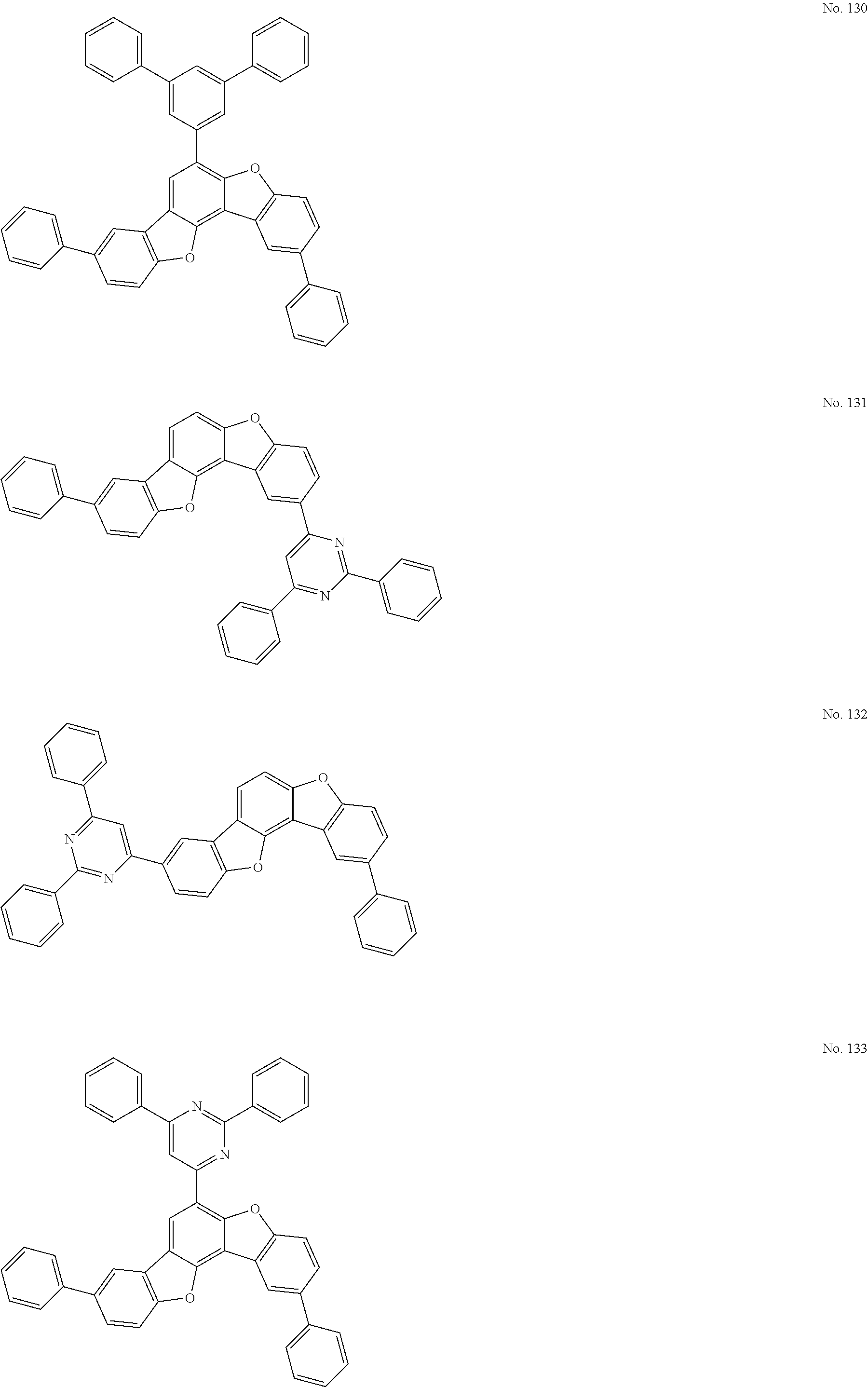

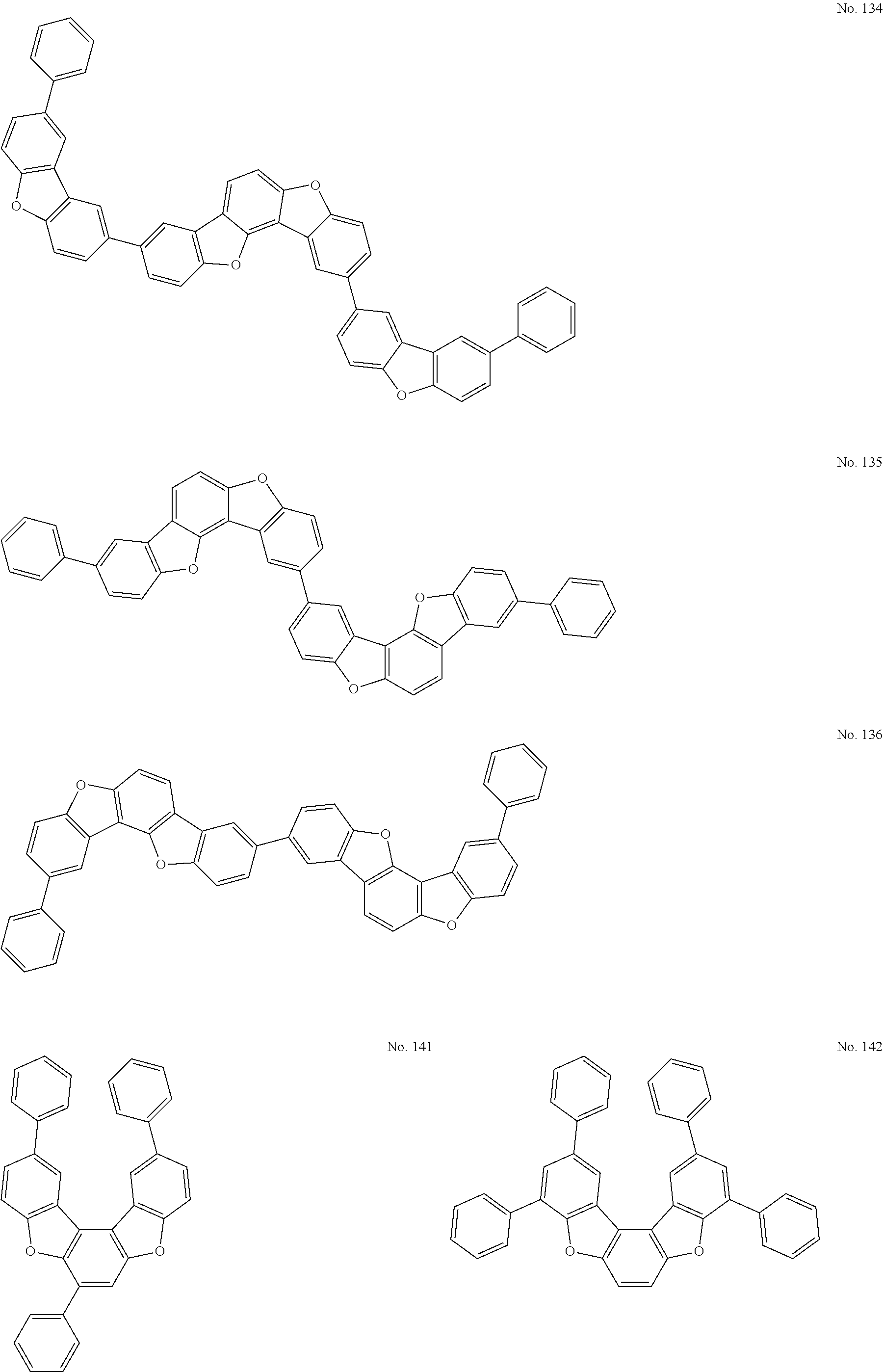

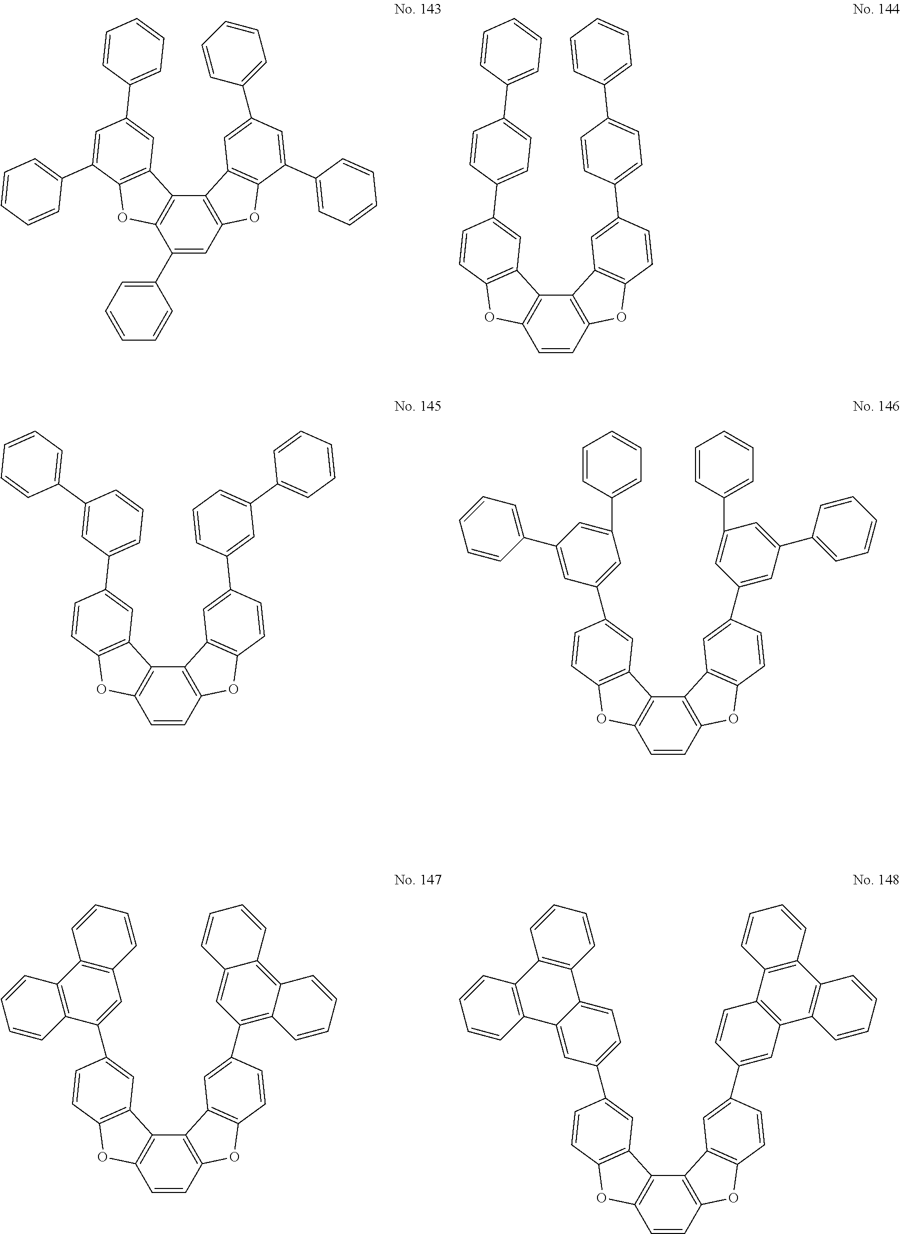

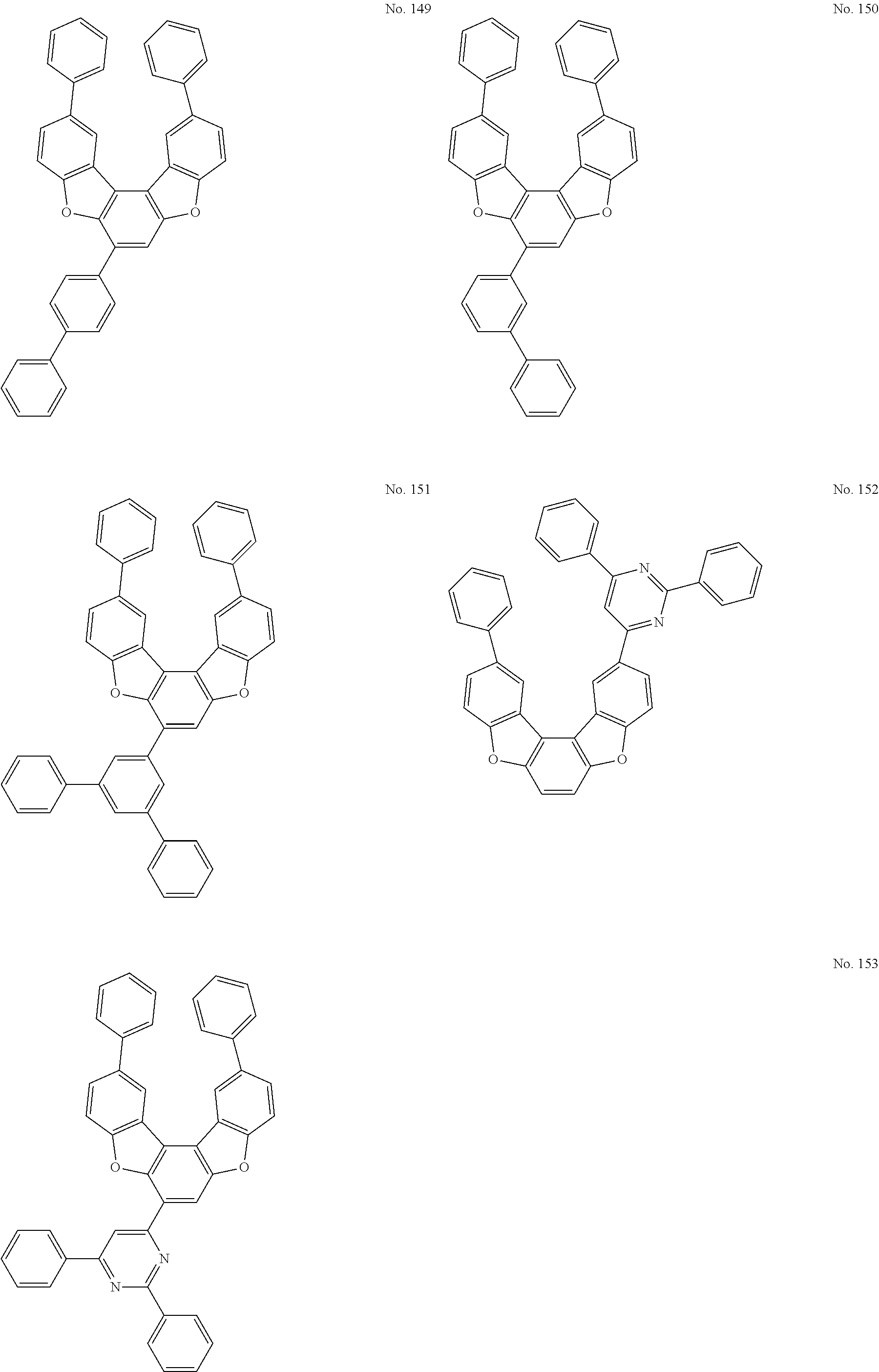

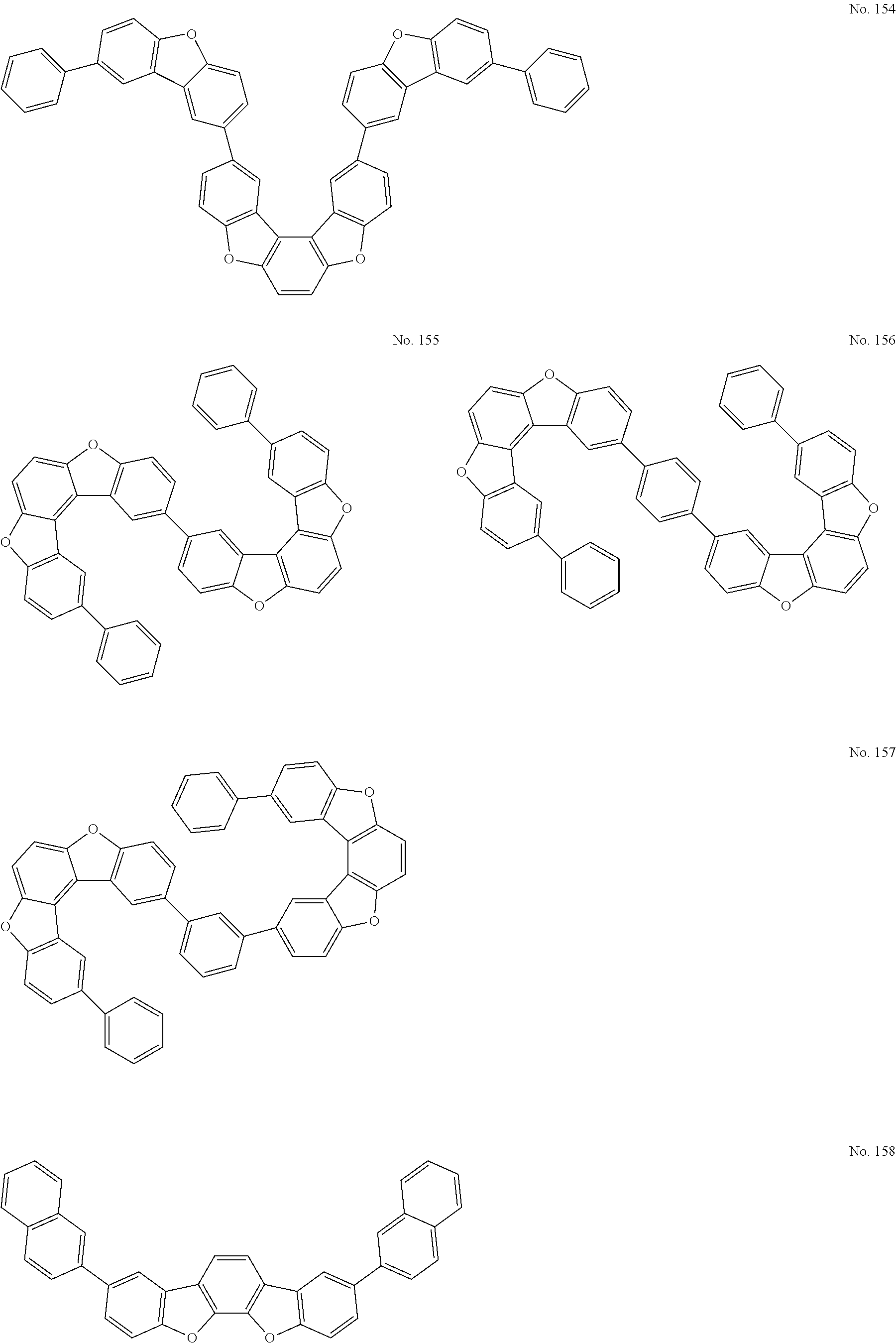

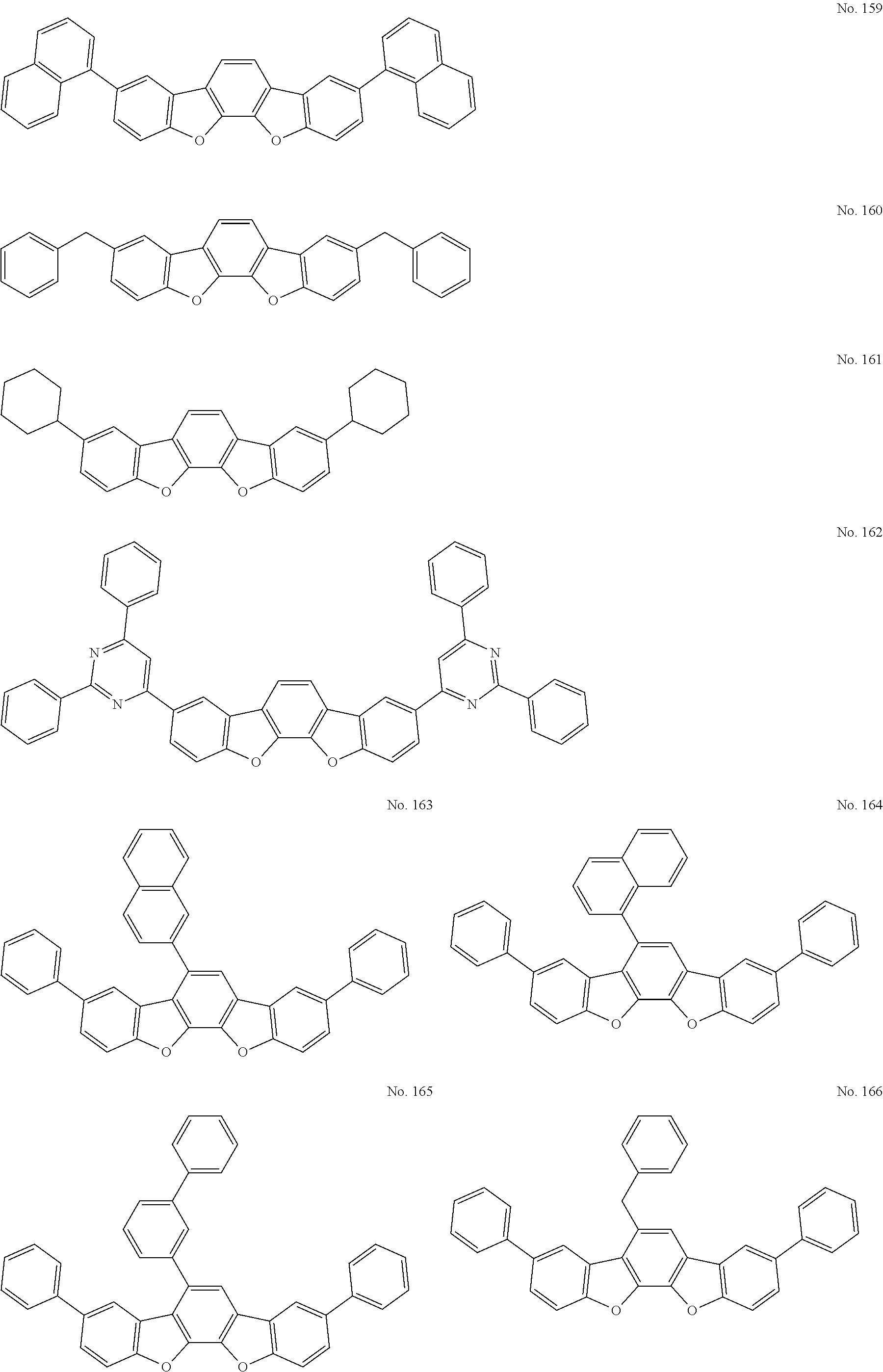

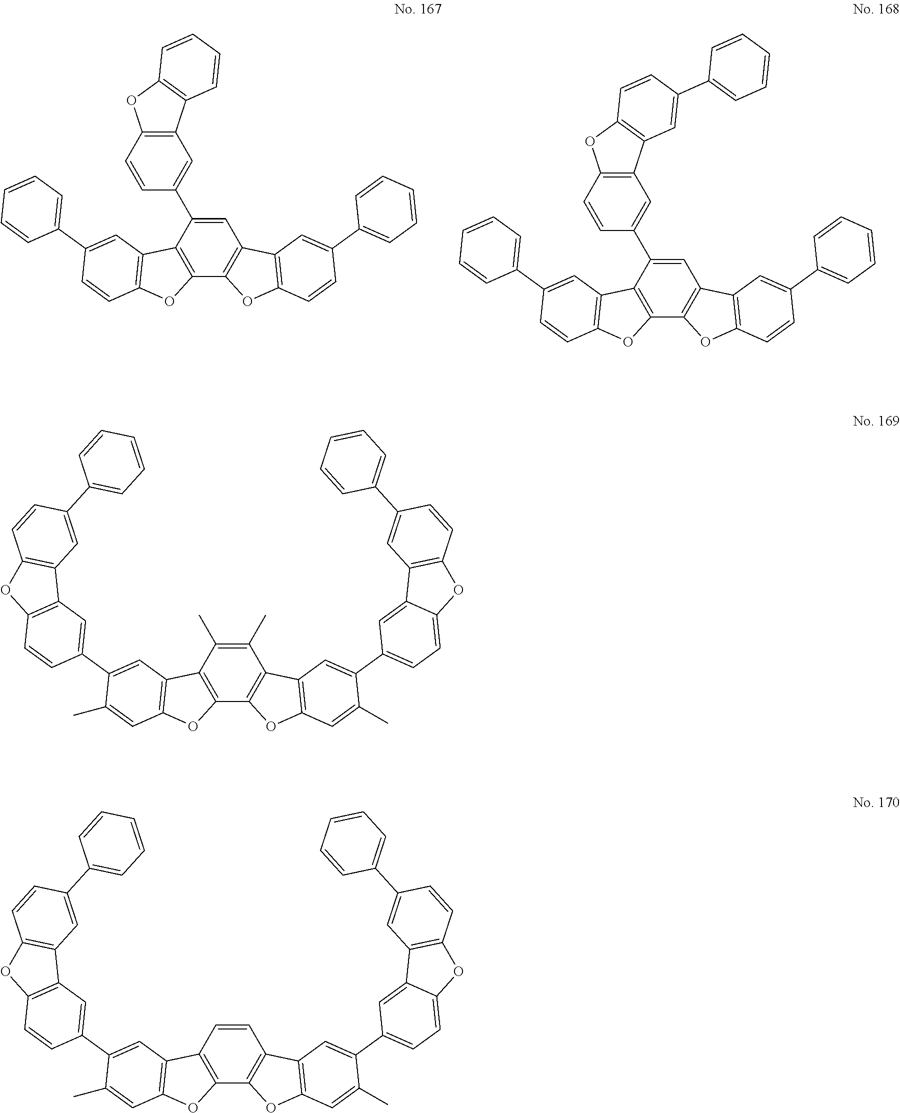

Further, the heterocycle-containing compound may be the following azole compound.

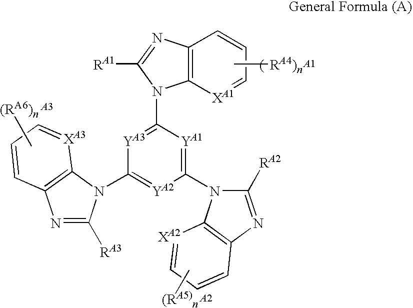

In the general formula (A), R^{A1}, R^{A2} and R^{A3} each represent a hydrogen atom or an aliphatic hydrocarbon group. R^{A4}, R^{A5} and R^{A6} each represent a substituent. n^{A1}, n^{A2} and n^{A3} each represent an integer of 0 to 3. X^{A1}, X^{A2} and X^{A3} each represent a nitrogen atom or C—R^{x} (R^{x} represents a hydrogen atom or a substituent). Y^{A1}, Y^{A2} and Y^{A3} each represent a nitrogen atom or C—R^{YX} (R^{YX} represents a hydrogen atom or a substituent).

Further, the fused polycyclic aromatic derivative or the heterocycle-containing compound may be the following phenanthroline derivative.

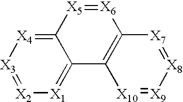

In the above formula, X₁ to X₁₀ each represent N or C—R. R represents a substituent and represents a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

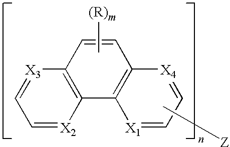

In the above formula, X₁, X₂, X₃ and X₄ each independently represent N or C-A1. A1 represents a substituent and represents a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group. n represents a natural number of 2 or more, and Z represents a bonding group. R represents a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

Further, the heterocycle-containing compound may be the following metal complex.

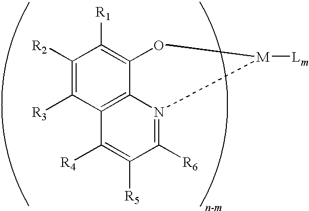

In the above formula, when n=2, M represents a divalent metal ion (magnesium, zinc, copper, palladium, platinum or gold). When n=3, M represents a trivalent metal ion (aluminum, yttrium, scandium or rare earths). R₁ to R₆ each independently represent a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

m is 0 or 1. When m is 1, L is any one of the following,

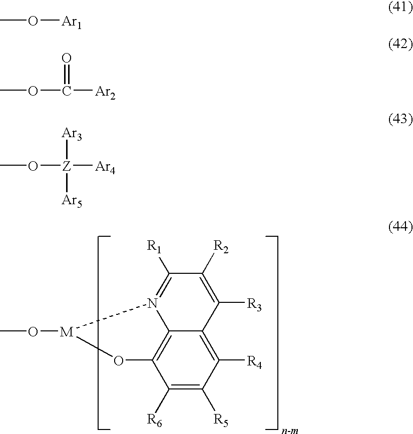

in which: A₁ to A₅ each independently represent a substituted or unsubstituted aromatic hydrocarbon ring group or substituted or unsubstituted aromatic heterocyclic group; Z represents silicon or germanium; and R₁ to R₆ each independently represent a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

Further, the heterocycle-containing compound may be the following metal complex.

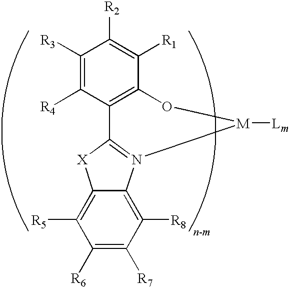

In the above formula, when n=2, M represents a divalent metal ion (magnesium, zinc, copper, palladium, platinum or gold). When n=3, M represents a trivalent metal ion (aluminum, yttrium, scandium or rare earths). X represents O, S pr M-Y (Y represents an H atom, methyl group, ethyl group or aryl group), and R₁ to R₈ each independently represent a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

m is 0 or 1. When m is 1, L is any one of the following,

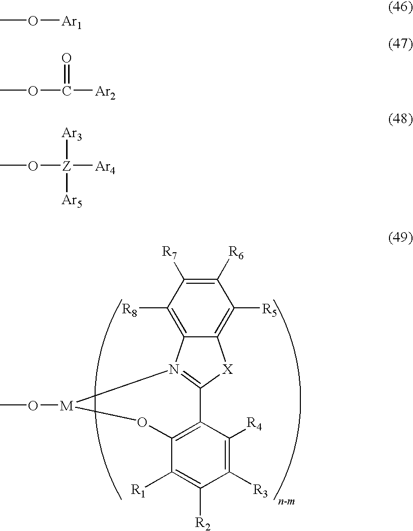

in which: A₁ to A₅ each independently represent a substituted or unsubstituted aromatic hydrocarbon ring group or substituted or unsubstituted aromatic heterocyclic group; Z represents silicon or germanium; and R₁ to R₈ each independently represent a hydrogen atom, alkyl group, aralkyl group, alkenyl group, cyano group, amino group, amide group, alkoxycarbonyl group, carboxyl group, alkoxy group, substituted or unsubstituted aromatic hydrocarbon group or substituted or unsubstituted aromatic heterocyclic group.

It is a preferable combination that: the fused polycyclic aromatic derivatives in the first emitting layer and the second emitting layer are naphthalene derivatives; and the heterocycle-containing compound in the third emitting layer is a ladder-type heterocycle-containing compound.

The naphthalene derivative preferably contains at least one skeleton selected from a phenanthrene ring, florene ring, fluoranthene ring, benzo[b]fluoranthene ring, benzochrysene ring and benzophenanthrene ring.

The ladder-type heterocycle-containing compound is preferably a ladder-type furan compound.

It is a preferable combination that: the fused polycyclic aromatic derivatives in the first emitting layer and the second emitting layer each are a compound represented by the formula (1) or (2); and the heterocycle-containing compound in the third emitting layer is a compound selected from the compounds represented by the formulae (23) to (32).

### (Phosphorescent Dopant)

The phosphorescent dopant used in this exemplary embodiment, which generates phosphorescent emission, preferably contains a metal complex. The metal complex is preferably a metal complex having: a period 6 metal atom selected from Ir, Pt, Os, Au and Re; and a ligand. Particularly, the ligand preferably has an ortho-metal bond.

The phosphorescent dopant is preferably a compound containing a metal selected from iridium (Ir), osmium (Os) and platinum (Pt) because such a compound, which exhibits high phosphorescence quantum yield, can further enhance external quantum efficiency of the emitting device. The phosphorescent dopant is more preferably a metal complex such as an iridium complex, osmium complex or platinum complex, among which an iridium complex and platinum complex are more preferable and ortho metalation of an iridium complex is the most preferable

Examples of the metal complexes are shown below, among which metal complexes that emit green to red light are particularly preferred.

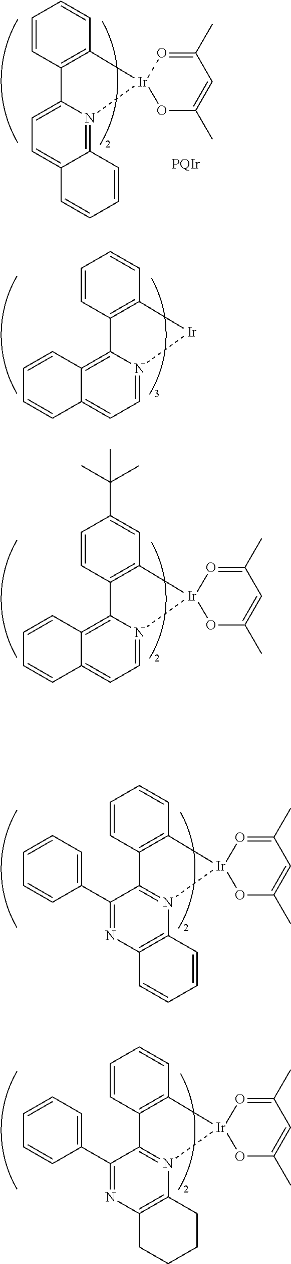

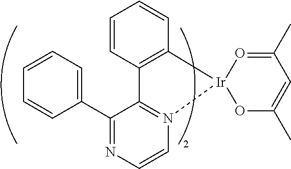

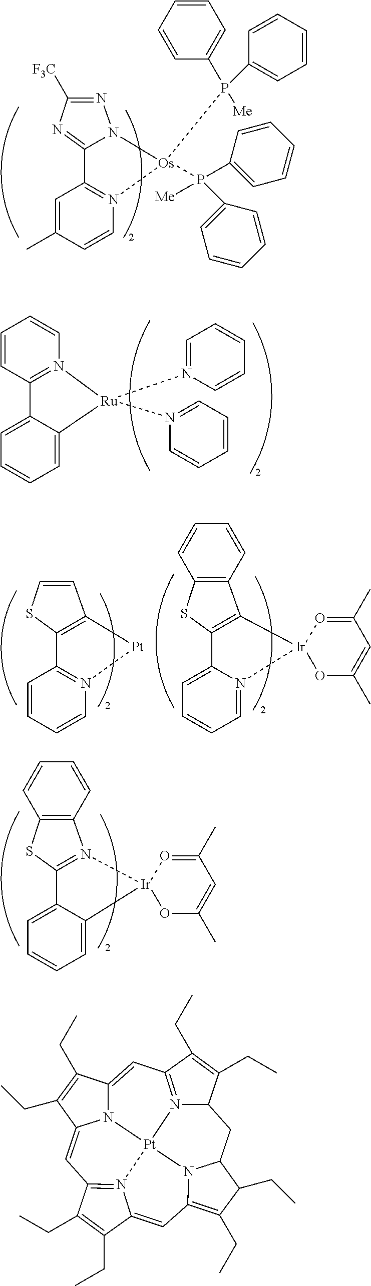

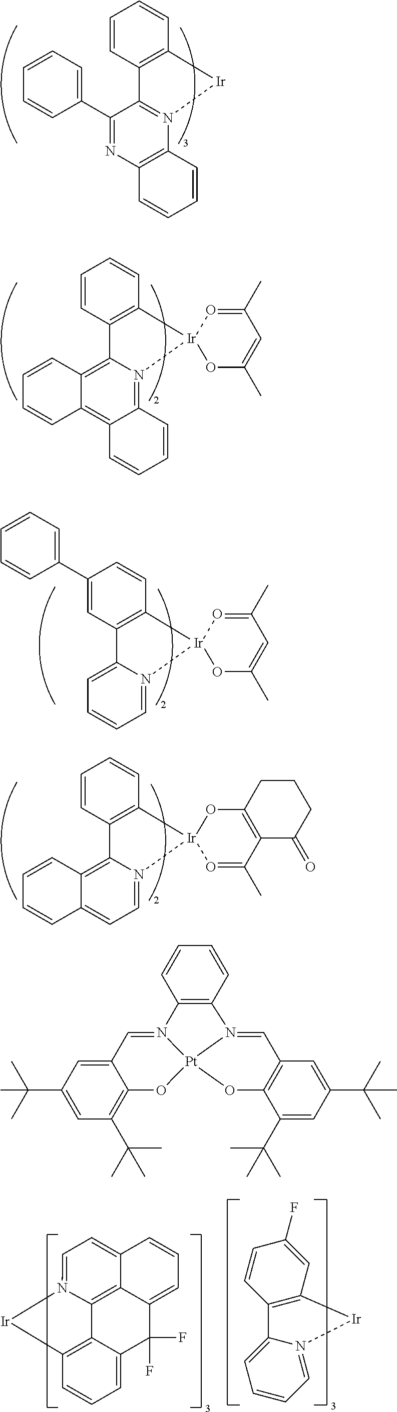

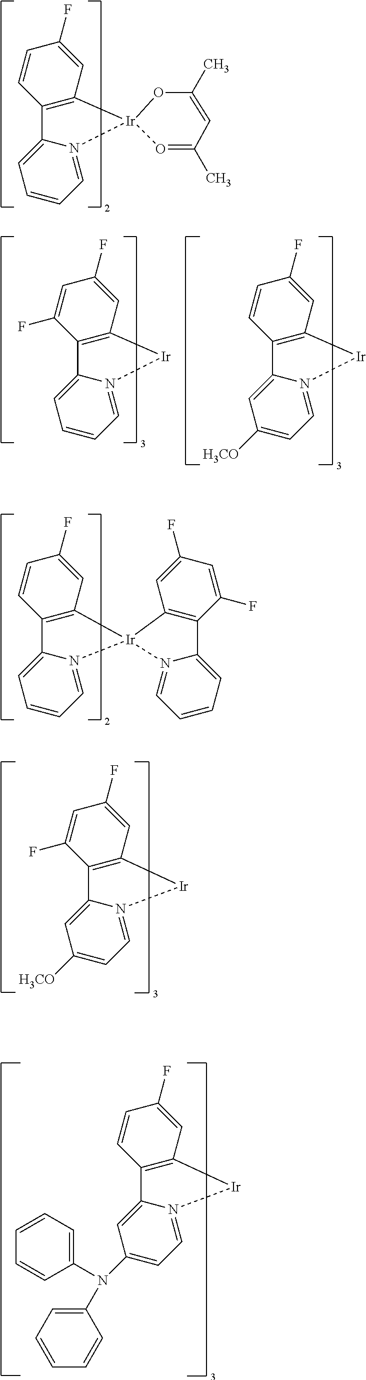

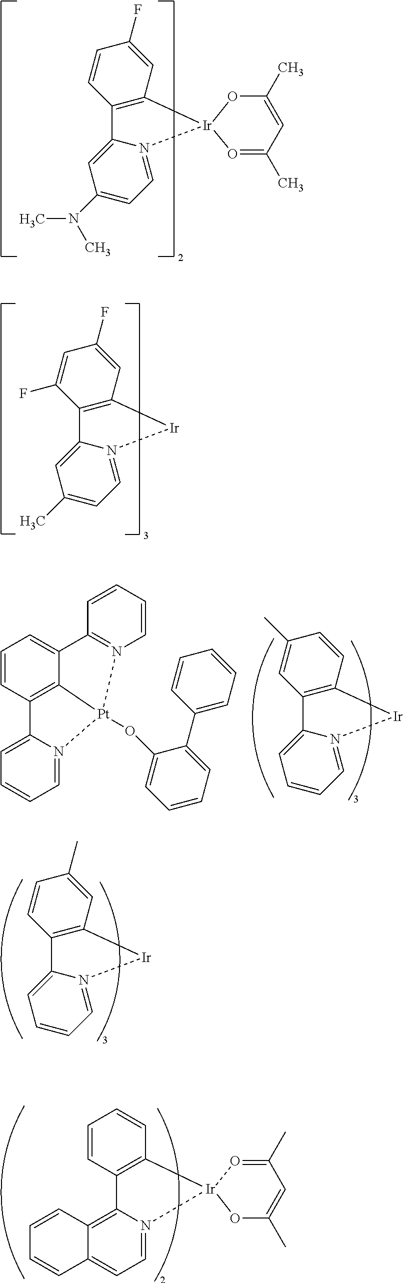

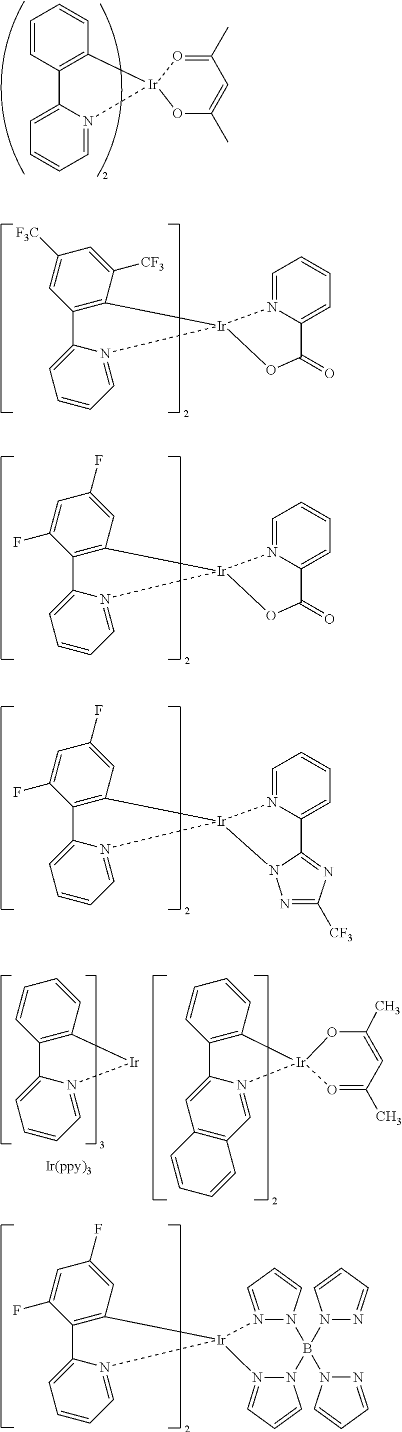

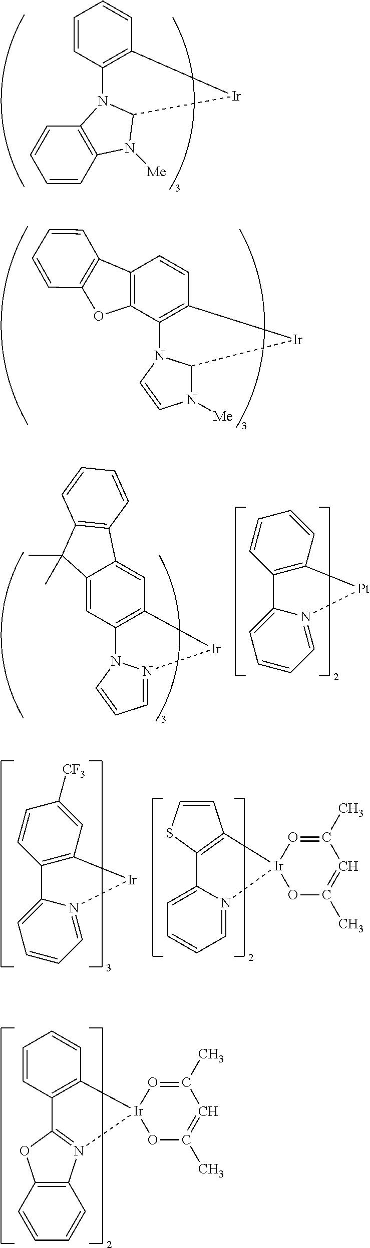

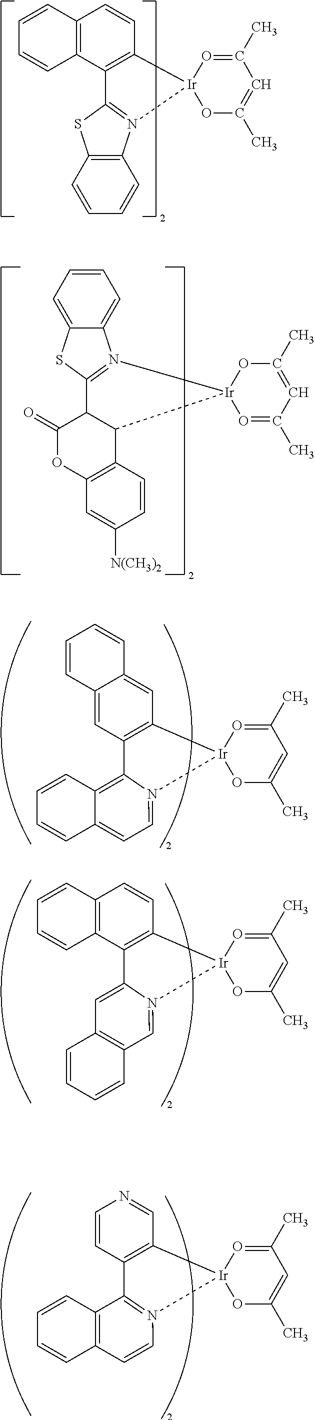

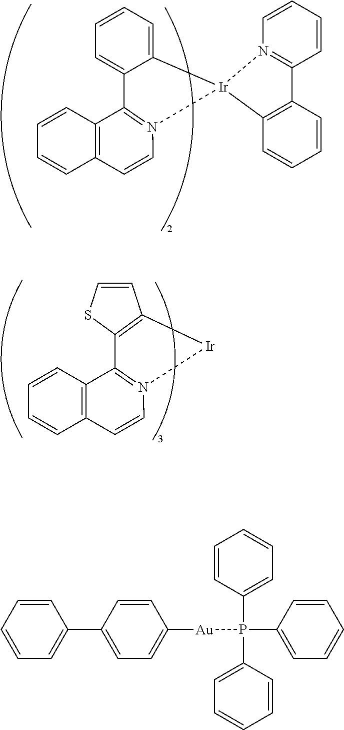

In the organic EL device of this exemplary embodiment, a reductive dopant may be preferably contained in an interfacial region between the cathode and the organic thin-film layer.

With this arrangement, the organic EL device can emit light with enhanced luminance intensity and have a longer lifetime.

The reductive dopant may be at least one compound selected from an alkali metal, an alkali metal complex, an alkali metal compound, an alkali earth metal, an alkali earth metal complex, an alkali earth metal compound, a rare-earth metal, a rare-earth metal complex, a rare-earth metal compound and the like.

Examples of the alkali metal are Na (work function: 2.36 eV), K (work function: 2.28 eV), Rb (work function: 2.16 eV), Cs (work function: 1.95 eV) and the like, among which a substance having a work function of 2.9 eV or less is particularly preferable. Among the above, the reductive dopant is preferably K, Rb or Cs, more preferably Rb or Cs, the most preferably Cs.

Examples of the alkali earth metal are Ca (work function: 2.9 eV), Sr (work function: 2.0 to 2.5 eV), Ba (work function: 2.52 eV), and the like, among which a substance having a work function of 2.9 eV or less is particularly preferable.

Examples of the rare-earth metal are Sc, Y, Ce, Tb, Yb and the like, among which a substance having a work function of 2.9 eV or less is particularly preferable.

Since the above preferable metals have particularly high reducibility, addition of a relatively small amount of the metals to an electron injecting zone can enhance luminance intensity and lifetime of the organic EL device.

Examples of the alkali metal compound are an alkali oxide such as Li₂O, Cs₂O or K₂O, an alkali halogen compound such as LiF, NaF, CsF or KF and the like, among which LiF, Li₂O and NaF are preferable.

Examples of the alkali earth metal compound are BaO, SrO, CaO, a mixture thereof such as BaₓSr_{1-X}O (0<x<1) or BaₓCa_{1-X}O (0<x<1) and the like, among which BaO, SrO and CaO are preferable.

Examples of the rare-earth metal compound are YbF₃, ScF₃, ScO₃, Y₂O₃, Ce₂O₃, GdF₃, TbF₃ and the like, among which YbF₃, ScF₃ and TbF₃ are preferable.

The alkali metal complex, the alkali earth metal complex and the rare-earth metal complex are not specifically limited, as long as at least one of alkali metal ion, alkali earth metal ion and rare-earth metal ion is contained therein as metal ion. The ligand for each of the complexes is preferably quinolinol, benzoquinolinol, acridinol, phenanthridinol, hydroxyphenyl oxazole, hydroxyphenyl thiazole, hydroxydiaryl oxadiazole, hydroxydiaryl thiadiazole, hydroxyphenyl pyridine, hydroxyphenyl benzoimidazole, hydroxybenzo triazole, hydroxy fluborane, bipyridyl, phenanthroline, phthalocyanine, porphyrin, cyclopentadiene, β-diketones, azomethines, or a derivative thereof, but the ligand is not limited thereto.

The reductive dopant is added to preferably form a layer or an island pattern in the interfacial region. The layer of the reductive dopant or the island pattern of the reductive dopant is preferably formed by depositing the reductive dopant by resistance heating deposition while, an emitting material for forming the interfacial region or an organic substance as an electron-injecting material are simultaneously deposited, so that the reductive dopant is dispersed in the organic substance. Dispersion concentration at which the reductive dopant is dispersed in the organic substance is a mole ratio (organic substance to reductive dopant) of 100:1 to 1:100, preferably 5:1 to 1:5.

When the reductive dopant forms the layer, the emitting material or the electron injecting material for forming the organic layer of the interfacial region is initially layered, and the reductive dopant is subsequently deposited singularly thereon by resistance heating deposition to form a preferably 0.1 to 15 nm-thick layer.

When the reductive dopant forms the island pattern, the emitting material or the electron injecting material for forming the organic layer of the interfacial region is initially formed in an island shape, and the reductive dopant is subsequently deposited singularly thereon by resistance heating deposition to form a preferably 0.05 to 1 nm-thick island shape.

A ratio of the main component to the reductive dopant in the organic EL device of this exemplary embodiment is preferably a mole ratio (main component to reductive dopant) of 5:1 to 1:5, more preferably 2:1 to 1:2.

The organic EL device of this exemplary embodiment preferably includes the electron transporting layer or the electron injecting layer between the emitting layer and the cathode, and the electron transporting layer or the electron injecting layer preferably contains the above organic-EL-device material. The electron transporting layer or the electron injecting layer more preferably contains the above organic-EL-device material as the main component. The electron injecting layer may serve also as the electron transporting layer.

It should be noted that “as the main component” means that the organic-EL-device material is contained in the electron injecting layer with a content of 50 mass % or more.

The electron injecting layer or the electron transporting layer, which aids injection of the electrons into the emitting layer, has a high electron mobility. The electron injecting layer is provided for adjusting energy level, by which, for instance, sudden changes of the energy level can be reduced.

A preferable example of an electron transporting material for forming the electron transporting layer or the electron injecting layer is an aromatic heterocyclic compound having in the molecule at least one heteroatom. Particularly, a nitrogen-containing cyclic derivative is preferable. The nitrogen-containing cyclic derivative is preferably an aromatic ring having a nitrogen-containing six-membered or five-membered ring skeleton, or a fused aromatic cyclic compound having a nitrogen-containing six-membered or five-membered ring skeleton.

A preferable example of the nitrogen-containing cyclic derivative is a nitrogen-containing cyclic metal chelate complex represented by the following formula (A1).

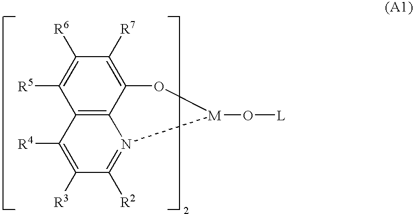

In the formula, R² to R⁷ each independently represent a hydrogen atom, a halogen atom, an oxy group, an amino group, a hydrocarbon group having 1 to 40 carbon atoms, an alkoxy group, an aryloxy group, an alkoxycarbonyl group or a heterocyclic group. R² to R⁷ may be substituted or unsubstituted.

Examples of the halogen atom are fluorine, chlorine, bromine, iodine and the like. Examples of a substituted or unsubstituted amino group are an alkylamino group, an arylamino group and an aralkylamino group.

Examples of the hydrocarbon group having 1 to 40 carbon atoms are a substituted or unsubstituted alkyl group, an alkenyl group, a cycloalkyl group, an aryl group, an aralkyl group and the like.

In this exemplary embodiment, the electron injecting layer or the electron transporting layer preferably contains a nitrogen-containing heterocyclic derivative.

The electron injecting layer or the electron transporting layer, which aids injection of the electrons into the emitting layer, has a high electron mobility. The electron injecting layer is provided for adjusting energy level, by which, for instance, sudden changes of the energy level can be reduced. As a material for the electron injecting layer or the electron transporting layer, 8-hydroxyquinoline or a metal complex of its derivative, an oxadiazole derivative and a nitrogen-containing heterocyclic derivative are preferable. An example of the 8-hydroxyquinoline or the metal complex of its derivative is a metal chelate oxinoid compound containing a chelate of oxine (typically 8-quinolinol or 8-hydroxyquinoline). For instance, tris(8-quinolinol) aluminum can be used. Examples of the oxadiazole derivative are as follows.

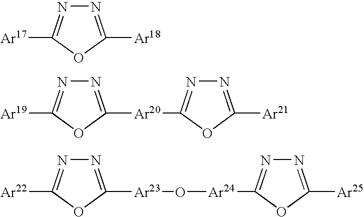

In the formula, Ar¹⁷, Ar¹⁸, Ar¹⁹, Ar²¹, Ar²² and Ar²⁵ each represent a substituted or unsubstituted arylene group. Ar¹⁷, Ar¹⁹ and Ar²² may be the same as or different from Ar¹⁸, Ar²¹ and Ar²⁵ respectively. Ar²⁰, Ar²³ and Ar²⁴ each represent a substituted or unsubstituted arylene group. Ar²³ and Ar²⁴ may be mutually the same or different.

Examples of the arylene group are a phenylene group, naphthylene group, biphenylene group, anthranylene group, perylenylene group and pyrenylene group. Examples of the substituent therefor are an alkyl group having 1 to 10 carbon atoms, alkoxy group having 1 to 10 carbon atoms and cyano group. Such an electron transport compound is preferably an electron transport compound that can be favorably formed into a thin film(s).

An example of the nitrogen-containing heterocyclic derivative is a nitrogen-containing heterocyclic derivative that is not a metal complex, the derivative being formed of an organic compound having the following structure. Examples of the nitrogen-containing heterocyclic derivative are five-membered ring or six-membered ring derivative having a skeleton represented by (A) and a derivative having a structure represented by (B).

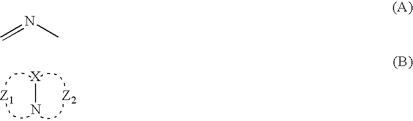

In (B). X represents a carbon atom or a nitrogen atom. Z₁ and Z₂ each independently represent an atom group capable of forming a nitrogen-containing heterocycle.

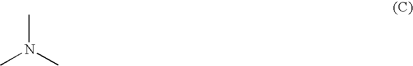

Preferably, the nitrogen-containing heterocyclic derivative is an organic compound having a nitrogen-containing aromatic polycyclic group having a five-membered ring or six-membered ring. When the nitrogen-containing heterocyclic derivative includes such nitrogen-containing aromatic polycyclic series having plural nitrogen atoms, the nitrogen-containing heterocyclic derivative may be a nitrogen-containing aromatic polycyclic organic compound having a skeleton formed by a combination of the skeletons respectively represented by the formulae (A) and (B), or by a combination of the skeletons respectively represented by the formulae (A) and (C).

A nitrogen-containing group of the nitrogen-containing organic compound is selected from nitrogen-containing heterocyclic groups respectively represented by the following.

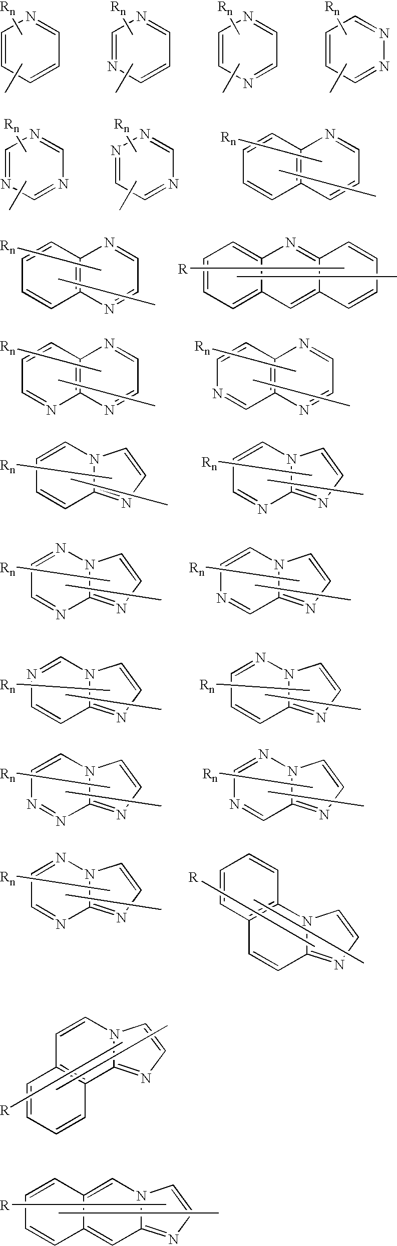

In the formulae: R represents an aryl group having 6 to 40 carbon atoms, heteroaryl group having 3 to 40 carbon atoms, alkyl group having 1 to 20 carbon atoms or alkoxy group having 1 to 20 carbon atoms; and n represents an integer in a range of 0 to 5. When n is an integer of 2 or more, plural R may be mutually the same or different.

A preferable specific compound is a nitrogen-containing heterocyclic derivative represented by the following formula.

Har-L¹-Ar¹—Ar²

In the formula, HAr represents a substituted or unsubstituted nitrogen-containing heterocycle having 3 to 40 carbon atoms; L¹ represents a single bond, substituted or unsubstituted arylene group having 6 to 40 carbon atoms or substituted or unsubstituted heteroarylene group having 3 to 40 carbon atoms; Ar¹ represents a substituted or unsubstituted divalent aromatic hydrocarbon group having 6 to 40 carbon atoms; and Ar² represents a substituted or unsubstituted aryl group having 6 to 40 carbon atoms or substituted or unsubstituted heteroaryl group having 3 to 40 carbon atoms.

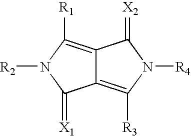

In the Formula, R₁ to R₄ each independently represent a hydrogen atom, substituted or unsubstituted aliphatic group, substituted or unsubstituted alicyclic group, substituted or unsubstituted carbocyclic aromatic cyclic group or substituted or unsubstituted heterocyclic group. X₁ and X₂ each independently represent an oxygen atom, sulfur atom or dicyanomethylene group.

Alternatively, the following compound (see JP-A-2000-173774) can also be favorably used.

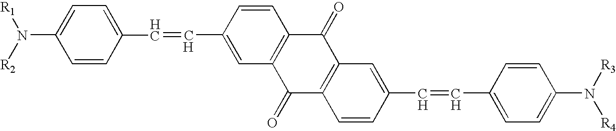

In the formula, R₁, R₂, R₃ and R₄, which may be mutually the same or different, each represent an aryl group represented by the following formula.

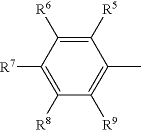

In the formula, R⁵, R⁶, R⁷, R⁸ and R⁹, which may be mutually the same or different, each represent a hydrogen atom, saturated or unsaturated alkoxy group, alkyl group, amino group or alkylamino group. At least one of R⁵, R⁶, R⁷, R⁸ and R⁹ represents a saturated or unsaturated alkoxy group, alkyl group, amino group or alkylamino group.

A polymer compound containing the nitrogen-containing heterocyclic group or a nitrogen-containing heterocyclic derivative may be used.

The electron transporting layer preferably contains at least one of nitrogen-containing heterocycle derivatives respectively represented by the following formulae (201) to (203).

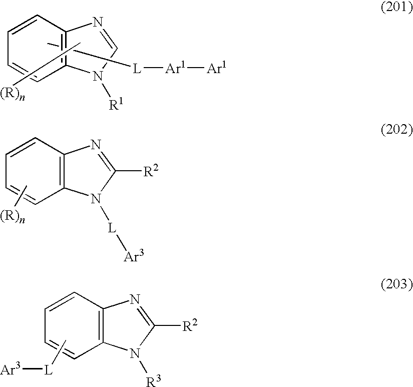

In the formulae (201) to (203): R represents a hydrogen atom, substituted or unsubstituted aryl group having 6 to 60 carbon atoms, substituted or unsubstituted pyridyl group, substituted or unsubstituted quinolyl group, substituted or unsubstituted alkyl group having 1 to 20 carbon atoms or substituted or unsubstituted alkoxy group having 1 to 20 carbon atoms; n represents an integer of 0 to 4; R¹ represents a substituted or unsubstituted aryl group having 6 to 60 carbon atoms, substituted or unsubstituted pyridyl group, substituted or unsubstituted quinolyl group, substituted or unsubstituted alkyl group having 1 to 20 carbon atoms or alkoxy group having 1 to 20 carbon atoms; R² and R³ each independently represent a hydrogen atom, substituted or unsubstituted aryl group having 6 to 60 carbon atoms, substituted or unsubstituted pyrydyl group, substituted or unsubstituted quinolyl group, substituted or unsubstituted alkyl group having 1 to 20 carbon atoms or substituted or unsubstituted alkoxy group having 1 to 20 carbon atoms; L represents a substituted or unsubstituted arylene group having 6 to 60 carbon atoms, substituted or unsubstituted pyridinylene group, substituted or unsubstituted quinolinylene group or substituted or unsubstituted fluorenylene group; Ar¹ represents a substituted or unsubstituted arylene group having 6 to 60 carbon atoms, substituted or unsubstituted pyridinylene group or substituted or unsubstituted quinolinylene group; Ar² represents a substituted or unsubstituted aryl group having 6 to 60 carbon atoms, substituted or unsubstituted pyridyl group, substituted or unsubstituted quinolyl group, substituted or unsubstituted alkyl group having 1 to 20 carbon atoms or substituted or unsubstituted alkoxy group having 1 to 20 carbon atoms.

Ar³ represents a substituted or unsubstituted aryl group having 6 to 60 carbon atoms, substituted or unsubstituted pyridyl group, substituted or unsubstituted quinolyl group, substituted or unsubstituted alkyl group having 1 to 20 carbon atoms, substituted or unsubstituted alkoxy group having 1 to 20 carbon atoms or a group represented by —Ar¹-Ar² (Ar¹ and Ar² may be the same as the above).

In the formulae (201) to (203), R represents a hydrogen atom, a substituted or unsubstituted aryl group having 6 to 60 carbon atoms, a substituted or unsubstituted pyridyl group, substituted or unsubstituted quinolyl group, a substituted or unsubstituted alkyl group having 1 to 20 carbon atoms, or a substituted or unsubstituted alkoxy group having 1 to 20 carbon atoms.

Although thickness of the electron injecting layer or the electron transporting layer is not specifically Limited, the thickness is preferably 1 to 100 nm.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron injectability of the electron injecting layer.

As the insulator, it is preferable to use at least one metal compound selected from a group consisting of an alkali metal chalcogenide, an alkali earth metal chalcogenide, a halogenide of alkali metal and a halogenide of alkali earth metal. By forming the electron injecting layer from the alkali metal chalcogenide or the like, the electron injecting capability can preferably be further enhanced. Specifically, preferable examples of the alkali metal chalcogenide are Li₂O, K₂O, Na₂S, Na₂Se and Na₂O, while preferable example of the alkali earth metal chalcogenide are CaO, BaO, SrO, BeO, BaS and CaSe. Preferable examples of the halogenide of the alkali metal are LiF, NaF, KF, LiCl, KCl and NaCl. Preferable examples of the halogenide of the alkali earth metal are fluorides such as CaF₂, BaF₂, SrF₂, MgF₂ and BeF₂, and halogenides other than the fluoride.

Examples of the semiconductor are one of or a combination of two or more of an oxide, a nitride or an oxidized nitride containing at least one element selected from Ba, Ca, Sr, Yb, Al, Ga, In, Li, Na, Cd, Mg, Si, Ta, Sb and Zn. An inorganic compound for forming the electron injecting layer is preferably a microcrystalline or amorphous semiconductor film. When the electron injecting layer is formed of such semiconductor film, more uniform thin film can be formed, thereby reducing pixel defects such as a dark spot. Examples of such an inorganic compound are the above-described alkali metal chalcogenide, alkali earth metal chalcogenide, halogenide of the alkali metal and halogenide of the alkali earth metal.

When the electron injecting layer contains such an insulator or such a semiconductor, a thickness thereof is preferably in a range of approximately 0.1 to 15 nm. The electron injecting layer of this exemplary embodiment may preferably contain the above-described reductive dopant.

The hole injecting layer or the hole transporting layer (including the hole injecting/transporting layer) may contain an aromatic amine compound such as an aromatic amine derivative represented by the following (IA).

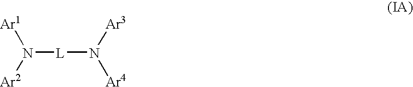

In the above (IA), Ar¹ to Ar⁴ each represent a substituted or unsubstituted aryl group having 6 to 50 carbon atoms for forming a ring or a substituted or unsubstituted heteroaryl group having 5 to 50 atoms for forming a ring.

Aromatic amine represented by the following (IIA) can also be preferably used for forming the hole injecting layer or the hole transporting layer.

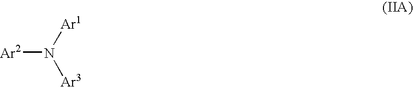

It should be noted that the present invention is not limited to the above description but may include any modification as long as such modification stays within a scope and a spirit of the present invention.

For instance, the following is a preferable example of such modification made to the invention.

According to the aspect of the invention, the emitting layer may also preferably contain an assistance material for assisting injection of charges.

When the emitting layer is formed of a host material that exhibits a wide energy gap, a difference in ionization potential (Ip) between the host material and the hole injecting/transporting layer etc. becomes so large that the holes can hardly be injected into the emitting layer and that a driving voltage required for providing sufficient luminance may be raised.

In the above instance, introducing a hole-injectable/transportable assistance material for assisting injection of charges in the emitting layer can contribute to facilitation of the injection of the holes into the emitting layer and to reduction of the driving voltage.

As the assistance material for assisting the injection of charges, for instance, a typical hole injecting/transporting material or the like can be used.

Examples of the assistance material for assisting the injection of charges are triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, polysilane-base copolymers, aniline-base copolymers and conductive polymer oligomers.

While the above are hole-injectable materials, porphyrin compounds, aromatic tertiary amine compounds and styrylamine compounds are preferable, among which aromatic tertiary amine compounds are particularly preferable.

In addition, 4,4′-bis(N-(1-naphthyl)-N-phenylamino)biphenyl (hereinafter, abbreviated as NPD) having in the molecule two fused aromatic rings disclosed in U.S. Pat. No. 5,061,569, 4,4′,4″-tris(N-(3-methylphenyl)-N-phenylamino) triphenylamine (hereinafter, abbreviated as MTDATA) in which three triphenylamine units disclosed in JP-A-04-308688 are bonded in a starbust form and the like may also be used.

Further, a hexaazatriphenylene derivative disclosed in Japanese Patent No. 3614405, Japanese Patent No. 3571977 or U.S. Pat. No. 4,780,536 may also preferably be used as the hole-injectable material.

Alternatively, inorganic compounds such as p-type Si and p-type SiC can also be used as the hole-injecting material.

A method of forming each of the layers in the organic EL device of this exemplary embodiment is lot particularly limited. A conventionally-known methods such as vacuum deposition or spin coating may be employed for forming the layers. The organic thin-film layer, which is used in the organic EL device of this exemplary embodiment, may be formed by a known coating method such as vacuum deposition, molecular beam epitaxy (MBE method) or coating methods using a solution such as a dipping, spin coating, casting, bar coating, and roll coating.

Although the thickness of each organic layer of the organic EL device of this exemplary embodiment is not particularly limited, the thickness is generally preferably in a range of several nanometers to 1 μm because an excessively-thinned film tends to entail defects such as a pin hole while an excessively-thickened film requires high voltage to be applied and deteriorates efficiency.

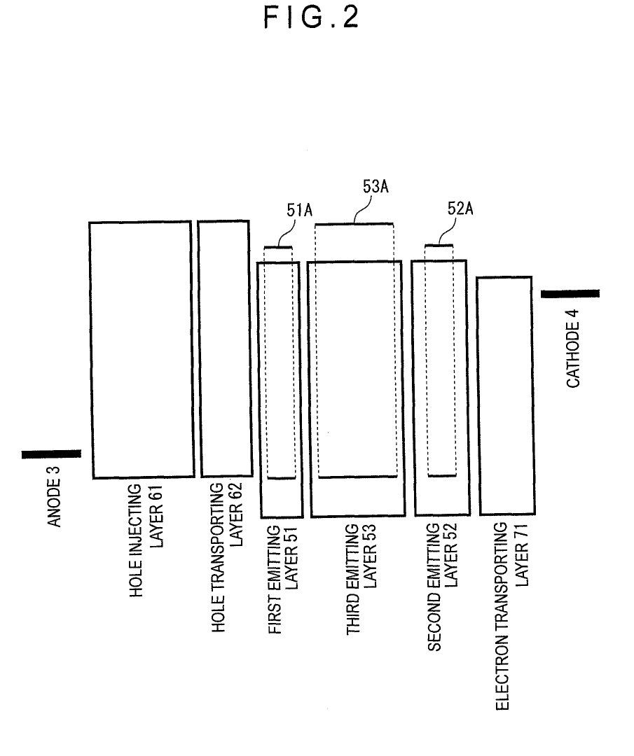

Now, operations of the organic EL device of this exemplary embodiment will be described with reference to the example in the band diagram of the organic EL device shown in FIG. 2.

Six rectangles shown in FIG. 2 respectively denote a hole injecting layer 61, hole transporting layer 62, first emitting layer 51, third emitting layer 53, second emitting layer 52 and electron transporting layer 71. The upper sides of the rectangles respectively denote affinity levels of the layers while the lower sides respectively denote ionization potentials of the layers (the ionization potentials are substantially equal to energy amounts of HOMO). However, with respect to the first emitting layer 51, second emitting layer 52 and third emitting layer 53, levels of the hosts are respectively denoted in place of the level of the entire layer.

When the organic EL device 1 is applied with voltage, holes are injected into the host of the first emitting layer 51 from the anode 3 through the hole injecting layer 61 and the hole transporting layer 62, and the holes are further injected into the third emitting layer 53 and the second emitting layer 52 through the first emitting layer 51.

On the other hand, electrons are injected into the host of the second emitting layer 52 from the cathode 4 through the electron transporting layer 71, and the electrons are further injected into the third emitting layer 53 and the first emitting layer 51 through the second emitting layer 52.

The numerals 51A, 52A and 53A each denote a dopant. The injected charges are recombined together within the emitting layers, so that the dopants emit light. The third emitting layer 53, which is interposed between the first emitting layer 51 and the second emitting layer 52, is invulnerable to influence of carrier accumulated in the first emitting layer 51 and the second emitting layer 52.

Accordingly, degradation of the heterocycle-containing compound contained in the third emitting layer 53 can be suppressed.

### <Modifications>

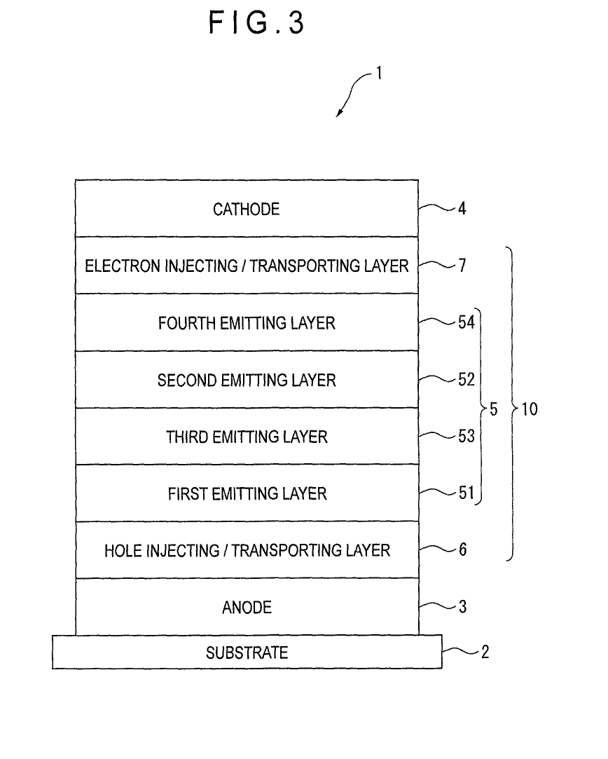

The organic EL device according to the aspect of the invention may include additional emitting layers in the phosphorescent-emitting layer 5 of the exemplary embodiment as shown in FIG. 3.

Specifically, the organic EL device may include the red-emitting first emitting layer 51, the green-emitting third emitting layer 53, the red-emitting second emitting layer 52 and a blue-emitting fourth emitting layer 54, so that the organic thin-film layer 10 may provide white-color emission. Since it is preferable that the red-emitting first emitting layer 51, the green-emitting third emitting layer 53 and the red-emitting second emitting layer 52 are continuously provided, the blue-emitting fourth emitting layer 54 is preferably provided to the red-emitting second emitting layer 52 adjacently to the cathode 4. Although not shown, the blue-emitting fourth emitting layer 54 may be provided to the red-emitting first emitting layer 51 adjacently to the anode 3.

Since emitting white light, the organic EL device 1 as described above is applicable to illuminators and the like. The fourth emitting layer has a fluorescent dopant or a phosphorescent dopant. Preferably, a phosphorescent dopant is used.

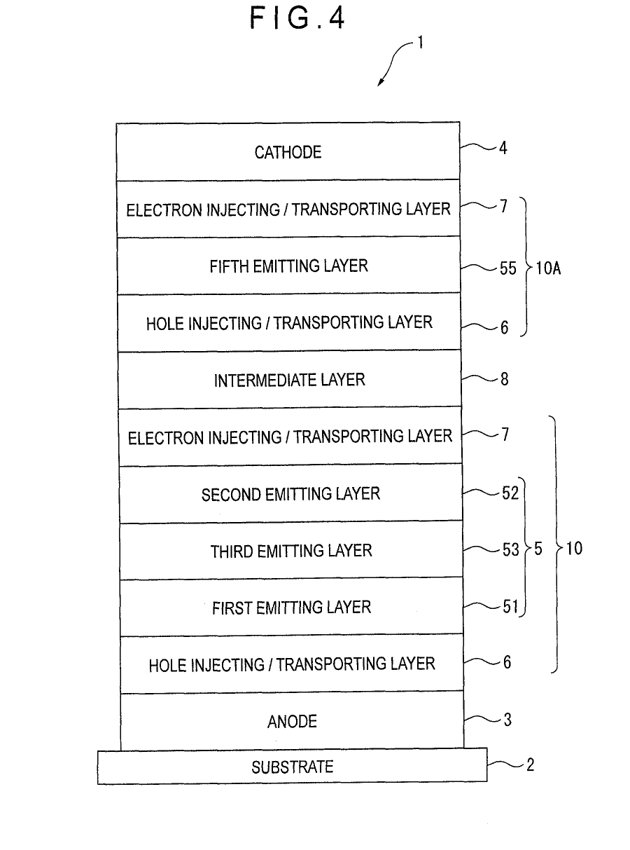

Further, the organic EL device according to the aspect of the invention may be structured as shown in FIG. 4.

In other words, the organic EL device includes a plurality of emitting units with intermediate layer(s) interposed. Specifically, the organic EL device is structured such that the anode, a first emitting unit 10 as the organic thin-film layer, an intermediate layer 8, a second emitting unit 10A as a second organic thin-film layer and the cathode 4 are arranged in this order. The first emitting unit 10 includes the hole injecting/transporting layer 6, the phosphorescent-emitting layer 5 of this exemplary embodiment (the first emitting layer 51, third emitting layer 53 and second emitting layer 52) and the electron injecting/transporting layer 7 in this order.

The second emitting unit 10A includes the hole injecting/transporting layer 6, a fifth emitting layer 55 and the electron injecting/transporting layer 7 in this order.

The intermediate layer 8 includes a charge generating layer, a transparent conductive layer and the like. The intermediate layer 8 includes, for instance, a laminate in which alkali metal and an alkali metal compound such as alkali metal oxide and an electron accepting material such as HAT are laminated in this order from the anode, an oxide semiconductor, or a laminate in which alkali metal and an alkali metal compound such as alkali metal oxide and an oxide semiconductor are laminated in this order from the anode.

The second emitting unit 10A may have the same structure as the first emitting unit 10.

The organic EL device of the above structure, which is a so-called tandem-type device, can exemplarily reduce the driving voltage and have a longer lifetime. In addition, the organic EL device of the above structure can also emit white light.

### EXAMPLES

Description of Examples will be made below. However, the invention is not limited by these Examples.

### Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus, so that a 10-nm thick film of a compound HT1 was initially formed at 1 Å/s as a hole injecting layer on a surface of the glass substrate where the transparent electrode line was provided so as to cover the transparent electrode.

On this film, a 10-nm thick film of a compound HT2 was formed at 1 Å/s as a hole transporting layer.

Further on this film of the compound HT2, a 3-nm thick film of a compound L1 and compound D1 was formed as a first emitting layer with a thickness ratio of the compound L1 to D1 being 2.85:0.15. Film-forming rates were respectively 1 Å/s and 0.052 Å/s.

Further on this film, a 35-nm thick film of a compound L2 and compound D2 was formed as a third emitting layer with a thickness ratio of the compound L2 to D2 being 31.5:3.5. Film-forming rates were respectively 1 Å/s and 0.11 Å/s.

Further on this film, a 10-nm thick film of a compound L1 and compound D1 was formed as a second emitting layer with a thickness ratio of the compound L1 to D1 being 9.5:0.5. Film-forming rates were respectively 1 Å/s and 0.11 Å/s.

On this film, a 30-nm thick film of a compound ET1 was formed at a film-forming rate of 1 Å/s as an electron transporting layer.

After that, LiF was formed into a 0.5-nm thick film at a film-forming rate of 0.1 Å/s. Metal (Al) was vapor-deposited on the LiF film at a film-forming rate of 1 Å/s to form a 100-nm thick metal cathode, thereby providing the organic EL device.

Structures of compounds used in Examples and Comparatives will be shown below.

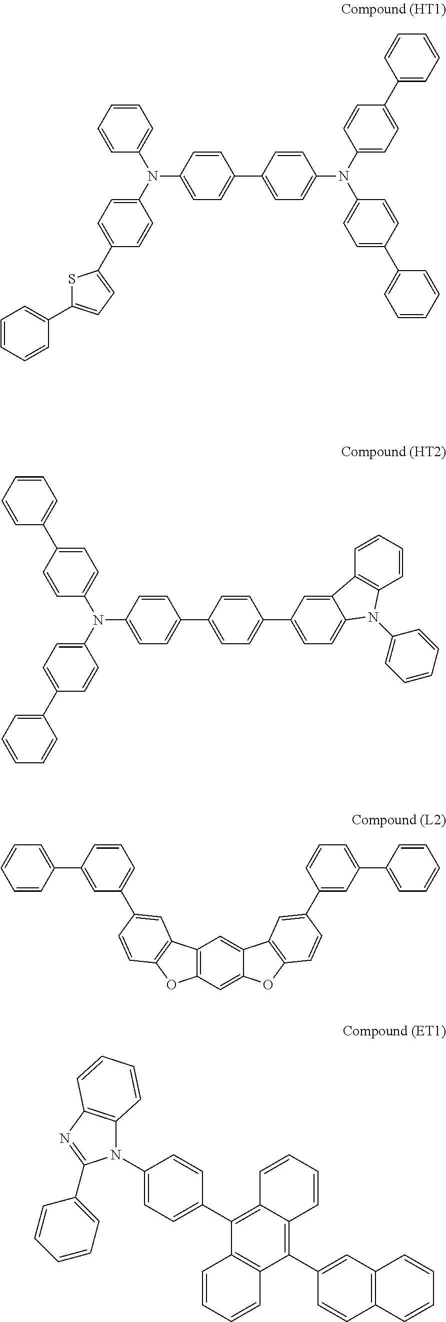

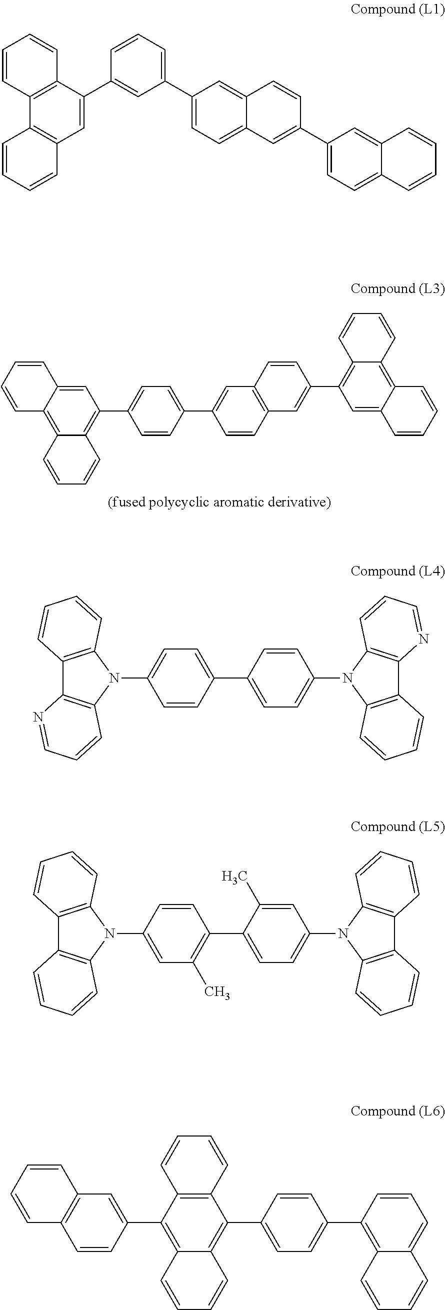

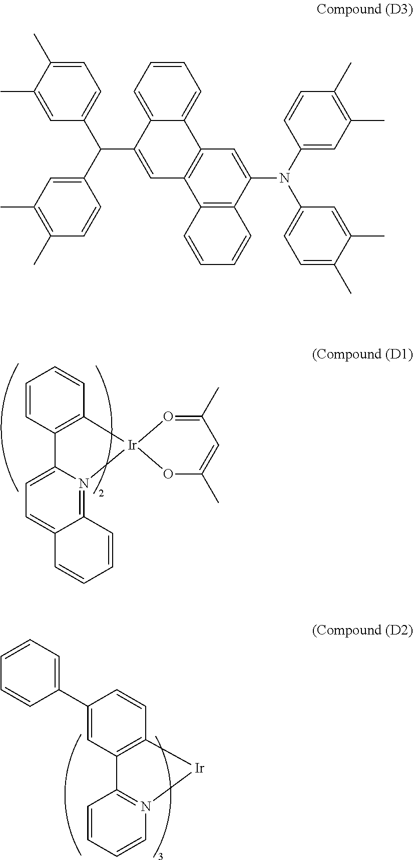

### Example 2

Except that the compound L3 was used as the second emitting layer in place of the compound L1, the organic EL device according to Example 2 was manufactured in the same manner as Example 1.

### Example 3

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus, so that 10-nm thick film of the compound HT1 was initially formed at 1 Å/s as a hole injecting layer on a surface of the glass substrate where the transparent electrode line was provided so as to cover the transparent electrode.

On this film, a 10-nm thick film of the compound HT2 was formed at 1 Å/s as a hole transporting layer.

Further on this film of the compound HT2, a 3-nm thick film of the compound L1 and compound D1 was formed as a first emitting layer with a thickness ratio of the compound L1 to D1 being 2.85:0.15. Film-forming rates were respectively 1 Å/s and 0.052 Å/s.

Further on this film, a 35-nm thick film of the compound L2 and compound D2 was formed as a third emitting layer with a thickness ratio of the compound L2 to D2 being 31.5:3.5. Film-forming rates were respectively 1 Å/s and 0.11 Å/s.

Further on this film, a 10-nm thick film of the compound L1 and compound D1 was formed as a second emitting layer with a thickness ratio of the compound L1 to D1 being 9.5:0.5 Film-forming rates were respectively 1 Å/s and 0.11 Å/s.

On this film, a 30-nm thick film of the compound ET1 was formed at a film-forming rate of 1 Å/s as an electron transporting layer.

After that, Li₂O (alkali metal oxide) was formed into 0.1-nm thick film at a film-forming rate of 0.1 Å/s. On this film, a 20-nm thick film of HAT (hexacyanoazatriphenylene), which is an electron donating material, was formed at a film-forming rate of 1 Å/s.

Then, a 20-nm thick film of the compound HT1 was formed at 1 Å/s as a hole injecting layer. On this film, a 20-nm thick film of the compound HT2 was formed at 1 Å/s as a hole transporting layer.

Further on this film of the compound HT2, a 40-nm thick film of the compound L6 and compound D3 was formed as a fifth emitting layer with a thickness ratio of the compound L6 to D3 being 38:2. Film-forming rates were respectively 1 Å/s and 0.052 Å/s. On this film, a 20-nm thick film of the compound ET1 was formed at a film-forming rate of 1 Å/s as an electron transporting layer.

After that, Li₂O was formed into 0.1-nm thick film at a film-forming rate of 0.1 Å/s. Metal (Al) was vapor-deposited on the LiF film at a film-forming rate of 1 Å/s to form a 100-nm thick metal cathode, thereby providing the organic EL device.

### (Comparative 1)

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus, so that 10-nm thick film of the compound HT1 was initially formed at 1 Å/s as a hole injecting layer on a surface of the glass substrate where the transparent electrode line was provided so as to cover the transparent electrode.

On this film, a 10-nm thick film of the compound HT2 was formed at 1 Å/s as a hole transporting layer.

Further on this film of the compound HT2, a 3-nm thick film of the compound L1 and compound D1 was formed as a first emitting layer with a thickness ratio of the compound L1 to D1 being 2.85:0.15. Film-forming rates were respectively 1 Å/s and 0.052 Å/s.

Further on this film, a 35-nm thick film of the compound L2 and compound D2 was formed as a third emitting layer with a thickness ratio of the compound L2 to D2 being 31.5:3.5. Film-forming rates were respectively 1 Å/s and 0.11 Å/s.

Further on this film, a 40-nm thick film of the compound ET1 was formed at a film-forming rate of 1 Å/s as an electron transporting layer.

After that, LiF was formed into 0.5-nm thick film at a film-forming rate of 0.1 Å/s. Metal (Al) was vapor-deposited on the LiF film at a film-forming rate of 1 Å/s to form a 100-nm thick metal cathode, thereby providing the organic EL device.

### (Comparative 2)

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus, so that 10-nm thick film of the compound HT1 was initially formed at 1 Å/s as a hole injecting layer on a surface of the glass substrate where the transparent electrode line was provided so as to cover the transparent electrode.

On this film, a 10-nm thick film of the compound HT2 was formed at 1 Å/s as a hole transporting layer.

Further on this film of the compound HT2, a 35-nm thick film of the compound L2 and compound D2 was formed as a third emitting layer with a thickness ratio of the compound L2 to D2 being 31.5:3.5. Film-forming rates were respectively 1 Å/s and 0.11 Å/s.

Further on this film, a 10-nm thick film of the compound L1 and compound D1 was formed as a second emitting layer with a thickness ratio of the compound L1 to D1 being 9.5:0.5. Film-forming rates were respectively 1 Å/s and 0.052 Å/s.

On this film, a 30-nm thick film of the compound ET1 was formed at a film-forming rate of 1 Å/s as an electron transporting layer.

After that, LiF was formed into 0.5-nm thick film at a film-forming rate of 0.1 Å/s. Metal (Al) was vapor-deposited on the LiF film at a film-forming rate of 1 Å/s to form a 100-nm thick metal cathode, thereby providing the organic EL device.

### (Comparative 3)

Except that the compound L4 was used as the first emitting layer and second emitting layer in place of the compound L1 and that the compound L5 was used as the third emitting layer in place of the compound L2, the organic EL device according to Comparative 3 was manufactured in the same manner as Example 1.

### (Evaluation)

The organic EL devices according to Examples 1 to 3 and Comparatives 1 to 3 are evaluated in a manner as follows.

(1) Initial Performance: The devices were driven to emit light with direct current of 10 mA/cm², and luminous efficiency (L/J) was measured.
(2) The devices were driven at constant current with the initial luminance being 10000 nit, and evaluated with respect to time elapsed until the luminance was reduced down to 50% (LT50).
(3) Chromaticity Change: The devices were evaluated with respect to difference between the initial chromaticity and the chromaticity exhibited when the devices, which were driven at constant current with the initial luminance being 10000 nit, reduced their luminance down to 50%.

The results of the evaluation are shown in Table 1.

TABLE 1

| | | | | Luminous | Time until | | |
|---|---|---|---|---|---|---|---|
| | First | Third | Second | Efficiency | Half-Life | Initial | Chromaticity |
| | Emitting Layer | Emitting Layer | Emitting Layer | (L/J) | (LT50) | Chromaticity | Change |
| | Composition | Composition | Composition | (cd/A) | (hr) | (x, y) | (Δx, Δy) |
| Example 1 | L1:D1 | L2:D2 | L1:D1 | 40 | 1300 | (0.466, 0.514) | (−0.005, 0.004) |
| Example 2 | L1:D1 | L2:D2 | L3:D1 | 60 | 1500 | (0.481, 0.503) | (−0.004, 0.005) |
| Example 3 | L1:D1 | L2:D2 | L1:D1 | 30 | 4000 | (0.372, 0.405) | (−0.005, 0.004) |
| Comparative 1 | L1:D1 | L2:D2 | — | 37 | 1200 | (0.479, 0.505) | (−0.025, 0.021) |
| Comparative 2 | — | L2:D2 | L1:D1 | 55 | 1100 | (0.361, 0.608) | (0.011, −0.01) |
| Comparative 3 | L4:D2 | L5:D2 | L4:D1 | 40 | 500 | (0.46, 0.51) | (−0.02, 0.01) |

The devices according to Examples 1 and 2, in which the compound L1 or L3 containing no heterocycle skeleton was used in the first emitting layer adjacent to the anode and the second emitting layer adjacent to the cathode, were capable of prolonging the time until half-life and greatly suppressing the chromaticity change as compared with the devices according to Comparatives 1 to 3. As in Examples 1 and 2, the device according to Example 3 was also capable of greatly suppressing the chromaticity change and achieving a longer device lifetime.

Accordingly, it has been found that an organic EL device excellent in color stability at the time of changes in current density and also at the time of continuous driving can be obtained.

The entire disclosure of Japanese Patent Application No. 2009-124740, filed May 22, 2009, is expressly incorporated by reference herein.

What is claimed is:

1. An organic electroluminescence device, comprising:
an anode;
a cathode; and
an organic thin-film layer provided between the anode and the cathode and comprising at least three emitting layers, wherein
the organic thin-film layer comprises: a first emitting layer adjacent to the anode; a second emitting layer adjacent to the cathode; and a third emitting layer interposed between the first emitting layer and the second emitting layer,
the first emitting layer, the second emitting layer and the third emitting layer contain phosphorescent dopants, and
the first emitting layer and the second emitting layer use fused polycyclic aromatic derivatives as host materials.

2. The organic electroluminescence device according to claim 1, wherein the third emitting layer uses a heterocycle-containing compound as a host material.

3. The organic electroluminescence device according to claim 2, wherein triplet energy of the heterocycle-containing compound in the third emitting layer is larger than triplet energy of the fused polycyclic aromatic derivatives in the first emitting layer and the second emitting layer.

4. The organic electroluminescence device according to claim 1, wherein the fused polycyclic aromatic derivatives have triplet energy of 2.0 eV or more.

5. The organic electroluminescence device according to claim 1, wherein the fused polycyclic aromatic derivatives are fused polycyclic aromatic hydrocarbon.

6. The organic electroluminescence device according to claim 1, wherein emission wavelengths of the phosphorescent dopants contained in the first emitting layer and the second emitting layer are longer than an emission wavelength of the phosphorescent dopant contained in third emitting layer.

7. The organic electroluminescence device according to claim 6, wherein
the phosphorescent dopants contained in the first emitting layer and the second emitting layer emit red light, and
the phosphorescent dopant contained in the third emitting layer emits green light.

8. The organic electroluminescence device according to claim 2, wherein the fused polycyclic aromatic derivatives in the first emitting layer and the second emitting layer are naphthalene derivatives, and
the heterocycle-containing compound in the third emitting layer is a ladder-type heterocycle-containing compound.

9. The organic electroluminescence device according to claim 8, wherein the naphthalene derivatives contain at least one skeleton selected from a phenanthrene ring, florene ring, fluoranthene ring, benzo[b]fluoranthene ring, benzochrysene ring and benzophenanthrene ring.

10. The organic electroluminescence device according to claim 8, wherein the ladder-type heterocycle-containing compound is a ladder-type furan compound.

11. The organic electroluminescence device according to claim 1, wherein
the phosphorescent dopant contains a metal complex, and
the metal complex has a period 6 metal atom and a ligand.

12. The organic electroluminescence device according to claim 11, wherein the metal atom is iridium.

13. The organic electroluminescence device according to claim 1, providing white-color emission comprising: color emission of the first emitting layer; color emission of the second emitting layer; and color emission of the third emitting layer.

14. The organic electroluminescence device according to claim 13, further comprising:
a second organic thin-film layer, wherein
an intermediate layer is interposed between the organic thin-film layer and the second organic thin-film layer.

15. The organic electroluminescence device according to claim 14, wherein the organic thin-film layer and the second organic thin-film layer provide different color emissions, the organic electroluminescence device providing white-color emission comprising the different color emissions.
